(19) United States
(12) Patent Application Publication
(10) Pub. No.: US 2026/0020451 A1
(43) Pub. Date: Jan. 15, 2026

(54) DISPLAY DEVICE

(71) Applicant: LG Display Co., Ltd., Seoul (KR)

(72) Inventors: Yu Cheol YANG, Paju-si (KR); Seung Han PAEK, Paju-si (KR); Kyung Jae YOON, Paju-si (KR); Jeon Phill HAN, Paju-si (KR); Nam Woo KIM, Paju-si (KR)

(73) Assignee: LG Display Co., Ltd., Seoul (KR)

(21) Appl. No.: 18/989,982

(22) Filed: Dec. 20, 2024

(30) Foreign Application Priority Data
Jul. 12, 2024 (KR) 10-2024-0092257

(51) Int. Cl. H10K 59/124; H10K 59/95

(52) U.S. Cl. CPC H10K 59/124; H10K 59/95

(57) ABSTRACT

A display device may include a display panel and a flexible printed circuit connected to a pad electrode. The display panel may include a substrate having an end portion with an inclined surface. A first planarization layer may be disposed on the substrate and a plurality of first lower patterns may be disposed between the substrate and the first planarization layer. The inclined surface of the substrate may include a top edge and bottom edge and a predetermined angle. An outermost first lower pattern may be disposed proximate the top edge of the inclined surface.

### CROSS-REFERENCE TO RELATED APPLICATION

This application claims priority to and the benefit of Korean Patent Application No. 10-2024-0092257, filed Jul. 12, 2024, the disclosure of which is incorporated herein by reference in its entirety.

### BACKGROUND

### Technical Field

The present disclosure relates to a display device.

### Discussion of the Related Art

Display devices may be mounted on an electronic product or a home appliance such as a television, a monitor, a notebook computer, a smart phone, a tablet computer, a portable information device, or a vehicle control display device are used as a screen to display images.

As such, the field of display devices that visually display electrical information signals is developing rapidly, and research is ongoing to develop performances such as thinning, lightening, and low power consumption strategies for various display devices.

Various display devices include liquid crystal display device (LCD) and organic light-emitting display device (OLED).

After a manufacturing process of manufacturing a plurality of display devices on a mother glass substrate, the mother glass substrate may be physically cut, such as with a laser or a wheel, to produce the plurality of display devices.

When the mother glass substrate is made of glass, a separate finishing process, such as a grinding process, is required because microcracks or glass fragments may occur on the cut surfaces. As such, the resulting increase in the number of processes may reduce the productivity of the display device.

### SUMMARY

The present disclosure is directed to a display panel in which a manufacturing process is simplified by the use of an etching process, and a display device including the same.

Objectives of the present disclosure are not limited to the above-described objectives, and other objectives, which are not described above, will be clearly understood by those skilled in the art from the following description.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

To achieve these and other aspects of the inventive concepts, as embodied and broadly described, a display device may include a display panel and a flexible printed circuit connected to a pad electrode of the display panel. The display panel may include a substrate, a first planarization layer disposed on the substrate, and a plurality of first lower patterns disposed between the substrate and the first planarization layer. The substrate may include an end portion having an inclined surface. The inclined surface may include a top edge and a bottom edge and may further include a predetermined angle. An outermost first lower pattern of the plurality of first lower patterns may be disposed proximate the top edge of the inclined surface.

In some embodiments, the plurality of first lower patterns are parallel to the edges of the display panel.

In some embodiments, the display device further includes a buffer layer disposed on the substrate. The buffer layer may include a buffer layer inclined surface that aligns with the inclined surface of the substrate and the outermost first lower pattern may directly contact an upper surface of the buffer layer in an area proximate the buffer layer inclined surface.

In some embodiments, the plurality of first lower patterns inclined a first target pattern and a second target pattern. The first and second target patterns may be spaced apart in a predetermined interval. The top edge may be disposed between the first target pattern and the second target pattern and the first pattern may be disposed at the outermost side. The display panel may further include a mark disposed on each of the first and second target patterns.

In some embodiments, the display device includes a groove that is disposed in a lower portion of the first planarization layer and protrudes from an exterior surface of the substrate. A side coating may be further disposed in the groove.

In some embodiments, the slope angle of the inclined surface is an acute angle.

In some embodiments, the display device further includes a second lower pattern group and a third pattern group spaced apart from the first lower pattern group that includes the first lower patterns. The second lower pattern group may include a plurality of second lower patterns and the third lower pattern group may include a plurality of third lower patterns. A second distance that extends from an edge of the display panel to the second lower pattern group may be larger than a first distance that extends from the edge of the display panel to the first lower pattern group and less than a third distance that extends from the edge of the display panel to the third lower pattern group.

In some embodiments, the display device further includes a first lower guide pattern and a second lower guide pattern. The first lower guide pattern may connect one of the first lower patterns to one of the second lower patterns and the second lower guide pattern may connect one of the first lower patterns to one of the third lower patterns. Each of the first, second, and third lower patterns may be spaced apart from each other in a first direction and the edge of the display panel may extend in a second direction. A predetermined interval may extend in the first direction and be formed by the second and third lower patterns corresponding to the first lower pattern that overlaps the top edge in a third direction. The bottom edge may be located in the predetermined interval.

In some embodiments, the display panel further includes first and second upper pattern groups disposed on the first planarization layer. The first upper pattern group may include a plurality of first upper patterns and the second upper pattern group may include a plurality of second upper patterns. A second distance that extends from an edge of the display panel to the first upper pattern group may be larger than a first distance that extends from the edge of the display panel to the first lower pattern and less than a third distance that extends from the edge of the display panel to the second upper pattern group. The display panel may further include first and second upper guide patterns disposed on the first planarization layer. The first guide pattern may extend from the first upper pattern toward one side of the first lower patterns and the second upper guide pattern may extend from the second upper pattern toward the other side of the first lower patterns.

In some embodiments, each of the first lower patterns, first upper patterns, and second upper patterns are spaced apart from each other in a first direction while the edge of the display extends in a second direction. A predetermined interval may extend in the first direction and be formed by the first and second upper patterns that correspond to the first lower pattern that overlaps the top edge in a third direction. The bottom edge may be located in the predetermined interval.

In some embodiments, the slope angle formed by the top surface of the substrate and the edge surface may be an obtuse angle.

In some embodiments, the display panel further includes a first upper pattern group and a second upper pattern group disposed on the first planarization layer. The first upper pattern group may include a plurality of first upper patterns and the second upper pattern group may include a plurality of second upper patterns. A fourth distance that extends from an edge of the display panel to the first upper pattern group may be less than a fifth distance that extends from the edge of the display panel to the second upper pattern group. A first distance that extends from the edge of the display to the first lower pattern group may be larger than the fifth distance.

In some embodiments, the display panel further includes first and second upper guide patterns disposed on the first planarization layer. The first upper guide pattern may extend from the first upper pattern toward one side of the plurality of first lower patterns and the second upper guide pattern may extend from the second upper pattern toward the other side of the plurality of first lower patterns.

In some embodiments the substrate is formed of glass.

According to certain embodiments, the display device may include a display panel and a flexible printed circuit connected to a pad electrode of the display panel. The display panel may include a substrate, a first planarization layer disposed on the substrate, a second planarization layer disposed on the first planarization layer, and a plurality of patterns disposed between the first and second planarization layers. The substrate may include an end portion having an inclined surface. The plurality of patterns may include a plurality of main patterns and a plurality of sub patterns, wherein the main patterns have a length that is longer than a length of the sub patterns.

In some embodiments, the main patterns includes a first main pattern and a second main pattern and the sub patterns may be disposed between the first main pattern and the second main pattern.

In addition to the above-mentioned advantages of the present disclosure, other features and advantages of the present disclosure will be described below or may be clearly understood by those skilled in the art from such description or explanation.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this specification, illustrate the embodiments of the disclosure and together with the description serve to explain the principles of the disclosure. In the drawings:

FIG. 1 is a diagram illustrating a display device according to an example embodiment of the present disclosure;

FIG. 2 is a cross-sectional view schematically illustrating a cross-sectional structure of a display area of a display device according to an example embodiment of the present disclosure;

FIG. 3 is a plan view illustrating a display panel according to an example embodiment of the present disclosure;

FIG. 4 is a cross-sectional view taken along line I-I′ in FIG. 3;

FIG. 5 is a cross-sectional view taken along line II-II′ in FIG. 3;

FIG. 6 is a plan view illustrating a display panel before a side coating layer is formed in a display device according to an example embodiment of the present disclosure;

FIG. 7 is a cross-sectional view taken along line III-III′ in FIG. 6;

FIG. 8 is a cross-sectional view taken along line IV-IV′ in FIG. 6;

FIG. 9 is a plan view of a mother glass substrate for explaining a method of manufacturing a display device according to an example embodiment of the present disclosure;

FIGS. 10 and 11 are cross-sectional views taken along lines V-V′ of FIG. 9 illustrating an etching process;

FIG. 12 is a plan view illustrating a display panel according to an example embodiment of the present specification;

FIG. 13 is a cross-sectional view taken along line VI-VI′ in FIG. 12;

FIG. 14 is a plan view illustrating a mark on a display panel according to an example embodiment of the present disclosure;

FIG. 15 is a diagram illustrating an arrangement relationship between an edge and patterns of a substrate in a display panel of a display device according to an example embodiment of the present disclosure;

FIG. 16 is a diagram illustrating a defect of an edge position of a substrate in a display panel of a display device according to an example embodiment of the present disclosure;

FIG. 17 is a diagram illustrating a slope defect of a substrate in a display panel of a display device according to an example embodiment of the present disclosure;

FIG. 18 is a plan view illustrating a display panel according to an example embodiment of the present disclosure;

FIG. 19 is a cross-sectional view taken along line VII-VII′ in FIG. 18;

FIG. 20 is a cross-sectional view taken along line VIII-VIII′ in FIG. 18;

FIG. 21 is a plan view illustrating a mark of a display panel according to an example embodiment of the present disclosure;

FIG. 22 is a diagram illustrating an arrangement relationship between an edge and patterns of a substrate in a display panel of a display device according to an example embodiment of the present disclosure;

FIG. 23 is a diagram illustrating a defect of an edge position of a substrate in a display panel of a display device in accordance with another embodiment of the present specification;

FIG. 24 is a diagram illustrating a slope defect of a substrate in a display panel of a display device accordance to an example embodiment of the present disclosure;

FIG. 25 is a plan view illustrating a display panel according to an example embodiment of the present disclosure;

FIG. 26 is a cross-sectional view taken along line IX-IX′ in FIG. 25;

FIG. 27 is a cross-sectional view taken along line X-X′ in FIG. 25;

FIG. 28 is a plan view illustrating a mark of a display panel according to an example embodiment of the present disclosure;

FIG. 29 is a diagram illustrating an arrangement relationship between an edge and patterns of a substrate in a display panel of a display device according to an example embodiment of the present disclosure;

FIG. 30 is a diagram illustrating a defect of an edge position of a substrate in a display panel of a display device in accordance with an example embodiment of the present disclosure;

FIG. 31 is a diagram illustrating a slope defect of a substrate in a display panel of a display device according to an example embodiment of the present disclosure;

FIG. 32 is a plan view illustrating a display panel according to an example embodiment of the present disclosure;

FIG. 33 is a cross-sectional taken along lines XI-XI′ in FIG. 32 illustrating the slope of an acute angle;

FIG. 34 is a cross-sectional taken along lines XII-XII′ in FIG. 32 illustrating the slope of an acute angle;

FIG. 35 is a cross-sectional view taken along lines XI-XI′ in FIG. 32 illustrating the slope of an obtuse angle;

FIG. 36 is a cross-sectional view taken along lines XII-XII′ in FIG. 32 illustrating the slope of an obtuse angle;

FIG. 37 is a plan view illustrating a mark of a display panel according to an example embodiment of the present disclosure;

FIG. 38 is a diagram illustrating an arrangement relationship between an edge and patterns of a substrate in a display panel having the slope of an acute angle of a display device, according to an example embodiment of the present disclosure;

FIG. 39 is a diagram illustrating a defect of an edge position of a substrate in a display panel having the slope of an acute angle of a display device, according to an example embodiment of the present disclosure;

FIG. 40 is a diagram illustrating a slope defect of a substrate in a display panel having the slope of an acute angle of a display device, according to an example embodiment of the present disclosure;

FIG. 41 is a diagram conceptually illustrating an arrangement relationship between an edge and patterns of a substrate in a display panel having the slope of an obtuse angle of a display device, according to an example embodiment of the present disclosure;

FIG. 42 is a diagram illustrating a defect of an edge position of a substrate in a display panel having the slope of an obtuse angle of a display device, according to an example embodiment of the present disclosure; and

FIG. 43 is a diagram illustrating a slope defect of a substrate in a display panel having the slope of an obtuse angle of a display device, according to an example embodiment of the present disclosure.

### DETAILED DESCRIPTION

It is to be understood that both the foregoing general description and the following detailed description of the present disclosure are by way of example and are intended to provide further explanation of the disclosures as claimed.

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are examples, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Hereinafter, preferred embodiments of the present disclosure will be described in detail with reference to the accompanying drawings.

As used herein, “a display apparatus” may include a display apparatus in a narrow sense, such as a liquid crystal module (LCM), an organic light-emitting diode (OLED) module, or a quantum dot (QD) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

The display device described in this disclosure may include a display device itself in a narrow sense, an application product including a display in a narrow sense, or even a set device being an end-consumer device.

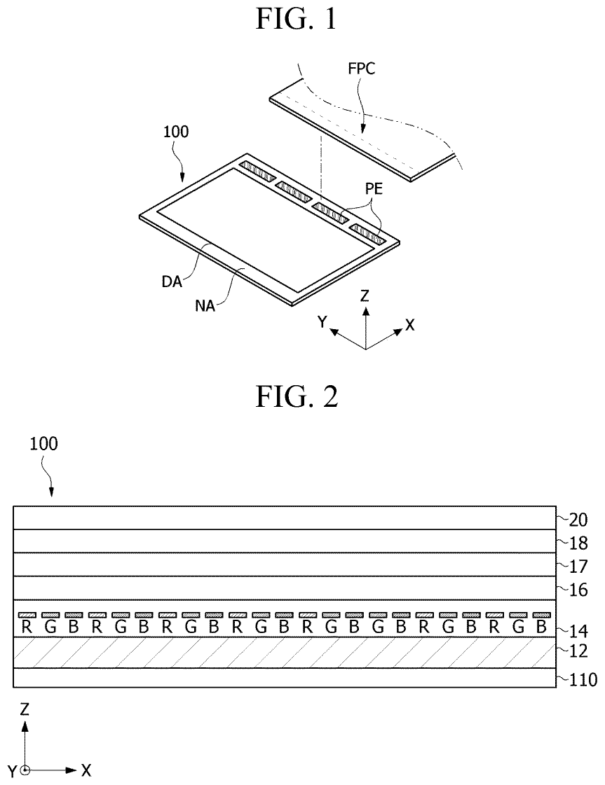

As shown in FIGS. 1 and 2, a display device according to an embodiment of the present disclosure may include a display panel 100 on which an input image is visually reproduced and a flexible printed circuit (FPC) connected to a pad electrode (PE) on the display panel 100.

The display panel 100 may include a display area DA in which the image is displayed and a non-display area NA in which no image is displayed. The display panel 100 may be a panel having a rectangular structure with a width in the X-axis direction, a length in the Y-axis direction, and a thickness in the Z-axis direction. The width and length of the display panel 100 may be set to different design values depending on the area of application of the display device. The X-axis direction may mean width direction, column direction, or vertical direction; the Y-axis direction may mean length direction, row direction, or horizontal direction; and the Z-axis direction may mean up-down direction or thickness direction. In addition, the X-axis direction, Y-axis direction, and Z-axis direction may be perpendicular to each other, but they may also mean different directions that are not perpendicular to each other. Accordingly, each of the X-axis direction, Y-axis direction, and Z-axis direction may be described as one of a first direction, a second direction, and a third direction. In addition, the plane extending in the X-axis direction and the Y-axis direction may mean a horizontal plane.

In some embodiments, in the display area DA of the display panel 100, data lines, gate lines crossing the data lines, and pixels Px arranged in a matrix form defined by the data lines and the gate lines may be disposed.

In some embodiments, each of the pixels Px includes sub-pixels of different colors for color implementation. The sub-pixels may include a red sub-pixel, a green sub-pixel, and a blue sub-pixel. Although not shown, each of the pixels Px may further include a white sub-pixel. In the following description, a pixel may be interpreted as a sub-pixel unless otherwise defined. Additionally, each of sub-pixels may include a pixel circuit.

The pixel circuit may include a light-emitting element, a driving element that supplies a current to the light-emitting element, one or more switch elements that switch the current paths of the driving element and the light-emitting element, and a capacitor that maintains the voltage Vgs between the gate and the source of the driving element.

The light-emitting elements may be implemented in an element structure such as organic light-emitting diode (OLED) display, quantum dot display, or micro light-emitting diode (micro LED) display. In the following description, the light-emitting elements will be described as an OLED structure including an organic compound layer.

In some embodiments, the OLED includes an organic compound layer formed between the anode and the cathode. The organic compound layer may include, but is not limited to, a hole injection layer (HIL), a hole transport layer (HTL), an emission layer (EML), an electron transport layer (ETL), and an electron injection layer (EIL). When a voltage is applied to the anode electrode and the cathode electrode of the OLED, holes passing through the hole transport layer (HTL) and electrons passing through the electron transport layer (ETL) may be moved to the emission layer (EML) to form excitons, thereby emitting visible light in the emission layer (EML).

In some embodiments, the display panel driver writes pixel data of the input image to pixels Px. The display panel driver may include a data driver that supplies a data voltage of pixel data to the data lines, and a gate driver that sequentially supplies a gate pulse to the gate lines. The data driver may be integrated into a drive IC and the drive IC may be attached to the display panel 100.

The drive IC may be connected to the data lines through data output channels and supplies the voltage of the data signal to the data lines. In some embodiments, the drive IC includes a timing controller. The timing controller may transfer pixel data of the input image received from the host system to the data driver and controls the operation timing of the data driver and the gate driver.

The data driver of the drive IC may convert pixel data into a gamma compensation voltage through a digital to analog converter (DAC) to output a data voltage.

The gate driver may include a shift register formed in the circuit layer of the display panel 100 along with the pixel array. The shift register of the gate driver may sequentially supply gate signals to the gate lines under the control of the timing controller. The gate signals may include a scan pulse and an emission control pulse (hereinafter referred to as “EM pulse”). The shift register may include a scan driver that outputs scan pulses and an EM driver that outputs EM pulses.

The host system may be implemented with an application processor (AP). In some embodiments, the host system transfers pixel data of the input image to the drive IC. The host system may be connected to the drive IC via a flexible printed circuit (FPC), for example.

In some embodiments the non-display area NA includes various wiring lines and driving circuits disposed thereon. The pad electrode PE to which integrated circuits and printed circuits are connected may also be disposed on the non-display area NA.

The flexible printed circuit (FPC) may be formed on a flexible printed circuit board and may be connected to the drive IC through the pad electrode PE. In some embodiments, the drive IC may be disposed on the display panel 100, but without being limited thereto. For example, the drive IC may be disposed on the flexible printed circuit board.

The display panel 100 may be manufactured using a glass substrate as the base.

As shown in FIG. 2, the display panel 100 may include a circuit layer 12 disposed on a substrate 110 and a light-emitting element layer 14 disposed on the circuit layer 12. In addition, the display panel 100 may include an encapsulation layer 16 disposed on the light-emitting element layer 14. In addition, the display panel 100 may include a polarizer 18 disposed on the encapsulation layer 16 and a cover member 20 disposed on the polarizer 18. In addition, the display panel 100 may further include a touch part 17 disposed between the encapsulation layer 16 and the polarizer 18.

The substrate 110 may be formed of an insulating material or a material with flexibility. For example, the substrate 110 may be made of glass, metal, or plastic, but is not limited thereto. The substrate 110 may be a glass substrate having a predetermined strength for the etching process in order to simplify the process.

The circuit layer 12 may include a pixel circuit connected to wires such as data lines, gate lines, and power lines, and a gate driver connected to the gate lines. In addition, the wires and the circuit elements in the circuit layer 12 may include a plurality of insulating layers, two or more metal layers separated by an insulating layer interposed therebetween, and an active layer including a semiconductor material.

The light-emitting element layer 14 may include light-emitting elements driven by a pixel circuit. The light-emitting elements may include a red light-emitting element, a green light-emitting element, or a blue light-emitting element. In another embodiment, the light-emitting element layer 14 may include a white light-emitting element and a color filter. The light-emitting elements of the light-emitting element layer 14 may be covered with a protective layer including an organic film and a protective film.

The encapsulation layer 16 may cover the light-emitting element layer 14 so as to seal the circuit layer 12 and the light-emitting element layer 14. In some embodiments, the encapsulation layer 16 may also have a multi-insulating film structure in which an organic film and an inorganic film are alternately stacked. The inorganic film may prevent the penetration of moisture and oxygen and the organic film may planarize the surface of the inorganic film. In some embodiments, when the organic film and the inorganic film are stacked in multiple layers, the movement path of moisture or oxygen becomes longer than that of a single layer, so that penetration of moisture/oxygen affecting the light-emitting element layer 14 may be effectively blocked.

The touch part 17 may include capacitive touch sensors that sense touch inputs based on changes in capacitance before and after the touch inputs. The touch part 17 may include metal wire patterns and insulating films that form the capacitance of the touch sensors. The insulating films may insulate portions where the metal wire patterns are intersected and may planarize the surface of the touch part.

The polarizer 18 may be disposed on the light-emitting element layer 14. The polarizer 18 may improve outdoor visibility of the display device. For example, the polarizer may improve visibility and contrast ratio by converting the polarization of external light reflected by the metal patterns of the circuit layer 12. In some embodiments, the polarizer 18 may be implemented as a polarizing plate or circular polarizing plate in which a linear polarizing plate and a phase retardation film are bonded. The cover member 20 may be bonded on the polarizer 18. In some embodiments, the cover member 20 may be a cover glass.

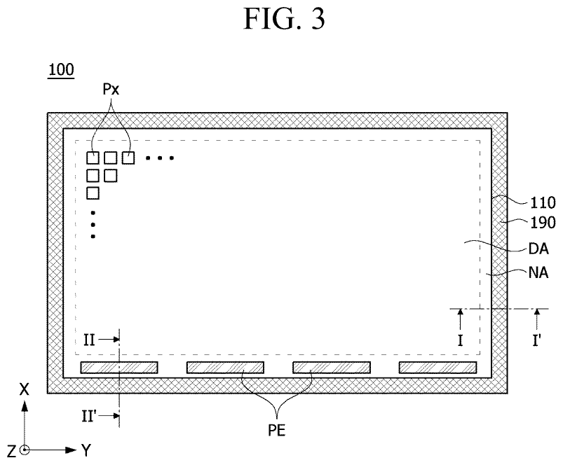

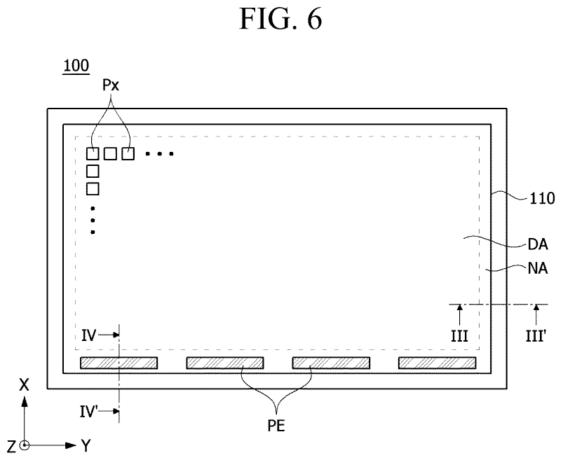

The display panel 100 shown in FIGS. 3 to 8 may represent a display panel according to a first embodiment.

As shown in FIGS. 3 to 8, the display panel 100 may include a substrate 110, a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, a first transistor TFT1, a second transistor TFT2, a storage capacitor SC, a storage supply line 120, a connection electrode 130, a light-emitting element 140, a spacer 150, a spacer layer 150L, a pad electrode PE, an encapsulation layer 16, a polarizer 18, a plurality of patterns PT, and a groove G. At least one of the plurality of patterns PT disposed parallel to an edge 100E of the display panel 100 may overlap an edge 110E of the substrate 110 in the Z-axis direction, or at least one of the plurality of patterns PT may be disposed adjacent to the edge 110E of the substrate 110 when viewed from the Z-axis direction. In some embodiments, the edge 100E of the display panel 100 may be referred to as a first edge, and the edge 110E of the substrate 110 may be referred to as a second edge. Thus, in the following description, the edge 100E of the display panel 100 will be described as the first edge and the edge 110E of the substrate 110 will be described as the second edge.

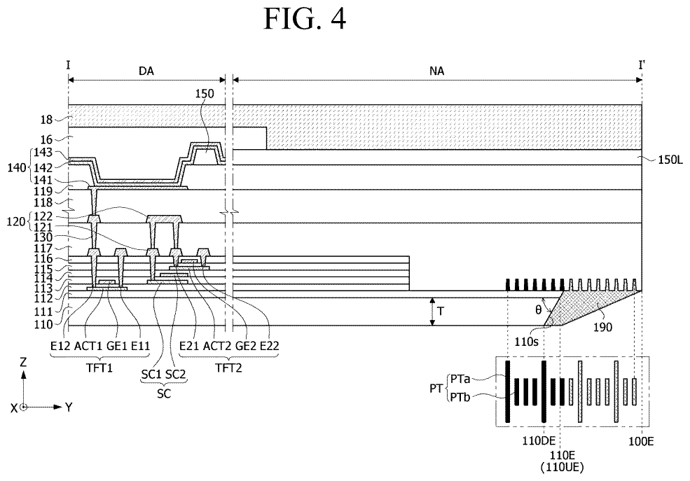

In some embodiments, the display device may monitor an edge position of the substrate 110 using a plurality of patterns PT disposed on the display panel 100 parallel to the first edge 100E of the display panel 100. In addition, the display device may measure the slope angle of an edge surface 110S of the substrate 110, which has been formed to have a predetermined slope by an etching process, by means of a plurality of patterns PT. Thus, the display device may manage the slope of the edge surface 110S of the substrate 110. The edge surface 110S of the substrate 110 may include a plane and may be referred to as an inclined surface. As shown in FIG. 4, the substrate 110 may include a plane and an inclined surface extending from the plane.

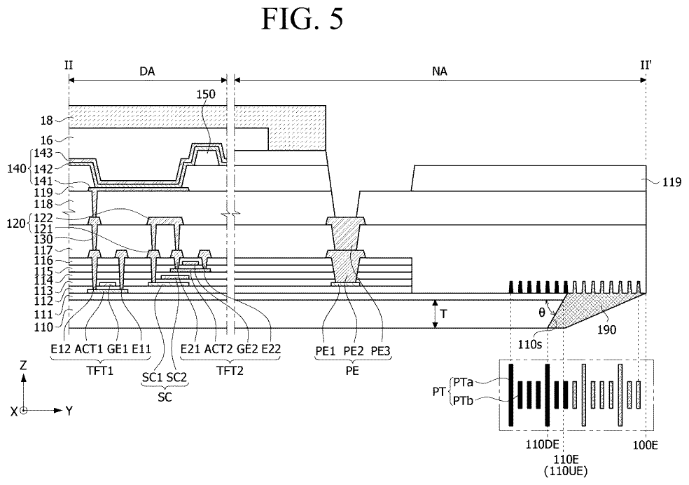

As shown in FIGS. 4-5, the display panel 100 may further include a side coating layer 190 disposed such that the side coating layer 190 covers the second edge 110E of the substrate 110, a portion of the first planarization layer 117 exposed by the etching process to form the second edge 110E, and the groove G formed by the etching process.

The substrate 110 may be configured to support various components included in the display panel 100 and may be made of an insulating material. For example, the substrate 110 may be formed of glass. However, the substrate 110 is not necessarily limited thereto and may further include a flexible material can be formed of a plastic film such as polyimide. The flexible materials can be selected from materials such as polyethylene terephthalate (PET), polyester, polycarbonate (PC), polymide (PI), polyethylene naphthalate (PEN), polyether ether ketone (PEEK), polyarylate (PAR), polycyclic olefin (PCO, polynorbornene, polyesthersulfone (PES) and cyclooefin polymers (COP).

The substrate 110 may include a display area DA and a non-display area NA.

In some embodiments, the display area DA is the area where an image is displayed on the display panel 100. A plurality of sub-pixels constituting a plurality of pixels Px and a circuit for driving the plurality of sub-pixels may be disposed in the display area DA. The light-emitting element 140, which includes an anode electrode 141, an emission layer 142, and a cathode electrode 143, may be disposed in the plurality of sub-pixels SP, but is not limited thereto. In addition, the circuit for driving the plurality of sub-pixels may include driving elements and wires. For example, the circuit may include, but is not limited to, transistors TFT1 and TFT2, a storage capacitor SC, a scan wire, and a data wire.

In some embodiments, the non-display area NA is an area where no image is displayed on the display panel 100. Various wires and circuits for driving the light-emitting element 140 of the display area DA may be disposed in the non-display area NA. For example, in the non-display area NA, a link wire for transmitting signals to the plurality of sub-pixels and the circuit disposed in the display area DA, and driving ICs such as a gate driver IC and a data driver IC may be disposed, but are not limited thereto. In some instances, the link wire may be called a link line.

A plurality of pad electrodes PE may be disposed in the non-display area NA. The plurality of pad electrodes PE may be electrically connected to a driving component, such as a flexible film and a flexible printed circuit (FPC), and the driving component may transmit various signals to the plurality of sub-pixels or the like via the pad electrodes PE. The pad electrodes PE may be electrically connected to the various signal wires connected to the plurality of sub-pixels. As shown in FIG. 3, four pad electrodes PE may be disposed in the lower non-displayed area NA by way of example, but are not necessarily limited thereto, and the number and the position of the pad electrodes PE may be varied.

The first buffer layer 111 may be disposed on the substrate 110. The first buffer layer 111 may delay the diffusion of moisture or oxygen that has penetrated into the substrate 110. In some embodiments, the first buffer layer 111 may be formed as a single layer of silicon nitride (SiNx) or silicon oxide (SiOx). In other embodiments, silicon nitride (SiNx) and silicon oxide (SiOx) may be alternately stacked at least once to form the first buffer layer 111.

A plurality of transistors may be disposed on the first buffer layer 111 so as to correspond to each of the plurality of sub-pixels. The plurality of transistors may include the first transistor TFT1 and the second transistor TFT2.

The plurality of transistors may be formed of different types of transistors. For example, one of the plurality of transistors may be a transistor having an oxide semiconductor as an active layer. In some embodiments, it may be advantageous to use oxide semiconductor materials due to their low off current, which may thus make them suitable for switching transistors with short turn-on times and long turn-off times.

The other one of the plurality of transistors may be a transistor having a low temperature poly silicon (LTPS) as an active layer. In some embodiments, poly silicon materials may be suitable for driving transistors due to their high mobility, low power consumption, and excellent reliability.

The plurality of transistors may be N-type or P-type transistors. In N-type transistors, since a carrier is an electron, electrons can flow from the source electrode to the drain electrode, and current may be able to flow from the drain electrode to the source electrode. In the P-type transistors, since a hole is a carrier, holes can flow from the source electrode to the drain electrode, and current may be able to flow from the source electrode to the drain electrode. For example, one transistor of the plurality of transistors may be an N-type transistor, and the other transistor of the plurality of transistors may be a P-type transistor.

The first transistor TFT1 may be disposed on the first buffer layer 111. The first transistor TFT1 may include a first active layer ACT1, a first gate electrode GE1, a first source electrode E11, and a first drain electrode E12.

The first active layer ACT1 may be disposed on the first buffer layer 111. The first active layer ACT1 may be made of a polycrystalline semiconductor layer and may include a channel region, a source region, and a drain region.

In some embodiments, the polycrystalline semiconductor layer has higher mobility than an amorphous semiconductor layer and an oxide semiconductor layer, resulting in lower energy consumption and excellent reliability. These advantages may allow the polycrystalline semiconductor layer to be used in driving transistors.

The first gate insulating layer 112 may be disposed on the first active layer ACT1 to cover the first active layer ACT1. A single layer of silicon oxide (SiOx) or silicon nitride (SiNx) or a multi-layer of silicon oxide (SiOx) and silicon nitride (SiNx) may be formed as an insulating layer for insulating the first gate insulating layer 112, the first active layer ACT1 and the first gate electrode GE1.

The first gate electrode GE1 may be disposed on the first gate insulating layer 112 and may be disposed so as to overlap the first active layer ACT1. The first gate electrode GE1 may be formed of a conductive material, such as, but not limited to, copper (Cu), aluminum (Al), molybdenum (Mo), nickel (Ni), titanium (Ti), chromium (Cr), or an alloy thereof.

The first interlayer insulating layer 113, the second buffer layer 114, the second gate insulating layer 115, and the second interlayer insulating layer 116 may be disposed on the first gate electrode GE1.

The first interlayer insulating layer 113 may be disposed on the first gate insulating layer 112 so as to cover the first gate electrode GE1 and the first capacitor electrode SC1 of the storage capacitor SC. In some embodiments, the first interlayer insulating layer 113 may be formed as a single layer of silicon oxide (SiOx) or silicon nitride (SiNx) or a multi-layer of silicon oxide (SiOx) and silicon nitride (SiNx).

The second buffer layer 114 may be disposed on the first interlayer insulating layer 113 so as to cover the second capacitor electrode SC2 of the storage capacitor SC. In some embodiments, the second buffer layer 114 may be formed as a single layer of silicon oxide (SiOx) or silicon nitride (SiNx), or as a multi-layer of silicon oxide (SiOx) and silicon nitride (SiNx).

The second gate insulating layer 115 may be disposed on the second buffer layer 114 so as to cover the second active layer ACT2 of the second Transistors TFT2. Thus, the second gate insulating layer 115 may insulate the second active layer ACT2 and the second gate electrode GE2 of the second transistor TFT2. The second gate insulating layer 115 may be formed as a single layer of silicon oxide (SiOx) or silicon nitride (SiNx) or a multi-layer of silicon oxide (SiOx) and silicon nitride (SiNx).

The second interlayer insulating layer 116 may be disposed on the second gate insulating layer 115 so as to cover the second gate electrode GE2 of the second transistor TFT2. The second interlayer insulating layer 116 may be formed as a single layer of silicon oxide (SiOx) or silicon nitride (SiNx) or a multi-layer of silicon oxide (SiOx) and silicon nitride (SiNx).

A portion of the first source electrode E11 and a portion of the first drain electrode E12 that is spaced apart from each other may be disposed on the second interlayer insulating layer 116. The first source electrode E11 and the first drain electrode E12 may be electrically connected to the first active layer ACT1 through a contact hole formed to penetrate the second interlayer insulating layer 116, the second gate insulating layer 115, the second buffer layer 114, and the first interlayer insulating layer 113. The first source electrode E11 and the first drain electrode E12 may be a single layer or a multi-layer formed of a conductive material, for example, but not limited to, copper (Cu), aluminum (Al), molybdenum (Mo), nickel (Ni), titanium (Ti), chromium (Cr), or an alloy thereof. For example, the first source electrode E11 and the first drain electrode E12 may be formed as a three-layer structure including a first layer made of titanium (Ti), a second layer made of aluminum (Al), and a third layer made of titanium (Ti).

The second transistor TFT2 may be disposed on the second buffer layer 114. The second transistor TFT2 may include a second active layer ACT2, a second gate electrode GE2, a second source electrode E21, and a second drain electrode E22.

The second active layer ACT2 may be disposed on the second buffer layer 114. The second active layer ACT2 may be formed of an oxide semiconductor and may include a channel region, a source region, and a drain region.

The second gate insulating layer 115 may be disposed on the second buffer layer 114 so as to cover the second active layer ACT2.

The second gate electrode GE2 may be disposed on the second gate insulating layer 115 and may be disposed so as to overlap the second active layer ACT2. The second gate electrode GE2 may be formed of a conductive material, such as, but not limited to, copper (Cu), aluminum (Al), molybdenum (Mo), nickel (Ni), titanium (Ti), chromium (Cr), or an alloy thereof.

The second interlayer insulating layer 116 may be disposed on the second gate insulating layer 115 so as to cover the second gate electrode GE2.

In some embodiments, a portion of the second source electrode E21 and a portion of the second drain electrode E22 are spaced apart from each other and are disposed on the second interlayer insulating layer 116. The second source electrode E21 and the second drain electrode E22 may be electrically connected to the second active layer ACT2 through a contact hole formed to penetrate the second interlayer insulating layer 116 and the second gate insulating layer 115. The second source electrode E21 and the second drain electrode E22 may be a single layer or a multi-layer formed of a conductive material, for example, but not limited to, copper (Cu), aluminum (Al), molybdenum (Mo), nickel (Ni), titanium (Ti), chromium (Cr), or an alloy thereof. For example, the second source electrode E21 and the second drain electrode E22 may be formed as a three-layer structure including a first layer made of titanium (Ti), a second layer made of aluminum (Al), and a third layer made of titanium (Ti).

The first source electrode E11 and the first drain electrode E12 corresponding to the first transistor TFT1 and the second source electrode E21 and the second drain electrode E22 corresponding to the second transistor TFT2 may be formed by the same mask process. This may reduce the number of processes required to form the source and drain electrodes of each of the first transistor TFT1 and the second transistor TFT2.

The storage capacitor SC may be disposed on the first gate insulating layer 112. The storage capacitor SC may store a constant voltage to keep the voltage level at the gate electrode of the driving transistor constant while the light-emitting element 140 is emitting light, and may ensure that a constant driving current is supplied to the light-emitting element 140.

The storage capacitor SC may include a plurality of capacitor electrodes. The storage capacitor SC may include the first capacitor electrode SC1 and the second capacitor electrode SC2.

The first capacitor electrode SC1 may be disposed on the first gate insulating layer 112. The first capacitor electrode SC1 may be formed of a conductive material, such as, but not limited to, copper (Cu), aluminum (Al), molybdenum (Mo), nickel (Ni), titanium (Ti), chromium (Cr), or an alloy thereof.

The first interlayer insulating layer 113 may be disposed on the first capacitor electrode SC1, and the second capacitor electrode SC2 overlapping the first capacitor electrode SC1 may be disposed on the first interlayer insulating layer 113. The second capacitor electrode SC2 may be formed of a conductive material, such as, but not limited to, copper (Cu), aluminum (Al), molybdenum (Mo), nickel (Ni), titanium (Ti), chromium (Cr), or an alloy thereof.

The first planarization layer 117 may be disposed on the first transistor TFT1, the second transistor TFT2, and the storage capacitor SC. The first planarization layer 117 may planarize upper portions of the first transistor TFT1, the second transistor TFT2, and the storage capacitor SC. Further, the first planarization layer 117 may extend up to the non-display area NA. The first planarization layer 117 may be formed of an organic insulating material. For example, the first planarization layer 117 may be formed of, but is not limited to, photoresist materials or acrylic organic materials.

The storage supply line 120 may electrically connect the storage capacitor SC and the second transistor TFT2.

The storage supply line 120 may include a first storage electrode 121 and a second storage electrode 122.

The first storage electrode 121 may be disposed on the second interlayer insulating layer 116. And the first storage electrode 121 may be electrically connected to the storage capacitor SC through a contact hole formed to penetrate the second interlayer insulating layer 116, the second gate insulating layer 115, the second buffer layer 114, and the first interlayer insulating layer 113. The first storage electrode 121 may be formed of the same material as the first source electrode E11, the first drain electrode E12, the second source electrode E21, and the second drain electrode E22. Thus, the first storage electrode 121 may be formed by the same mask process as the first source electrode E11, the first drain electrode E12, the second source electrode E21, and the second drain electrode E22.

The second storage electrode 122 may be disposed on the first planarization layer 117. Also the second storage electrode 122 may be electrically connected to the second source electrode E21 and the first storage electrode 121 through a contact hole formed in the first planarization layer 117. The second storage electrode 122 may be formed of a conductive material, such as, but not limited to, copper (Cu), aluminum (Al), molybdenum (Mo), nickel (Ni), titanium (Ti), chromium (Cr), or an alloy thereof. Further, the second storage electrode 122 may be formed of the same material as the connection electrode 130. Thus, the second storage electrode 122 may be formed by the same mask process as the connection electrode 130.

The connection electrode 130 may be disposed on the first planarization layer 117. The connection electrode 130 may electrically connect the first transistor TFT1 and the light-emitting element 140. The connection electrode 130 may be electrically connected to the first transistor TFT1 through a contact hole formed in the first planarization layer 117. The connection electrode 130 may be formed of a conductive material, such as, but not limited to, copper (Cu), aluminum (Al), molybdenum (Mo), nickel (Ni), titanium (Ti), chromium (Cr), or an alloy thereof. For example, the connection electrode 130 may be formed as a three-layer structure like the first source electrode E11 and the drain electrode E12.

The second planarization layer 118 may be disposed on the storage supply line 120 and the connection electrode 130. The second planarization layer 118 may planarize upper portions of the storage supply line 120 and the connection electrode 130. In addition, the second planarization layer 118 may extend up to the non-display area NA. The second planarization layer 118 may be formed of an organic insulating material. For example, the second planarization layer 118 may be formed of, but is not limited to, photoresist materials or acrylic organic materials.

The light-emitting element 140 may be disposed on the second planarization layer 118. The light-emitting element 140 is a spontaneous emission element that emits light, and may include an anode electrode 141, an emission layer 142, and a cathode electrode 143.

The anode electrode 141 may be connected to the exposed connection electrode 130 through a contact hole in the second planarization layer 118. The anode electrode 141 may be formed as a multi-layer structure including a transparent conductive film and an opaque conductive film with high reflective efficiency. The transparent conductive film may be made of material having a relatively large work function value, such as indium-tin-oxide (ITO) or indium-zinc-oxide (IZO), and the opaque conductive films may be formed as a single layer structure or a multi-layer structure containing Al, Ag, Cu, Pb, Mo, Ti, or alloys thereof. For example, in some embodiments, the anode electrode 141 may be formed of a transparent conductive film, and in other embodiments the anode electrode 141 may be formed of a structure in which opaque and transparent conductive films are sequentially stacked.

The anode electrode 141 may be disposed on the second planarization layer 118 so as to overlap an emission region arranged by the bank 119 as well as a pixel circuit region where the first and second transistors TFT1 and TFT2 and the storage capacitor SC are disposed.

The bank 119 may be formed on the second planarization layer 118 to expose the anode electrodes 141. In this case, the bank 119 may be disposed so as to cover the periphery of the anode electrode 141 and may be disposed at the boundaries between adjacent sub-pixels to reduce the color mixing of light emitted from the light-emitting element 140 of each of the plurality of sub-pixels. In addition, the bank 119 may cover the display area DA as well as the non-display area NA disposed at the periphery of the display area DA.

The bank 119 may be formed of an organic material, such as photoacrylic, and may be formed of, but is not limited to, translucent materials. For example, the bank 119 may also be formed of an opaque material to prevent light interference between the sub-pixels.

The emission layer 142 may be disposed on the anode electrode 141 exposed by the bank 119.

The emission layer 142 may include a hole injection layer, a hole transport layer, an organic emission layer, an electron transport layer, and an electron injection layer, and, in a tandem structure in which a plurality of organic emission layers overlap, it may further include a charge generation layer additionally disposed between the organic emission layer and the organic emission layer. For example, the emission layer 142 may include first and second organic emission layers facing each other with the charge generating layer interposed therebetween. In some embodiments, in the case of the organic emission layer, different colors may be emitted for each sub-pixel.

The cathode electrode 143 may be disposed on the emission layer 142 to face the anode electrode 141 with the emission layer 142 interposed therebetween. In this case, the cathode electrode 143 may be disposed over the entirety of the plurality of sub-pixels. For example, the light-emitting element 140 of each of the plurality of sub-pixels may share the cathode electrode 143.

When the cathode electrode 153 is employed in a top emission type organic light-emitting display, the cathode electrode 153 may be formed of a thin transparent conductive film of indium-tin-oxide (ITO), indium-zinc-oxide (IZO), or magnesium-silver (Mg—Ag).

The spacer 150 may be disposed between the bank 119 and the emission layer 142. The spacer 150 may support a fine metal mask (FMM), which is a deposition mask used to form the emission layer 142. In this case, the spacer 150 may be formed into a shape that narrows in width toward the top, thereby minimizing contact with the deposition mask. The spacer 150 may be formed of an organic insulating material, such as, but not limited to, a polyimide, acrylic, or benzocyclobytene (BCB) resin.

A spacer layer 150L may be disposed in the non-display area NA and may be formed of the same material and by the same process as the spacer 150. The spacer layer 150L may cover the bank 119 in the non-displayed area NA.

The encapsulation layer 16 may be disposed on the light-emitting element 140. Further, the encapsulation layer 16 may cover a portion of the spacer layer 150L that is disposed in the non-display area NA.

The encapsulation layer 16 may seal the light-emitting element 140, thereby protecting the light-emitting element 140 from external moisture, oxygen, shock, and the like.

The encapsulation layer 16 may be formed in a variety of structures depending on design requirements and desires. For example, the encapsulation layer 16 may be formed in a multi-insulating film structure in which inorganic films made of inorganic materials and organic films made of organic materials are alternately stacked. In some embodiments, the inorganic film may be formed of inorganic materials such as silicon oxide (SiOx), silicon nitride (SiNx), and aluminum oxide (AlOx), and the organic film may be formed of polymers such as, but not limited to, epoxy or acryl polymers. For example, the encapsulation layer 16 may be formed of a metallic material such as aluminum (Al), nickel (Ni), chromium (Cr), iron (Fe), or an alloy material of nickel with iron, which has strong corrosion resistance and is easy to process.

The polarizer 18 may be disposed in the display area DA and the non-display area NA. In the display area DA, the polarizer 18 may be disposed on the encapsulation layer 16. In some cases, the polarizer 18 may be omitted from the display device.

The polarizer 18 may improve outdoor visibility of the display device. The polarizer 18 may reduce light reflected from the surface of the display panel and block light reflected from the metal of the circuit layer 12, thereby improving the brightness of the pixels.

As shown in FIGS. 3 and 5, the pad electrode PE may be disposed in the non-display area NA. The pad electrode PE may include a first pad electrode PE1, a second pad electrode PE2, and a third pad electrode PE3.

The first pad electrode PE1 may be disposed on the first gate insulating layer 112. The first pad electrode PE1 may be connected to various wires disposed in the display area DA and may carry signals from the flexible printed circuit (FPC) to each of the sub-pixels.

The first pad electrode PE1 may be formed of a conductive material, such as, but not limited to, copper (Cu), aluminum (Al), molybdenum (Mo), nickel (Ni), titanium (Ti), chromium (Cr), or an alloy thereof. The first pad electrode PE1 may be formed together with the first capacitor electrode SC1 in the process of forming the first capacitor electrode SC1, but is not necessarily limited thereto.

The second pad electrode PE2 may be disposed on the first pad electrode PE1 and electrically connected to the first pad electrode PE1. For example, the second pad electrode PE2 may be electrically connected to the first pad electrode PE1 through a contact hole formed in the second interlayer insulating layer 116, the second gate insulating layer 115, the second buffer layer 114, and the first interlayer insulating layer 113.

The second pad electrode PE2 may be formed of a conductive material, such as, but not limited to, copper (Cu), aluminum (Al), molybdenum (Mo), nickel (Ni), titanium (Ti), chromium (Cr), or an alloy thereof. The second pad electrode PE2 may be formed together with the first source electrode E11, the first drain electrode E12, the second source electrode E21, and the second drain electrode E22 in a process of forming the first source electrode E11, the first drain electrode E12, the second source electrode E21, and the second drain electrode E22, but is not necessarily limited thereto.

The third pad electrode PE3 may be disposed on the second pad electrode PE2 and electrically connected to the second pad electrode PE2. For example, the third pad electrode PE3 may be electrically connected to the second pad electrode PE2 through a contact hole formed in the first planarization layer 117.

The third pad electrode PE3 may be formed of a conductive material, such as, but not limited to, copper (Cu), aluminum (Al), molybdenum (Mo), nickel (Ni), titanium (Ti), chromium (Cr), or an alloy thereof. The third pad electrode PE3 may be formed together with the connection electrode 130 and the like in the process of forming the connection electrode 130 and the like, but is not necessarily limited thereto.

Further, the third pad electrode PE3 may be electrically connected to a flexible printed circuit (FPC) or the like through a contact hole formed in the second planarization layer 118 and the bank 119. Thus, in some embodiments, the polarizer 18 may not be disposed so that the third pad electrode PE3 is exposed. For example, when the pad electrode PE is disposed in the non-display area NA, the polarizer 18 may be disposed such that the third pad electrode PE3 is not exposed.

Meanwhile, most of the inorganic insulating layers formed by the inorganic insulating materials in the non-display area NA may be disposed inwardly relative to the second edge 110E of the substrate 110 formed by the etching process. In some embodiments, the second edge 110E of the substrate 110 may represent a corner of the substrate 110 that is disposed at the outermost side, wherein the corner of the substrate 110 may be rounded by the etching process. For example, the inorganic insulating layers may include a first buffer layer 111, a first gate insulating layer 112, a first interlayer insulating layer 113, a second buffer layer 114, a second gate insulating layer 115, and a second interlayer insulating layer 116. Most of the inorganic insulating layers, except for the first buffer layer 111, may be disposed such that a portion thereof are spaced apart from the second edge 110E of the substrate 110 in the non-display area NA. Thus, the inorganic insulating layers disposed so as to be spaced apart from the second edge 110E of the substrate 110 may not be exposed to the etchant used in the etching process to etch the substrate 110, and thus may be prevented from being etched by the etchant. As used herein, the term inward may refer to a direction toward the center of the display panel 100, and the term outward may refer to a direction opposite to the inward.

Although it has been described as an example that the first buffer layer 111 shown in FIG. 4 is disposed over the entirety of the substrate 110 and a partial area thereof is exposed to the etchant used in the etching process to etch the substrate 110, but the first buffer layer 111 need not be so limited. For example, the first buffer layer 111 may also be spaced apart from the second edge 110E of the substrate 110, and thus may not be exposed to the etchant.

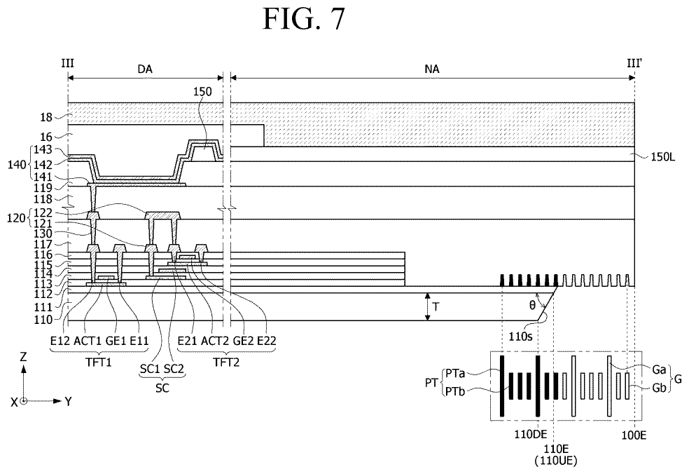

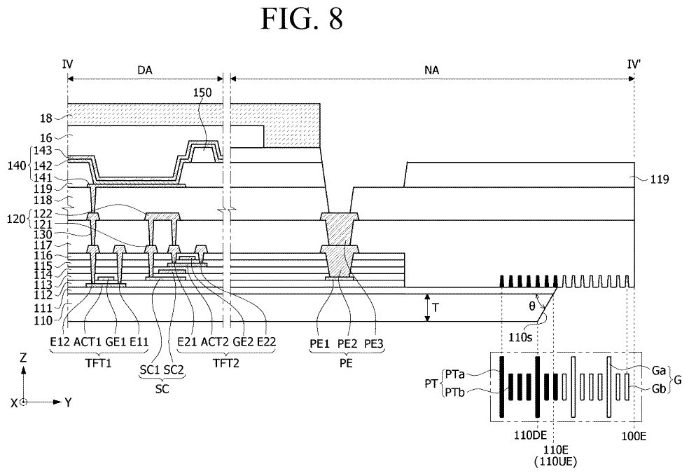

The first planarization layer 117, the bank 119, and the spacer layer 150L formed of organic insulating material may be disposed such that partial areas thereof project outwardly relative to the second edge 110E of the substrate 110. Thus, the first planarization layer 117, the bank 119, and the spacer layer 150L may form the first edge 100E of the display panel 100. As the organic insulating material may form the second edge 110E of the substrate 110, the inorganic insulating material that is relatively weak against cracks may not be exposed to the outside. As a result, when an external impact is applied, the propagation of cracks through the inorganic insulating material may be prevented in advance. In other words, the first edge 100E and the side surface of the display panel 100 may be formed using the organic insulating material, thereby improving the shock resistance thereof. In this case, as a portion of the substrate 110 is etched by the etching process of forming the edge surface 110S of the substrate 110, a partial area of the first planarization layer 117 may be disposed so as to protrude outward relative to the second edge 110E of the substrate 110. When a lower portion of the partial area of the first planarization layer 117 is exposed by the etching process, some of the plurality of patterns PT may be etched to form a groove G concavely in the lower portion of the partial area of the first planarization layer 117. For example, as shown in FIGS. 7 and 8, the groove G may be concavely formed in a lower portion of the partial are of the first planarization layer 117. Furthermore, as shown in FIGS. 4 and 5, the side coating layer 190 may be disposed in the groove G.

The first planarization layer 117 may serve as an etch stop layer to prevent the etchant from penetrating into the inside of the display panel 100. For example, when the second edge 110E of the substrate 110 is formed by the etching process, the first planarization layer 117 may prevent the etchant from penetrating into the inside of the display panel 100 even though the first buffer layer 111 is etched.

In some embodiments, the side coating layer 190 may be disposed to cover a lower portion of the first planarization layer 117 that is exposed by the etching process for forming the second edge 110E and the second edge 110E of the substrate 110. For example, the side coating layer 190 may be disposed on the lower portion of the first planarization layer 117 while being disposed outwardly relative to the second edge 110E of the substrate 110. Thus, the side coating layer 190 may protect the display panel 100 by forming a lower corner of the display panel 100. Although it has been described as an example that the side coating layer 190 is formed at the lower corner of the display panel 100, it is not necessarily limited thereto, and the side coating layer 190 may also be disposed on a rear surface of the substrate 110. A surface on which the image is displayed on the display panel 100 may be referred to as the front surface, and the rear surface may refer to a surface opposite to the front surface.

The side coating layer 190 may be formed of an organic insulating material, including polyester polymers, acrylic polymers, and the like. For example, the side coating layer 190 may be formed of, but is not limited to, insulating materials such as polyimide (PI), poly urethane, epoxy, acryl materials, or the like.

The plurality of patterns PT may be disposed so as to be spaced apart from each other at predetermined intervals on the lower portion of the first planarization layer 117. The plurality of patterns PT may be disposed in an area adjacent to the second edge 110E of the substrate 110. The plurality of patterns PT may overlap the substrate 110. In this case, the plurality of patterns PT may be disposed between the first buffer layer 111 and the first planarization layer 117 disposed on the substrate 110. In some embodiments, the patterns PT that overlap the first buffer layer 111 may be referred to as first lower patterns, and the patterns PT may be referred to as a first lower pattern group.

When the periphery of the substrate 110 is etched, the plurality of patterns PT may serve as a kind of scale for monitoring an amount of etching of the substrate 110 and a position of an edge of the substrate 110 formed by the etching process. For example, the edge position of the substrate 110 may be determined by recognizing a pattern PT, which is located at the outermost side of the substrate 110 and is overlapped with the second edge 110E, among the plurality of patterns PT. Alternatively, the edge position of the substrate 110 may be identified by recognizing a pattern PT, which is located at the outermost side of the substrate 110 and is adjacent to the second edge 110E, among the plurality of patterns PT. In some embodiments, the substrate 110 includes a top edge 110UE and a bottom edge 110DE that are spaced apart from each other in the Z-axis direction. The top edge 110UE, which may be located at the outermost side of the substrate 110 in the Y-axis direction and may represent the second edge 110E of the substrate 110, as shown in FIG. 4. In some embodiments, the top edge 110UE may be a corner of the upper surface of the substrate 110. The upper surface of the substrate 110 may be a surface disposed to face the first buffer layer 111 or a surface in contact with the first buffer layer 111, and may be referred to as a first surface or a front surface of the substrate 110. The bottom edge 110DE may be a corner of the lower surface of the substrate 110. The lower surface of the substrate 110 may be a surface opposite to the upper surface and may be referred to as the second surface or the rear surface of the substrate 110. Thus, the top edge 110UE and the bottom edge 110DE of the substrate 110 may be positioned in the outermost region of the substrate 110.

In some embodiments, when the thickness T of the substrate 110 is measured, the slope angle of the edge surface 110S is formed to have a predetermined slope and may be measured by means of the patterns PT overlapping the edge surface 110S of the substrate 110 in the Z-axis direction. The edge surface 110S may be a side surface of the substrate 110 connecting the top edge 110UE and the bottom edge 110DE. As shown in FIG. 4, when the edge surface 110S is formed to have a predetermined slope by the etching process, the thickness of the edge surface 110S may decrease from the bottom edge 110DE to the top edge 110UE. Thus, when viewed from the Z-axis direction, there may be a contrast difference according to the thickness of the edge surface 110S. The slope angle of the edge surface 110S may be measured by using the contrast difference and the patterns PT overlapping the edge surface 110S. Moreover, based on the measured slope angle of the edge surface 110S, the edge surface 110S may be managed by adjusting the extent of spraying of the etchant. For example, a slope angle θ of the edge surface 110S may be measured by using the distance between a pattern PT overlapping the top edge 110UE of the substrate 110 and a pattern PT overlapping the bottom edge 110DE and the thickness T of the substrate 110. The measured slope angle θ may then make it possible to manage the slope of the edge surface 110S.

The plurality of patterns PT may be disposed parallel to the second edge 110E of the substrate 110 so as to easily measure the position of the second edge 110E of the substrate 110. For example, a planar shape of each of the plurality of patterns PT may be formed into a rectangular shape elongated from the outermost region of the substrate 110. And the plurality of patterns PT may be spaced apart from each other so as to have the same interval.

The plurality of pattern PT may include a plurality of main patterns PTa and a plurality of sub-patterns PTb. For example, a plurality of sub-patterns PTb may be located between two main patterns PTa. Therefore, the interval between two main patterns PTa may be larger than the interval between two sub-patterns PTb.

The plurality of main patterns PTa may have a longer length than the plurality of sub-patterns PTb. Thus, the plurality of main patterns PTa may enable a rough position of the second edge 110E of the substrate 110 to be identified, and the plurality of sub-patterns PTb may enable a fine position of the second edge 110E of the substrate 110 to be measured. For example, the plurality of main patterns PTa may indicate a scale of 10 units and the plurality of sub-patterns PTb may indicate a scale of 2.5 units, but are not necessarily limited thereto, and the number and the interval of the plurality of main patterns PTa and the plurality of sub-patterns PTb may be varied. The range of process error due to etching may be expressed as ±k μm, where k is a constant. Thus, by setting the width W of the pattern PT to 2 k μm, the detailed position of the second edge 110E of the substrate 110 may be more easily measured while easily responding to the range of process error. For example, if the width W of the pattern PT is set to 50 μm when the range of the process error due to the etching of the substrate 110 is ±25 μm, even though the second edge 110E of the substrate 110 overlaps either one of the two patterns PT indicating the range for determining a display panel corresponding to the second edge 110E of the substrate 110 as a normal panel, the display panel may be determined as a normal panel even if the range of the process error is not considered.

The plurality of patterns PT may be formed of materials, such as inorganic materials and/or metal materials that may be etched together by an etchant when the substrate 110 formed of glass is etched. Since the etchant containing hydrofluoric acid and nitric acid may etch inorganic materials, metallic materials, or the like in addition to glass, the patterns PT may also be etched together with the substrate 110 during the etching process. In the case where the plurality of patterns PT are made of inorganic materials only, the patterns PT may be formed together with the inorganic materials when any of the inorganic insulating layers disposed on the first buffer layer 111 is formed, or may be formed by a separate process. In addition, in the case where the plurality of patterns PT are made of metal materials, the patterns PT may be formed by the same process and with the same materials as the various electrodes and wires formed on the substrate 110, or may be formed by a separate process. For example, the plurality of patterns PT may be a single or a multi-layer formed of a conductive material, e.g., but not limited to, copper (Cu), aluminum (Al), molybdenum (Mo), nickel (Ni), titanium (Ti), chromium (Cr), or an alloy thereof. For example, the plurality of patterns PT may be formed as a three-layer structure including a first layer made of titanium (Ti), a second layer made of aluminum (Al), and a third layer made of titanium (Ti). For example, the plurality of patterns PT may be formed together with the first source electrode E11 or the like when the first source electrode E11 or the like is formed. In the case where the plurality of patterns PT are made of a metal material, the positions of the plurality of patterns PT may be more easily identified by the naked eye by using reflective characteristics of the metal material.

As some of the plurality of patterns PT are etched during the etching process of the substrate 110, a lower portion of a partial area of the first planarization layer 117 may be exposed. And since the lower portion of the partial area of the first planarization layer 117 is exposed, some of the plurality of patterns PT may also be exposed to the etchant. Accordingly, some of the plurality of patterns PT may be etched to form a plurality of grooves G concavely in the lower portion of the first planarization layer 117.

The groove G may be concavely formed in a lower surface of the first planarization layer 117. Here, the lower surface of the first planarization layer 117 may represent a surface disposed to face the first buffer layer 111. When the side coating layer 190 is then formed, the inside of the groove G may be filled with a material forming the side coating layer 190. For example, the plurality of patterns PT are respectively disposed in the plurality of grooves G during the manufacturing of the display panel 100, but some of the patterns PT may be removed during the etching process of the substrate 110 and the first buffer layer 111, exposing the grooves G to the outside. The etched area of the substrate 110 etched by the etchant may be provided as an opening, and the groove G of the first planarization layer 117 is also exposed by the opening. When the side coating layer 190 is disposed in the etched area, the inside of the groove G may be filled with the side coating layer 190.

The plurality of grooves G may be disposed parallel to the edge 110E of the substrate 110. For example, since the plurality of patterns PT are disposed parallel to the edge 110E of the substrate 110 and the first planarization layer 117 acts as an etch stop layer, the plurality of patterns PT may be etched by the etchant. Thus, a planar shape of the plurality of grooves G may be formed into a rectangular shape elongated along the edge 110E of the substrate 110, which may be the same as the shape of the pattern PT.

Since the plurality of patterns PT includes a plurality of main patterns PTa and a plurality of sub-patterns PTb, the plurality of grooves G may include a plurality of main grooves Ga and sub-grooves Gb. Here, a main groove Ga is a space in which a main pattern PTa was placed, and may be called a first groove. A sub-groove Gb is a space in which a sub-pattern PTb was placed, and may be called a second groove.

The plurality of main grooves Ga may have a longer length than the plurality of sub-grooves Gb. Further, the interval between the plurality of main grooves Ga may be larger than the interval between the plurality of sub-grooves Gb. The planar shape of the main groove Ga may be the same as the planar shape of the main pattern PTa, and the planar shape of the sub-groove Gb may be the same as the planar shape of the sub-pattern PTb.

Thus, even before the side coating layer 190 is formed, a rough position of the second edge 110E of the substrate 110 may be identified by the plurality of main grooves Ga and the main pattern Pta, and a detailed position of the second edge 110E of the substrate 110 may be determined by the plurality of sub-patterns PTb. For example, the plurality of main grooves Ga may indicate a scale of 10 units like the main pattern PTa, and the plurality of sub-grooves Gb may indicate a scale of 2.5 units like the sub-pattern PTb, but are not limited thereto, and the number and the interval of the plurality of main grooves Ga and the plurality of sub-patterns PTb may be varied.

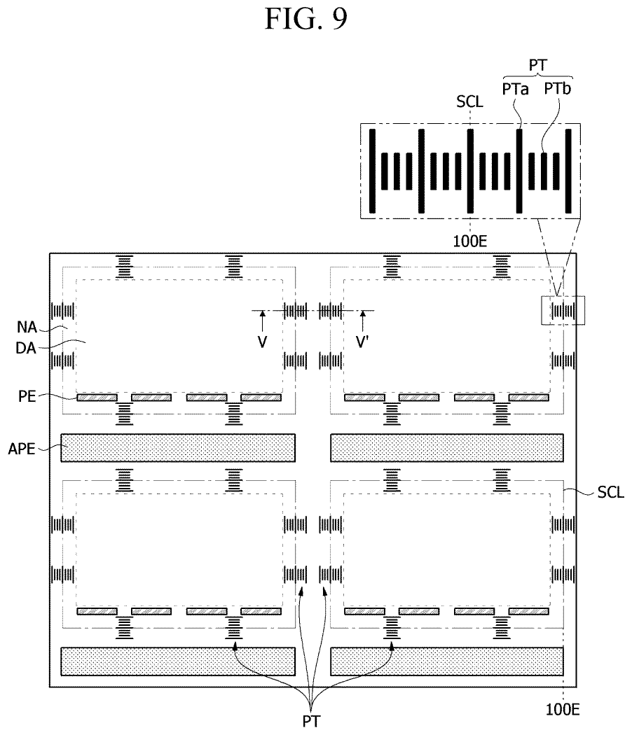

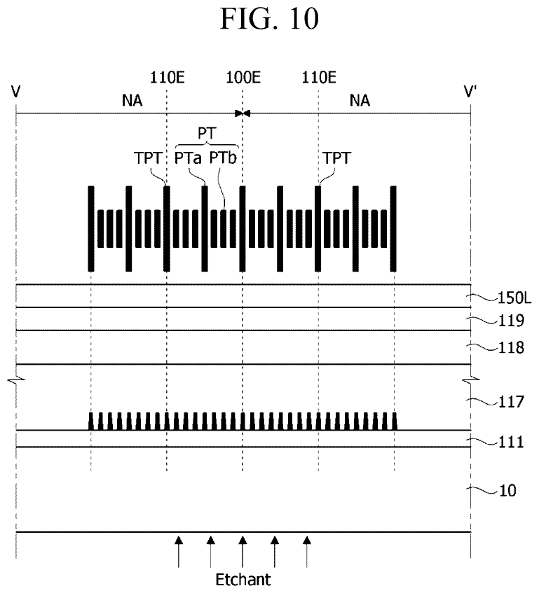

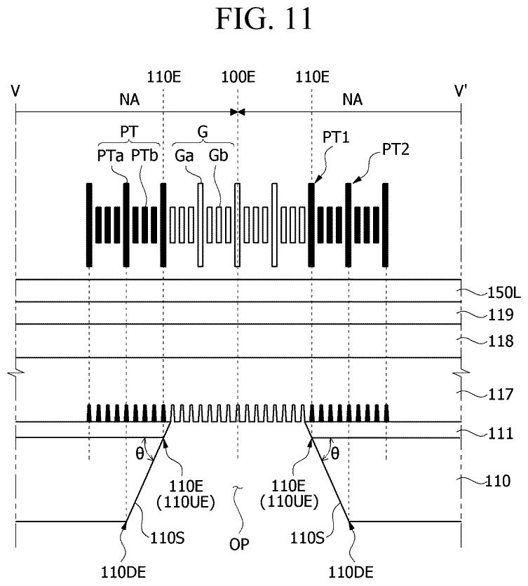

FIG. 9 is a plan view of a mother glass substrate for explaining a method of manufacturing a display device according to one embodiment of the present specification, and FIGS. 10 and 11 are cross-sectional views taken along lines V-V′ in FIG. 9 illustrating an etching process. Specifically, FIG. 10 is a cross-sectional view of a mother glass substrate 10 before the etching process, and FIG. 11 is a cross-sectional view of a mother glass substrate 10 after the etching process.

As shown in FIG. 9, the mother glass substrate 10 is a substrate for manufacturing a plurality of display panels 100 at one time, and a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, and the like corresponding to each of the plurality of display panels 100 may be disposed on the mother glass substrate 10.

The mother glass substrate 10 may be made of glass, such as the substrate 110 of the display panel 100. A manufacturing process for a plurality of display panels 100 on a single mother glass substrate 10 may be carried out simultaneously, and the mother glass substrate 10 may then be cut and divided into a plurality of display panels 100.

A plurality of inspection pads APE may be disposed on the mother glass substrate 10. Each of the plurality of inspection pads APE may be formed corresponding to each of the plurality of display panels 100. The plurality of inspection pads APE may be provided to inspect whether the display panels 100 formed on the mother glass substrate 10 are defective. Thus, whether sub-pixels are emitted or not may be inspected by the plurality of inspection pads APE.

The plurality of inspection pads APE may be electrically connected to the respective pad electrodes PE of the plurality of display panels 100. When an inspection signal is applied to the plurality of inspection pads APE, the inspection signal may be applied to a plurality of sub-pixels disposed in the display area DA via the inspection pads APE and the pad electrodes PE, thereby performing the inspection as to whether the sub-pixels are emitted. Although not shown in drawings, an inspection wire may be formed on the mother glass substrate 10 for electrically connecting each of the plurality of inspection pads APE to the pad electrode PE of the display panel 100.

After the manufacturing process of the display panel 100 on the mother glass substrate 10 is completed, the mother glass substrate 10 may be cut into a plurality of pieces along a scribing line SCL. In a scribing process of cutting the mother glass substrate 10 into a plurality of pieces, the plurality of inspection pads APE are separated from the display panels 100, so that no inspection pads APE remain on the display panels 100.

In some embodiments, the display device uses an etching process on the substrate 110 such that the sharpness of the side surfaces of the substrate 110 may be reduced while also maintaining the stiffness of the substrate 110. As such, the display device may not necessarily require separate grinding or smoothing of the surface.

In addition, in some embodiments, the display device may form various openings in the substrate 110 by using an etching process.

Furthermore, in some embodiments, the display device may omit a separate finishing process for the substrate 110 by means of the etching process. Thus, the display device may enable low-power operation of the manufacturing process in terms of reducing manufacturing energy by the simplified process. For example, the display device according may omit a finishing process for the edge of the substrate 110 by forming an opening by the etching process on a partial area of the mother glass substrate 10 corresponding to the scribing lines SCL. Here, the opening may be formed to have a tapered shape.

However, in the case where an etchant is used to cut the mother glass substrate 10, it may be difficult to accurately control the amount of etching of the substrate 110 as compared to a physical method. In contrast, a method of manufacturing the display panel 100 and the display device according to one embodiment of the present disclosure may allow the edge position of the substrate 110 to be easily measured by means of the plurality of patterns PT according to the amount of etching of the substrate 110 and, based thereon, the etching process to be controlled.

As shown in FIGS. 9 to 11, a plurality of patterns PT may be disposed to correspond to the second edge 110E of the substrate 110 on the mother glass substrate 10. For example, the plurality of patterns PT are disposed to correspond to each of the four sides of the substrate 110, and may be disposed parallel to the four sides. In this case, a scribing line SCL is disposed between the second edges 110E of the substrate 110 that are disposed adjacent to each other. Thus, the plurality of patterns PT may be disposed on both sides of the scribing line SCL with respect to the scribing line SCL. Here, the scribing line SCL may correspond to the first edge 100E of the display panel 100, and the pattern PT corresponding to the second edge 110E of the substrate 110 may be designated as a target pattern TPT to control the amount of etching and the etching process. In this case, the pattern PT designated as the target pattern TPT may be a pattern that overlaps the second edge 110E of the substrate 110 in the Z-axis direction after the etching process for the substrate 110 is completed, or it may be a pattern that is disposed adjacent to the second edge 110E of the substrate 110 when viewed from the Z-axis direction. For example, a pattern that is intended to overlap the second edge 110E of the substrate 110 in the z-axis direction, or a pattern that is intended to be disposed adjacent to the second edge 110E of the substrate 110 when viewed from the Z-axis direction may be recognized as the target pattern TPT, and the recognized target pattern TPT may be used to control the etching process to adjust the amount of etching of the substrate 110. Here, the target pattern TPT may be distinguished from the other patterns PT by changing its shape, using a separate mark, or otherwise.

As shown in FIGS. 10 and 11, the mother glass substrate 10 may be etched using an etchant. The mother glass substrate 10 may be etched by applying or spraying an etchant along the scribing line SCL. At this time, portions of the mother glass substrate 10 and the first buffer layer 111 may be etched to form an opening OP, exposing some of the plurality of patterns PT to the etchant. Because the plurality of patterns PT are formed of inorganic and/or metallic materials that may be etched by the etchant, the plurality of patterns PT exposed by the opening OP may also be etched together with the substrate 110. Accordingly, as shown in FIG. 11, a plurality of grooves G may be formed in the first planarization layer 117 as the plurality of patterns PT overlapping the etched area from which the mother glass substrate 10 has been removed are removed.

The amount of etching of the substrate 110 and the edge position of the substrate 110 may be inspected by the plurality of patterns PT remaining on the substrate 110. For example, the second edge 110E of the substrate 110 may correspond to a pattern PT disposed at the outermost side among a plurality of patterns PT remaining on the substrate 110 and the first buffer layer 111. In this case, the pattern PT disposed at the outermost side among the plurality of patterns PT may overlap the second edge 110E of the substrate 110 in the Z-axis direction, or it may be disposed adjacent to the second edge 110E of the substrate 110 when viewed from the Z-axis direction. And, the amount of etching of the substrate 110 may be controlled by comparing the position of the target pattern TPT to the position of the pattern PT disposed at the outermost side among the plurality of patterns PT remaining on the substrate 110.

And when the etching of the mother glass substrate 10 is completed, an organic insulating layer that is disposed to overlap the etched area of the substrate 110 is cut with a laser along the scribing line SCL. Accordingly, the mother glass substrate 10 may be separated into a plurality of display panels 100. For example, an organic insulating layer such as the first planarization layer 117 may be formed of a material that is not etched by the etching process, and therefore it may be cut using a separate laser.

Then, the side coating layer 190 may be formed that covers the edge 110E of the substrate 110. At this time, the inside of the groove G may be filled with a material forming the side coating layer 190.

Therefore, the display device and the method of manufacturing the display device according to the embodiment of the present disclosure facilitate the separation of the mother glass substrate 10 into the plurality of display panels 100 by a chemical method using the etchant. In this case, the plurality of patterns PT disposed in an adjacent area of the scribing line SCL may allow the etching process to be monitored. For example, since some of the plurality of patterns PT are etched as the etching process progresses, it is possible to precisely control the etching process. In addition, it is possible to monitor the edge position of the substrate 110 by using the pattern PT disposed at the outermost side among the plurality of patterns PT remaining on the substrate 110 when the etching process progresses. Moreover, in the case where the thickness T of the substrate 110 is measured, the slope angle of the edge surface 110S may also be measured by means of the patterns PT that overlap the edge surface 110S, which is formed to have a predetermined slope, in the Z-axis direction. For example, in the case where the thickness T of the substrate 110 is measured, or in the case where the substrate 110 has a predetermined thickness T, the thickness of the substrate 110 may be identified. The thickness of the first buffer layer 111 may also be identified. And since the plurality of patterns PT remaining on the substrate 110 during the etching process may be utilized as rulers, the slope angle of the edge surface 110S may be measured by means of the patterns PT that overlap the edge surface 110S among the plurality of remaining patterns PT. More specifically, as shown in FIG. 11, the distance between a first pattern PT1 overlapping the top edge 110UE of the edge surface 110S and a second pattern PT2 overlapping the bottom edge 110DE of the edge surface 110S may be identified. In this way, the slope angle of the edge surface 110S may be measured based on the distance between the first pattern PT1 overlapping the top edge 110UE of the edge surface 110S and the second pattern PT2 overlapping the bottom edge 110DE of the edge surface 110S and the thickness T of the substrate 110.

The patterns PT on the display panel 100 shown in FIGS. 1 to 11 serves as rulers that allow the edge position of the substrate 110 to be identified while managing the slope of the substrate 110. As described above, the position of the edge 110E of the substrate 110 and the slope of the edge surface 110S of the substrate 110 may be identified by the use of the first embodiment of the display panel 100 shown in FIGS. 1 to 11, but the display device according to the embodiment of the present disclosure may present a variety of embodiments in which different arrangements of the patterns allow for easier and faster determination with the naked eye as to whether the display panel 100 is defective or not.

Various embodiments of the present disclosure that identify the position of the edge 110E of the substrate 110 and the slope of the substrate 110 by means of the different arrangements of the patterns PT will be discussed below.

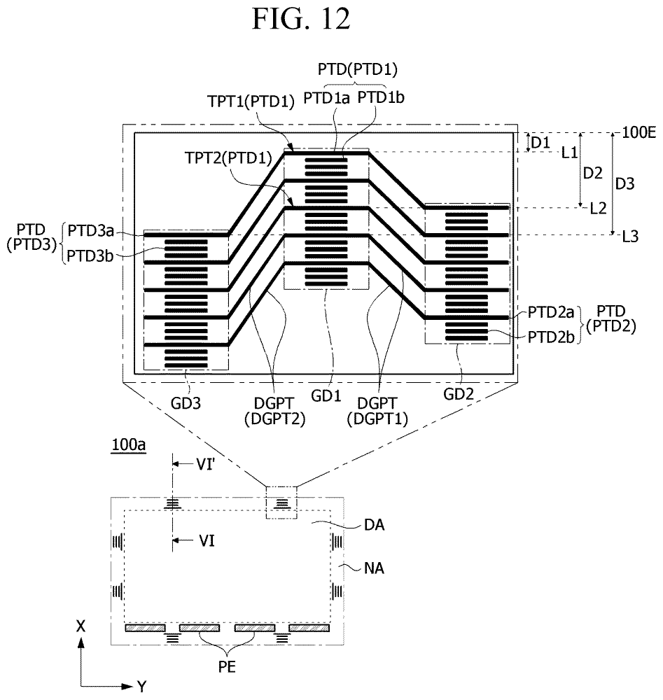

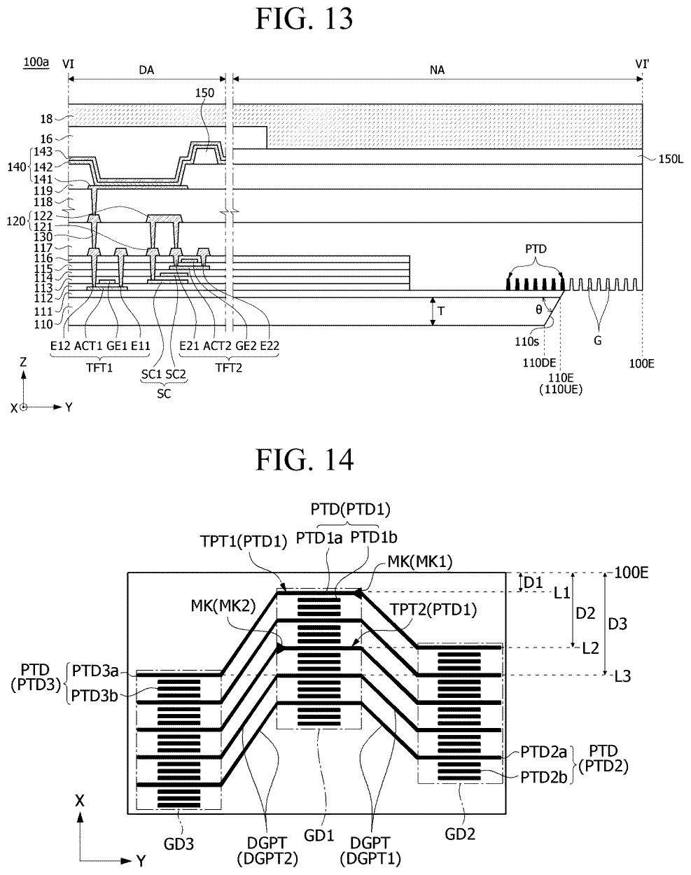

FIG. 12 is a plan view illustrating a display panel according to another embodiment of the present disclosure, FIG. 13 is a cross-sectional view taken along lines VI-VI′ in FIG. 12, and FIG. 14 is a plan view illustrating a mark on a display panel according to another embodiment of the present disclosure. Imaginary first line L1, second line L2, and third line L3 shown in FIG. 12 are parallel to a first edge 100E of a display panel 100a and/or a second edge 110E of the substrate 110. Here, the display panel 100a shown in FIGS. 12 to 14 may be referred to as a display panel according to a second embodiment. FIGS. 12 and 14 are diagrams clearly illustrating an arrangement relationship between the first edge 100E of the display panel 100a and the outermost first lower pattern PTD1 of the first lower pattern group GD1, an arrangement relationship between the first edge 100E of the display panel 100a and the outermost second lower pattern PTD2 of the second lower pattern group GD2, and an arrangement relationship between the first edge 100E of the display panel 100a and the outermost third lower pattern PTD3 of the third lower pattern group GD3 by omitting the position of the second edge 110E of the display panel 100a.

When comparing the display panel 100 according to the first embodiment with the display panel 100a according to the second embodiment with reference to FIGS. 3 to 17, the display panel 100a of the second embodiment is different from the display panel 100 of the first embodiment in that the display panel 100a includes a plurality of pattern groups wherein each of the plurality of pattern groups includes a plurality of patterns. Herein, a display device according to the embodiment of the present disclosure may use the display panel 100a according to the second embodiment instead of the display panel 100 according to the first embodiment.

In describing the display panel 100a according to the second embodiment with reference to FIGS. 12 to 14, the same components of the display panel 100 according to the first embodiment and the display panel 100a according to the second embodiment may be denoted by the same reference symbols, and thus a detailed description thereof will be omitted.

As shown in FIGS. 12 and 13, the display panel 100a according to the second embodiment includes a substrate 110, a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, a first transistor TFT1, a second transistor TFT2, a storage capacitor SC, a storage supply line 120, a connection electrode 130, a light-emitting element 140, a spacer 150, a spacer layer 150L, a pad electrode PE, an encapsulation layer 16, a polarizer 18, a side coating layer 190, a plurality of lower pattern groups GD1, GD2, GD3, and a groove G. Further, the display panel 100a according to the second embodiment may include a plurality of lower guide patterns DGPT that guide the correspondence between patterns disposed in one lower pattern group and patterns disposed in another lower pattern group.

The substrate 110 may include an edge surface 110S formed by an etching process. The edge surface 110S may be formed on the substrate 110 to have a predetermined slope angle θ by an etching process. As shown in FIG. 13, the slope angle θ may represent the angle formed by the top surface of the substrate 110 and the edge surface 110S, which may be an acute angle. Thus, the edge surface 110S of the substrate 110 includes a top edge 110UE and a bottom edge 110DE with respect to the Z-axis direction, wherein the top edge 110UE disposed at the outermost side of the substrate 110 may represent the second edge 110E of the substrate 110.

The plurality of lower pattern groups GD1, GD2, and GD3 may be disposed to be spaced apart from each other by a predetermined interval on a lower side of the first planarization layer 117. In this case, the plurality of lower pattern groups GD1, GD2, and GD3 may be disposed on the first buffer layer 111, wherein some of the patterns disposed in the plurality of lower pattern groups GD1, GD2, and GD3 may be etched together with the first buffer layer 111 by an etching process.

Each of the plurality of lower pattern groups GD1, GD2, and GD3 may include a plurality of lower patterns PTD disposed to be spaced apart from each other, and the lower patterns PTD may be disposed parallel to the second edge 110E of the substrate 110. Here, the lower patterns PTD disposed in the first lower pattern group GD1 may be referred to as first lower patterns PTD1, the lower patterns PTD disposed in the second lower pattern group GD2 may be referred to as second lower patterns PTD2, and the lower patterns PTD disposed in the third lower pattern group GD3 may be referred to as third lower patterns PTD3. The plurality of first lower patterns PTD1, the plurality of second lower patterns PTD2, and the plurality of third lower patterns PTD3 may include main patterns and sub-patterns, as in the plurality of patterns PT disposed on the display panel 100 according to the first embodiment.

The plurality of lower pattern groups GD1, GD2, and GD3 may include a first lower pattern group GD1, a second lower pattern group GD2, and a third lower pattern group GD3, but are not limited thereto. For example, the display panel 100a may include the first lower pattern group GD1 and the second lower pattern group GD2, or it may include four or more lower pattern groups.

The first lower pattern group GD1, the second lower pattern group GD2, and the third lower pattern group GD3 may be disposed to be spaced apart from each other along the first edge 100E of the display panel 100 on a horizontal plane. For example, since the first lower pattern group GD1, the second lower pattern group GD2, and the third lower pattern group GD3 may be disposed to correspond to each of the four sides of the substrate 110, the first lower pattern group GD1, the second lower pattern group GD2, and the third lower pattern group GD3 may be disposed to be spaced apart from each other in a first direction or a second direction. Here, the first direction may represent the X-axis direction and the second direction may represent the Y-axis direction.

The first lower pattern group GD1, the second lower pattern group GD2, and the third lower pattern group GD3 may be disposed at different distances relative to the first edge 100E of the display panel 100a. For example, based on the X-axis direction, the outermost first lower pattern PTD1 in the first lower pattern group GD1 may be disposed to be spaced apart from the first edge 100E of the display panel 100a by a first distance D1. The outermost second lower pattern PTD2 in the second lower pattern group GD2 may be spaced apart from the first edge 100E of the display panel 100a by a second distance D2. The outermost third lower pattern PTD3 in the third lower pattern group GD3 may be spaced apart from the first edge 100E of the display panel 100a by a third distance D3. Here, the second distance D2 is larger than the first distance D1 and smaller than the third distance D3. Thus, the display panel 100a may monitor an outermost edge position of the substrate 110 by using the first lower pattern group GD1. Moreover, the display panel 100a may easily monitor the slope of the edge surface 110S of the substrate 110 by using the second lower patterns PTD2 in the second lower pattern group GD2, the third lower patterns PTD3 in the third lower pattern group GD3, and the lower guide patterns DGPT.

The first lower pattern group GD1 may be, but is not necessarily limited to, disposed between the second lower pattern group GD2 and the third lower pattern group GD3. However, in consideration of the arrangement of a plurality of lower guide patterns DGPT disposed between the first lower pattern group GD1 and the second lower pattern group GD2 and a plurality of lower guide patterns DGPT disposed between the second lower pattern group GD2 and the third lower pattern group GD3, the display panel 100a may provide the first lower pattern group GD1 disposed between the second lower pattern group GD2 and the third lower pattern group GD3 as an embodiment.

The first lower pattern group GD1 may include a plurality of lower patterns PTD. For example, the first lower pattern group GD1 may include a plurality of first lower patterns PTD1.

The plurality of first lower patterns PTD1 may be disposed in an area adjacent to the second edge 110E of the substrate 110, and may be disposed between the first buffer layer 111 and the first planarization layer 117. Here, the plurality of first lower patterns PTD1 in the first lower pattern group GD1 may correspond to the plurality of patterns PT of the display panel 100 according to the first embodiment. Thus, the plurality of first lower patterns PTD1 may serve as a kind of scale for monitoring the amount of etching of the substrate 110 and the outermost edge position of the substrate 110 formed by the etching process. For example, the outermost edge position of the substrate 110 may be identified by recognizing the first lower pattern PTD1 that is disposed at the outermost side of the substrate 110 and that overlaps the second edge 110E, or the first lower pattern PTD1 that is disposed at the outermost side of the substrate 110 and that is adjacent to the second edge 110E, among the plurality of first lower patterns PTD1. In this case, the top edge 110UE disposed at the outermost side of the substrate 110 may represent the second edge 110E of the substrate 110.

The plurality of first lower patterns PTD1 may include main patterns and sub-patterns. For example, the plurality of first lower patterns PTD1 may include first lower main patterns PTD1a and first lower sub-patterns PTD1b. In this case, a plurality of first lower sub-patterns PTD1b may be disposed between the two first lower main patterns PTD1a, wherein the first lower main patterns PTD1a may be formed to have a longer length than the first lower sub-patterns PTD1b.

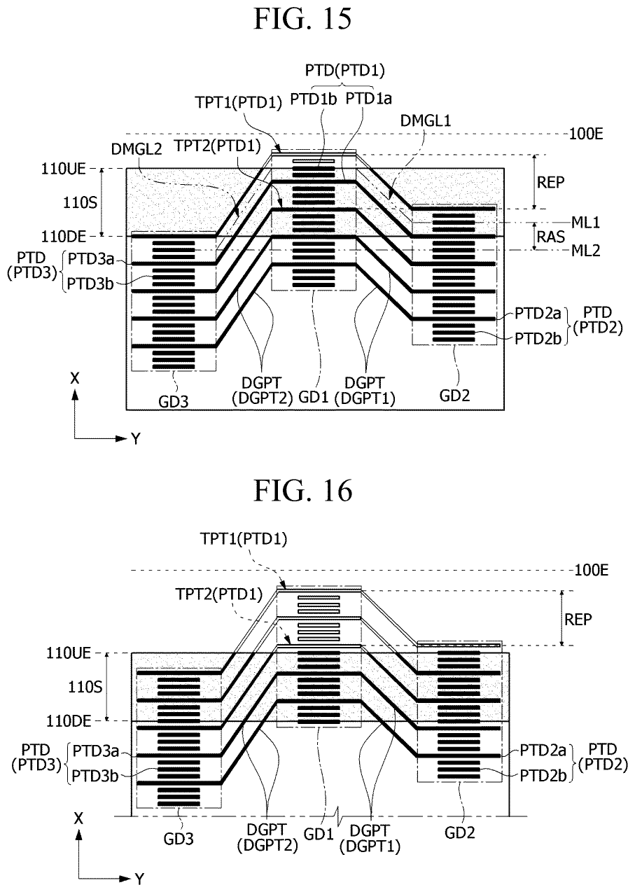

Moreover, some of the plurality of first lower patterns PTD1 may be designated as target patterns. As shown in FIG. 15, a first target pattern TPT1 and a second target pattern TPT2 may be designated as the target patterns.

For example, taking into account the allowable range of the outermost edge position for the substrate 110 due to process error, two first lower main patterns PTD1a that are spaced apart from each other among the plurality of first lower patterns PTD1 may be designated as the target patterns. Thus, when the second edge 110E of the substrate 110 is located between the two first lower main patterns PTD1a designated as target patterns, the display panel 100a may be determined to be a normal panel. For example, the display panel 100a may be determined to be a normal panel when the second edge 110E of the substrate 110 is located between the first target pattern TPT1 and the second target pattern TPT2, which are designated as the target patterns (see FIG. 15). In other words, when the second edge 110E of the substrate 110 is located between the two first lower main patterns PTD1a designated as the target patterns, the display panel 100a may receive a Safe determination for the outermost edge position of the substrate 110. Here, the designation of some of the plurality of first lower patterns PTD1 as the target patterns may also apply to the patterns PT of the display panel 100 according to the first embodiment.

As shown in FIG. 14, among the plurality of first lower patterns PTD1, a first lower pattern PTD1 disposed on an imaginary first line L1 and a first lower pattern PTD1 disposed on an imaginary second line L2 may be designated as the target patterns. Here, the first lower pattern PTD1 disposed on the first line L1 may be referred to as a first target pattern TPT1, and the first lower pattern PTD1 disposed on the second line L2 may be referred to as a second target pattern TPT2, wherein the interval between the first target pattern TPT1 and the second target pattern TPT2, i.e., the interval between the two target patterns, may represent an outermost edge allowable range of the substrate 110. For example, the substrate 110 may include the top edge 110UE and the bottom edge 110DE, wherein one of the top edge 110UE and the bottom edge 110DE may represent the outermost edge disposed at the outermost side of the substrate 110. A predetermined range (or an interval) may be established for the outermost edge of the substrate 110 to be determined to be normal, taking into account process error due to the etching process, and this range may represent an allowable range for the position where the outermost edge is disposed. Thus, when the outermost edge of the substrate 110 is located within the allowable range of the outermost edge position, the display panel 100a may receive a Safe determination for the outermost edge position of the substrate 110.

In this case, the first target pattern TPT1 may represent an upper limit of the outermost edge allowable range for the substrate 110, and the second target pattern TPT2 may represent a lower limit of the outermost edge allowable range for the substrate 110. Accordingly, when the second edge 110E of the substrate 110 is disposed between the first target pattern TPT1 and the second target pattern TPT2, the display panel 100a may receive a Safe determination for the outermost edge position of the substrate 110. Therefore, when two of the plurality of first lower patterns PTD1 that are spaced apart by a predetermined interval are designated as a first target pattern TPT1 and a second target pattern TPT2, and the top edge 110UE is located between the first target pattern TPT1 and the second target pattern TPT2, it may be identified that the top edge is normally located relative to the outermost edge position of the substrate 110.

As shown in FIG. 14, the display panel 100a may further include a mark MK that makes the target pattern recognizable. Here, the mark MK may be formed in various shapes, and may be formed in a triangular shape, as shown in FIG. 14.

The mark MK may include a first mark MK1 and a second mark MK2.

The first mark MK1 may be disposed on the first target pattern TPT1. For example, the first mark MK1 may be disposed on the first lower pattern PTD1 designated as the first target pattern TPT1.

The second mark MK2 may be disposed to correspond to the second target pattern TPT2. For example, the second mark MK2 may be placed on the first lower pattern PTD1 designated as the second target pattern TPT2.

Accordingly, when the second edge 110E of the substrate 110 is disposed between the first mark MK1 and the second mark MK2, the display panel 100a may receive a Safe determination for the outermost edge position of the substrate 110. Here, the designation of some of the plurality of first lower patterns PTD1 as the target patterns using the mark MS may also apply to the patterns PT of the display panel 100 according to the first embodiment. In this way, the mark MK is placed where the target pattern is, making it easy to recognize which of the lower patterns is the target pattern.

The second lower pattern group GD2 may include a plurality of lower patterns PTD. For example, the second lower pattern group GD2 may include a plurality of second lower patterns PTD2.

The plurality of second lower patterns PTD2 may be disposed to be spaced apart from the first edge 100E of the display panel 100a by a predetermined distance, and may be disposed between the first buffer layer 111 and the first planarization layer 117.

A second lower pattern PTD2 disposed at the outermost side among the plurality of second lower patterns PTD2 may be disposed on the second line L2 provided as an imaginary straight line. In this case, the second lower pattern PTD2 disposed at the outermost side may be disposed so as to overlap the first lower pattern PTD1 designated as the target pattern on the second line L2 in the first direction or in the second direction. Thus, the second lower pattern PTD2 disposed at the outermost side may serve as a kind of scale for monitoring the outermost edge position of the substrate 110. For example, the second lower pattern PTD2 disposed at the outermost side may be disposed to overlap the first lower pattern PTD1 designated as the target pattern, and the second lower pattern PTD2 disposed at the outermost side may be etched together with the first lower pattern PTD1 designated as the target pattern by the etching process. Thus, the display panel 100a may be classified as an abnormal panel by receiving an Out determination for the outermost edge position of the substrate 110. Here, the first lower pattern PTD1, designated as the target pattern, may represent a lower limit of the outermost edge allowable range for the substrate 110.

Further, the plurality of second lower patterns PTD2 may be used in conjunction with the plurality of third lower patterns PTD3 to measure an slope angle θ with respect to the edge surface 110S of the substrate 110. In this case, a third lower pattern PTD3 disposed at the outermost side among the plurality of third lower patterns PTD3 may be disposed on a third line L3 provided as an imaginary straight line.

For example, the edge surface 110S formed to have a predetermined slope includes a top edge 110UE and a bottom edge 110DE. And, a first directional distance between the second lower pattern PTD2 of the second lower pattern group GD2 corresponding to the top edge 110UE and the third lower pattern PTD3 of the third lower pattern group GD3 corresponding to the bottom edge 110DE may be measured, and an slope angle θ of the edge surface 110S may be measured by using the above-mentioned first directional distance and the thickness T of the substrate 110. Thus, the slope of the edge surface 110S of the substrate 110 may be managed by controlling the etching process based on the measured slope angle θ. Here, the plurality of second lower patterns PTD2 and the plurality of third lower patterns PTD3 may be disposed to be spaced apart from each other along the first direction. In this case, the top edge 110UE of the edge surface 110S may be disposed along the second direction that is different from the first direction, wherein the first direction and the second direction may be perpendicular to each other in a horizontal plane.

In addition, the plurality of second lower patterns PTD2 may be used in conjunction with the plurality of third lower patterns PTD3 to determine a slope allowable range RAS for the edge surface 110S of the substrate 110. Specifically, when a Safe determination is made for the outermost edge position of the substrate 110 using the first target pattern TPT1 and the second target pattern TPT2, the position of the top edge 110UE provided as the outermost edge position of the substrate 110 may be identified. In this case, if the position of the bottom edge 110DE of the substrate 110 is within the allowable range of the slope angle, it may facilitate the determination for the slope angle θ to be normal without substantially measuring the slope angle θ.

For example, a first lower pattern PTD1 corresponding to the second edge 110E among the plurality of first lower patterns PTD1 may be recognized, and a second lower pattern PTD2 and a third lower pattern PTD3 corresponding to the recognized first lower pattern PTD1 may be easily detected using the lower guide pattern DGPT. In this case, the detected second lower pattern PTD2 may represent an upper limit within the slope allowable range RAS, and the detected third lower pattern PTD3 may represent a lower limit within the slope allowable range RAS. Here, the interval between the detected second lower pattern PTD2 and the third lower pattern PTD3 in the first direction may represent the slope allowable range RAS. Thus, the display panel 100a may receive a Safe determination for the slope angle θ if the bottom edge 110DE is located within the interval between the detected second lower pattern PTD2 and the third lower pattern PTD3 in the first direction Then, the display panel 100a may be identified to be a normal panel with respect to the slope angle θ of the edge surface 110S by the Safe determination.

The third lower pattern group GD3 may include a plurality of lower patterns PTD. For example, the third lower pattern group GD3 may include a plurality of third lower patterns PTD3.

The plurality of third lower patterns PTD3 may be disposed to be spaced apart from the first edge 100E of the display panel 100a by a predetermined distance, and may be disposed between the first buffer layer 111 and the first planarization layer 117.

The plurality of second lower patterns PTD2 and third lower patterns PTD3 may include main patterns and sub-patterns. For example, the plurality of second lower patterns PTD2 may include first lower main patterns PTD2a and first lower sub-patterns PTD2b. In this case, a plurality of second lower sub-patterns PTD2b may be disposed between the two second lower main patterns PTD2a, wherein the second lower main patterns PTD2a may be formed to have a longer length than the second lower sub-patterns PTD2b. In addition, the plurality of third lower patterns PTD3 may include third lower main patterns PTD3a and third lower sub-patterns PTD3b. In this case, a plurality of third lower sub-patterns PTD3b may be disposed between the two third lower main patterns PTD3a, wherein the third lower main patterns PTD3a may be formed to have a longer length than the third lower sub-patterns PTD3b.

The plurality of lower guide patterns DGPT may be disposed between the plurality of lower pattern groups GD1, GD2, and GD3. For example, a plurality of first lower guide patterns DGPT1 may be disposed between the first lower pattern group GD1 and the second lower pattern group GD2, and a plurality of second lower guide patterns DGPT2 may be disposed between the second lower pattern group GD2 and the third lower pattern group GD3.

A lower guide patterns DGPT may be disposed to correspond to one pattern in one lower pattern group and one pattern in another lower pattern group. For example, one first lower guide pattern DGPT1 may connect one first lower main pattern PTD1a and one second lower main pattern PTD2a, allowing the correspondence between the first lower main pattern PTD1a and the second lower main pattern PTD2a to be identified. As shown in FIGS. 12 and 14, a first lower guide pattern DGPT1 may connect one first lower main pattern PTD1a in the first lower pattern group GD1 to one second lower main pattern PTD2a in the second lower pattern group GD2 so that these lower main patterns can be identified as corresponding to each other. Although it has been described as an example that the first lower guide pattern DGPT1 connects the first lower main pattern PTD1a and the second lower main pattern PTD2a, it is not necessarily limited thereto. When the correspondence between the first lower main pattern PTD1a and the second lower main pattern PTD2a may be identified, the first lower guide pattern DGPT1 may be disposed to be disconnected from either the first lower main pattern PTD1a or the second lower main pattern PTD2a. Further, one second lower guide pattern DGPT2 may connect one first lower main pattern PTD1a and one third lower main pattern PTD3a, allowing the correspondence between the first lower main pattern PTD1a and the third lower main pattern PTD3a to be identified.

Although it has been described as an example that the display panel 100a includes two or more lower guide patterns DGPT disposed between two lower pattern groups, it is not necessarily limited thereto. In consideration of the recognition rate for the allowable range of the outermost edge position of the substrate 110, two lower guide patterns DGPT may be presented to correspond to the first lower pattern PTD1 designated as the target pattern in the first lower pattern group GD1.

Moreover, the lower guide pattern DGPT may be disposed to correspond to the slope angle θ of the edge surface 110S. Thus, from the disposed orientation of the lower guide pattern DGPT, it is possible to predict whether the slope angle θ of the edge surface 110S is an acute angle or an obtuse angle.

As shown in FIGS. 11 and 13, as a positively tapered opening is formed in the mother glass substrate 10, the slope angle θ of the edge surface 110S may form an acute angle. As the slope angle θ of the edge surface 110S forms an acute angle, the outermost edge at the second edge 110E of the substrate 110 may be the top edge 110UE. Therefore, if the slope angle θ of the edge surface 110S is acute, the second edge 110E of the substrate 110 is provided as the outermost edge and becomes as a reference for etching some of the first lower patterns PTD1. Furthermore, the plurality of second lower patterns PTD2 are disposed to be spaced apart by a predetermined distance from the first edge 100E of the display panel 100 so as to be provided as an element for identifying the slope angle θ of the edge surface 110S. Thus, the first lower guide pattern DGPT1 may be disposed to be inclined toward the first lower pattern PTD1 at an end of the second lower pattern PTD2. In this case, since the second lower pattern group GD2 is disposed at a second distance D2 that is greater than the first distance D1, the first lower guide pattern DGPT1 connecting the first lower pattern PTD1 and the second lower pattern PTD2, which correspond to each other, may be disposed to be inclined outwardly. Thus, it may be identified that the first lower guide pattern DGPT1 is disposed to be inclined outwardly, and based on this, it may be predicted that the slope angle θ of the edge surface 110S is acute. Further, from the second lower guide pattern DGPT2, which is disposed to be inclined outwardly, it is possible to predict that the slope angle θ of the edge surface 110S is acute.

FIG. 15 is a diagram conceptually illustrating an arrangement relationship between an edge and patterns of a substrate determined to be normal in a display panel of a display device according to another embodiment of the present disclosure.

As shown in FIG. 15, the top edge 110UE provided as the second edge 110E of the substrate 110 is located between the first target pattern TPT1 and the second target pattern TPT2. Thus, the display panel 100a may receive a Safe determination for the outermost edge position of the substrate 110. Here, the first target pattern TPT1 may represent an upper limit of an outermost edge allowable range REP, and the second target pattern TPT2 may represent a lower limit of the outermost edge allowable range REP.

As the top edge 110UE is located between the first target pattern TPT1 and the second target pattern TPT2, the first lower pattern PTD1 corresponding to the top edge 110UE may be recognized. For example, a first lower pattern PTD1 in the first lower pattern group GD1 that overlaps the top edge 110UE in the Z-axis direction may be recognized. And, a second lower pattern PTD2 corresponding to the recognized first lower pattern PTD1 may be identified by an imaginary first lower matching guide line DMGL1. And, a third lower pattern PTD3 corresponding to the identified first lower pattern PTD1 may be identified by an imaginary second lower matching guide line DMGL2. Here, the first lower matching guide line DMGL1 may be an imaginary line disposed parallel to the first lower guide pattern DGPT1, and the second lower matching guide line DMGL2 may be an imaginary line disposed parallel to the second lower guide pattern DGPT2.

As shown in FIGS. 14 and 15, because the outermost lower pattern PTD in the second lower pattern group GD2 is disposed to be spaced apart by a second distance D2 from the edge 100E of the display panel 100, and the outermost lower pattern PTD in the third lower pattern group GD3 is disposed to be spaced apart by a third distance D3 from the edge 100E of the display panel 100, an imaginary first matching line ML1 extending in the second direction (Y-axis direction) from the second lower pattern PTD2 corresponding to the recognized first lower pattern PTD1 and an imaginary second matching line ML2 extending in the second direction (Y-axis direction) from the third lower pattern PTD3 corresponding to the recognized first lower pattern PTD1 have a predetermined interval in the first direction (X-axis direction). In this case, the interval between the first matching line ML1 and the second matching line ML2, which are spaced apart from each other in the first direction, may represent a preset slope allowable range RAS. Here, the imaginary first matching line ML1 may be an imaginary line extending in the second direction (Y-axis direction) from the second lower pattern PTD2 corresponding to the one first lower pattern PTD1. In addition, the imaginary second matching line ML2 may be an imaginary line extending in the second direction (Y-axis direction) from the third lower pattern PTD3 corresponding to the one first lower pattern PTD1. Although it has been described as an example that the display panel 100a discriminates between the first lower matching guide line DMGL1 and the first matching line ML1 for understanding the arrangement relationship between the recognized first lower pattern PTD1 and the second lower pattern PTD2 and the setting for the slope allowable range RAS, it is not necessarily limited thereto. For example, the first matching line ML1 may be an imaginary line that includes the first lower matching guide line DMGL1. In addition, although it has been described as an example that the display panel 100a discriminates between the second lower matching guide line DMGL2 and the second matching line ML2 for understanding the arrangement relationship between the recognized first lower pattern PTD1 and the third lower pattern PTD3 and the setting for the slope allowable range RAS, it is not necessarily limited thereto. For example, the second matching line ML2 may be an imaginary line that includes the second lower matching guide line DMGL2.

The first matching line ML1 and the second matching line ML2, which are disposed at a distance from each other in the first direction (X-axis direction), makes it possible to set the slope allowable range RAS. For example, the edge surface 110S having a predetermined slope angle θ is formed by an etching process, and the slope angle θ may be measured using the thickness T of the substrate 110 and the distance on the plane between the top edge 110UE and the bottom edge 110DE as discussed above. As can be seen in FIG. 15, whether or not the edge 110E of the substrate 110 is normal may first be determined by means of the first lower pattern PTD1 corresponding to the top edge 110UE. And, according to the determination of whether the outermost edge position of the substrate 110 is normal, the second lower pattern PTD2 corresponding to the first lower pattern PTD1 in the first lower pattern group GD1 overlapping the top edge 110UE in the Z-axis direction may be designated by means of the first lower matching guide line DMGL1. And, the third lower pattern PTD3 corresponding to the first lower pattern PTD1 in the first lower pattern group GD1 overlapping the top edge 110UE in the Z-axis direction may be designated by means of the second lower matching guide line DMGL2. In this case, since the designated second lower pattern PTD2 and the designated third lower pattern PTD3 are designated according to the determination of whether the outermost edge position of the substrate 110 is normal, the designated second lower pattern PTD2 and the designated third lower pattern PTD3 may be used as a reference for determining whether the slope angle θ is normal or not. Thus, the interval between the first matching line ML1 extending in the second direction (Y-axis direction) from the designated second lower pattern PTD2 and the second matching line ML2 extending in the second direction (Y-axis direction) from the designated third lower pattern PTD3 may represent the slope allowable range RAS, wherein the slope allowable range RAS may be used to determine whether or not the slope angle θ of the edge surface 110S is normal. In this case, the first matching line ML1 may represent an upper limit within the slope allowable range RAS for the edge surface 110S, and the second matching line ML2 may represent a lower limit within the slope allowable range RAS for the edge surface 110S.

Therefore, when the bottom edge 110DE is located between the first matching line ML1 and the second matching line ML2, the display panel 100a may receive a Safe determination for the slope angle θ of the edge surface 110S. In other words, the determination of whether the slope angle θ of the edge surface 110S is normal or not may be easily made by means of the bottom edge 110DE located between the first matching line ML1 and the second matching line ML2, without separate calculation. Here, the bottom edge 110DE may serve as a factor for measuring the slope angle θ of the edge surface 110S in conjunction with the top edge 110UE.

That is, each of a plurality of first lower patterns PTD1, a plurality of second lower patterns PTD2, and a plurality of third lower patterns PTD3 is disposed to be spaced apart from each other in the first direction, the first edge 100E of the display panel 100a is disposed in the second direction, and the second lower pattern PTD2 and the third lower pattern PTD3, which correspond to the first lower pattern PTD1 overlapping the top edge 110UE in the third direction, form a predetermined interval in the first direction, the slope allowable range RAS. And, when the bottom edge 110DE is located between the slope allowable ranges RAS, it may be easily determined that the display panel 100a is a normal panel.

FIG. 16 is a diagram illustrating a defect of an edge position of a substrate determined by a plurality of patterns in a display panel of a display device according to another embodiment of the present disclosure.

As shown in FIG. 16, it is illustrated that the top edge 110UE provided as the second edge 110E of the substrate 110 is located beyond the outermost edge allowable range REP as represented by the interval between the first target pattern TPT1 and the second target pattern TPT2. Thus, the display panel 100a may be classified as an abnormal panel by receiving an Out determination for the outermost edge position of the substrate 110.

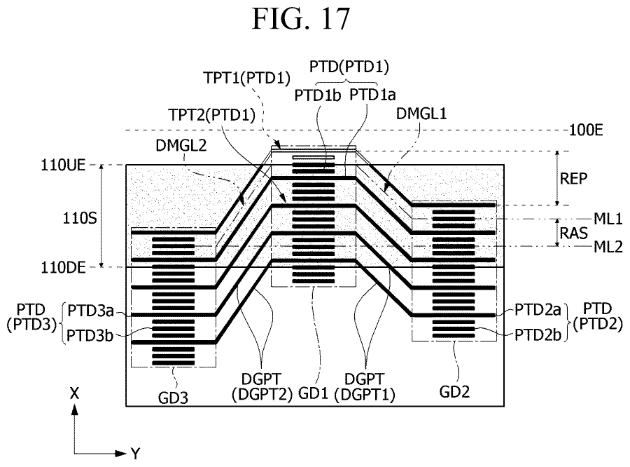

FIG. 17 is a diagram illustrating a slope defect of a substrate determined by a plurality of patterns in a display panel of a display device according to another embodiment of the present disclosure.

As shown in FIG. 17, it is illustrated that the bottom edge 110DE of the substrate 110 is located beyond the slope allowable range RAS as represented by the interval between the first matching line ML1 and the second matching line ML2. Thus, the display panel 100a may be classified as an abnormal panel by receiving an Out determination with respect to the slope angle θ of the edge surface 110S of the substrate 110.

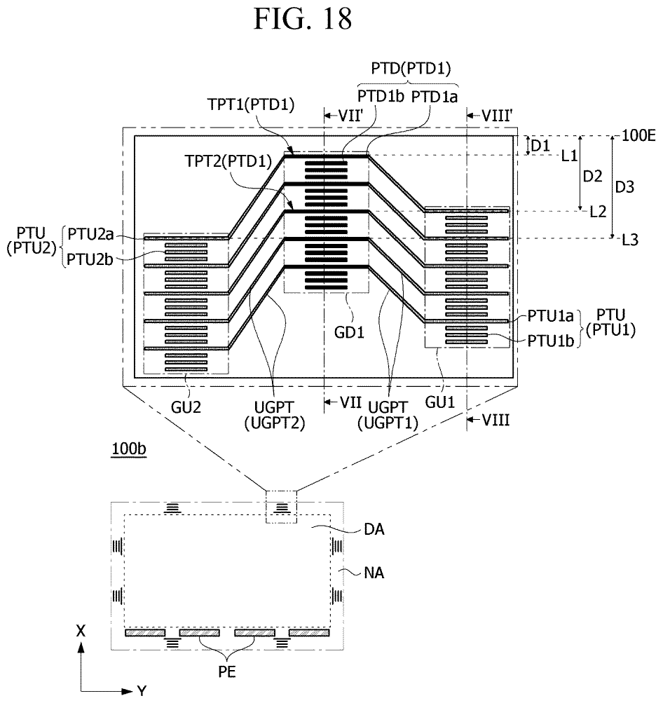

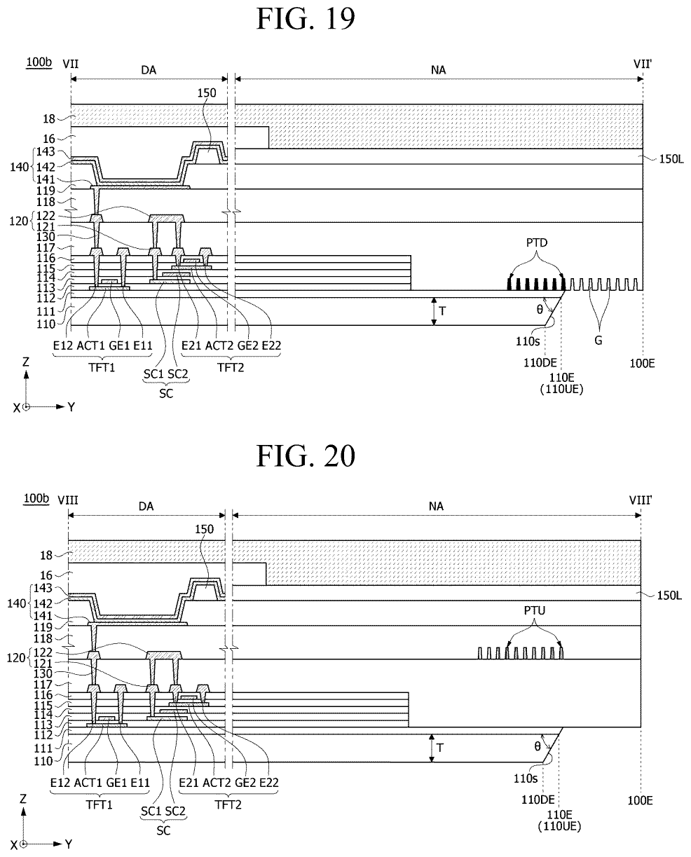

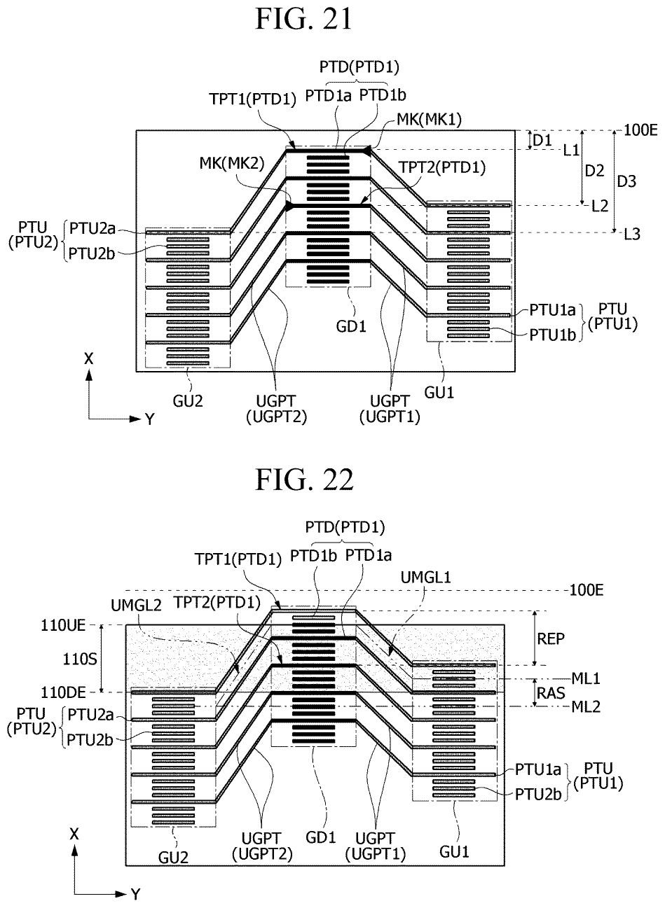

FIG. 18 is a plan view illustrating a display panel according to another embodiment of the present disclosure, FIG. 19 is a cross-sectional view taken along line VII-VII′ in FIG. 18, FIG. 20 is a cross-sectional view taken along line VIII-VIII′ in FIG. 18, FIG. 21 is a plan view illustrating a mark of a display panel according to another embodiment of the present disclosure. An imaginary first line L1, an imaginary second line L2, and an imaginary third line L3 shown in FIG. 18 are parallel to the first edge 100E of the display panel 100b and/or the second edge 110E of the substrate 110. Here, the display panel 100b shown in FIGS. 18 to 21 may be referred to as a display panel according to a third embodiment.

When the display panel 100a according to the second embodiment and the display panel 100b according to the third embodiment are compared with reference to FIGS. 12 to 14 and 18 to 21, there are differences in that the display panel 100b of the third embodiment includes a first upper pattern group GU1 instead of the first lower pattern group GD1 and a second upper pattern group GU2 instead of the second lower pattern group GD2, in that the first upper pattern group GU1 and the second upper pattern group GU2 are disposed on the first planarization layer 117, and in that the upper guide pattern UGPT is included instead of the lower guide pattern DGPT. Here, a display device according to the embodiment of the present disclosure may use the display panel 100b according to the third embodiment instead of the display panel 100 according to the first embodiment.

In describing the display panel 100b according to the third embodiment with reference to FIGS. 18 to 21, the same components of the display panel 100a according to the second embodiment and the display panel 100b according to the third embodiment may be denoted by the same reference symbols, and thus a detailed description thereof will be omitted.

As shown in FIGS. 18 and 20, the display panel 100b according to the third embodiment includes a substrate 110, a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, a first transistor TFT1, a second transistor TFT2, a storage capacitor SC, a storage supply line 120, a connection electrode 130, a light-emitting element 140, a spacer 150, a spacer layer 150L, a pad electrode PE, an encapsulation layer 16, a polarizer 18, a side coating layer 190, a lower pattern group, a plurality of upper pattern groups GU1 and GU2, and a groove G. Further, the display panel 100b according to the third embodiment may include a plurality of upper guide patterns UGPT that guide the correspondence between patterns disposed in the lower pattern group and patterns disposed in one of the upper pattern groups GU1 and GU2. The lower pattern group shown in FIG. 18 may have the same configuration as the first lower pattern groups GD1 of the display panel 100a according to the second embodiment. Thus, the lower pattern group of the display panel 100b according to the third embodiment may be referred to as a first lower pattern group GD1, and will be described hereinafter as the first lower pattern group GD1.

The substrate 110 may include an edge surface 110S formed by an etching process. The edge surface 110S may be formed on the substrate 110 to have a predetermined slope angle θ by an etching process. The slope angle θ may represent the angle formed by the top surface of the substrate 110 and the edge surface 110S, which may be an acute angle. Thus, the edge surface 110S of the substrate 110 includes a top edge 110UE and a bottom edge 110DE with respect to the Z-axis direction, wherein the top edge 110UE disposed at the outermost side of the substrate 110 may represent the second edge 110E of the substrate 110.

When viewed from the Z-axis direction, the first lower pattern group GD1, the first upper pattern group GU1, and the second upper pattern group GU2 may be disposed to be spaced apart from each other along the first edge 100E of the display panel 100b. For example, since the first lower pattern group GD1, the first upper pattern group GU1, and the second upper pattern group GU2 may be disposed to correspond to each of the four sides of the substrate 110, the first lower pattern group GD1, the first upper pattern group GU1, and the second upper pattern group GU2 may be disposed to be spaced apart from each other in a first direction or a second direction. Here, the first direction may represent the X-axis direction and the second direction may represent the Y-axis direction.

The first lower pattern group GD1, the first upper pattern group GU1, and the second upper pattern group GU2 may be disposed at different distances relative to the first edge 100E of the display panel 100b. For example, the outermost lower pattern PTD in the first lower pattern group GD1 may be disposed to be spaced apart from the first edge 100E of the display panel 100b by a first distance D1. The outermost upper pattern PTU in the first upper pattern group GU1 may be spaced apart from the first edge 100E of the display panel 100b by a second distance D2. The outermost upper pattern PTU in the second upper pattern group GU2 may be disposed to be spaced apart from the first edge 100E of the display panel 100b by a third distance D3. Here, the second distance D2 is larger than the first distance D1 and smaller than the third distance D3. Thus, the display panel 100b may monitor the outermost edge position of the substrate 110 by using the first lower pattern group GD1. Moreover, the display panel 100b may facilitate monitoring the slope of the edge surface 110S of the substrate 110 by using the first upper pattern group GU1 and the second upper pattern group GU2.

When viewed from the Z-axis direction, the lower pattern group GD1 may be disposed between the first upper pattern group GU1 and the second upper pattern group GU2.

The first lower pattern group GD1 may include a plurality of lower patterns PTD. For example, the first lower pattern group GD1 may include a plurality of first lower patterns PTD1.

The plurality of first lower patterns PTD1 may be disposed in an area adjacent to the second edge 110E of the substrate 110, and may be disposed between the first buffer layer 111 and the first planarization layer 117. Here, the plurality of first lower patterns PTD1 in the first lower pattern group GD1 may correspond to the plurality of patterns PT of the display panel 100 according to the first embodiment. Thus, the plurality of first lower patterns PTD1 may serve as a kind of scale for monitoring the amount of etching of the substrate 110 and the outermost edge position of the substrate 110 formed by the etching process.

The plurality of first lower patterns PTD1 may include main patterns and sub-patterns. For example, the plurality of first lower patterns PTD1 may include first lower main patterns PTD1a and first lower sub-patterns PTD1b. In this case, a plurality of first lower sub-patterns PTD1b may be disposed between the two first lower main patterns PTD1a, wherein the first lower main patterns PTD1a may be formed to have a longer length than the first lower sub-patterns PTD1b.

Moreover, some of the plurality of first lower patterns PTD1 may be designated as target patterns. For example, two first lower main patterns PTD1a that are spaced apart from each other among the plurality of first lower patterns PTD1 may be designated as target patterns, and the display panel 100b may be determined to be a normal panel when the second edge 110E of the substrate 110 is located between the two first lower main patterns PTD1a designated as target patterns.

Moreover, among the plurality of first lower patterns PTD1, a first lower pattern PTD1 disposed on an imaginary first line L1 and a first lower pattern PTD1 disposed on an imaginary second line L2 may be designated as a target pattern. Here, the first lower pattern PTD1 disposed on the first line L1 may be referred to as a first target pattern TPT1, and the first lower pattern PTD1 disposed on the second line L2 may be referred to as a second target pattern TPT2, wherein the interval between the first target pattern TPT1 and the second target pattern TPT2 may represent the outermost edge allowable range for the substrate 110. In this case, the first target pattern TPT1 may represent an upper limit of the outermost edge allowable range for the substrate 110, and the second target pattern TPT2 may represent a lower limit of the outermost edge allowable range for the substrate 110. Accordingly, when the second edge 110E of the substrate 110 is located between the first target pattern TPT1 and the second target pattern TPT2, the display panel 100b may receive a Safe determination for the outermost edge position of the substrate 110.

As shown in FIG. 21, the display panel 100b may further include a mark MK that makes the target pattern recognizable. The mark MK may include a first mark MK1 and a second mark MK2.

The first mark MK1 may be disposed on the first target pattern TPT1. The second mark MK2 may be disposed to correspond to the second target pattern TPT2. Therefore, when the second edge 110E of the substrate 110 is located between the first mark MK1 and the second mark MK2, the display panel 100b may receive a Safe determination for the outermost edge position of the substrate 110.

The first upper pattern group GU1 may include a plurality of upper patterns PTU. For example, the first upper pattern group GU1 may include a plurality of first upper patterns PTU1.

The plurality of first upper patterns PTU1 may be disposed to be spaced apart from the first edge 100E of the display panel 100b by a predetermined distance, and may be disposed on the first planarization layer 117.

The plurality of upper pattern groups GU2 and GU1 may be disposed to be spaced apart from each other by a predetermined interval on the first planarization layer 117. Thus, the upper patterns PTUs in the plurality of upper pattern groups GU1 and GU2 remain even after the etching process is performed on the substrate 110.

Each of the plurality of upper pattern groups GU2 and GU1 may include a plurality of upper patterns PTU disposed to be spaced apart from each other, and the upper patterns PTU may be disposed parallel to the second edge 110E of the substrate 110. Here, the upper patterns PTU disposed in the first upper pattern group GU1 may be referred to as first upper patterns, and the upper patterns PTU disposed in the second upper pattern group GU2 may be referred to as second upper patterns. The plurality of first upper patterns and the plurality of second upper patterns may include main patterns and sub-patterns, as in the plurality of patterns PT disposed on the display panel 100 according to the first embodiment.

The plurality of upper pattern groups GU1 and GU2 may include, but is not necessarily limited to, the first upper pattern group GU1 and the second upper pattern group GU2. For example, the display panel 100b may include the first upper pattern group GU1, or it may include three or more upper pattern groups.

The first upper pattern group GU1 may include a plurality of upper patterns PTU. For example, the first upper pattern group GU1 may include a plurality of first upper patterns PTU1. The first upper pattern group GU1 may be used to represent an upper limit within the slope allowable range RAS.

The second upper pattern group GU2 may include a plurality of upper patterns PTU. For example, the second upper pattern group GU2 may include a plurality of second upper patterns PTU2. The second upper pattern group GU2 may be used to represent a lower limit within the slope allowable range RAS.

The plurality of first upper patterns PTU1 and second upper patterns PTU2 may be disposed to be spaced apart from the first edge 100E of the display panel 100b by a predetermined distance, and may be disposed on the first planarization layer 117.

The plurality of first upper patterns PTU1 and second upper patterns PTU2 may include main patterns and sub-patterns. For example, the plurality of first upper patterns PTU1 may include first upper main patterns PTU1a and first upper sub-patterns PTU1b. In this case, a plurality of first upper sub-patterns PTU1b may be disposed between the two first upper main patterns PTU1a, wherein the first upper main patterns PTU1a may be formed to have a longer length than the first upper sub-patterns PTU1b. In addition, the plurality of second upper patterns PTU2 may include second upper main patterns PTU2a and second upper sub-patterns PTU2b. In this case, a plurality of second upper sub-patterns PTU2b may be disposed between the two second upper main patterns PTU2a, wherein the second upper main patterns PTU2a may be formed to have a longer length than the second upper sub-patterns PTU2b.

A first upper pattern PTU1 disposed at the outermost side among the plurality of first upper patterns PTU1 may be disposed on a second line L2 provided as an imaginary straight line. In this case, the first upper pattern PTU1 disposed at the outermost side may be disposed on the second line L2 in the first direction or the second direction to overlap the first lower pattern PTD1 designated as the target pattern. Thus, even though the first lower pattern PTD1 designated as the target pattern is etched by the etching process, the first upper pattern PTU1 disposed at the outermost side is not etched, allowing for more accurate monitoring of the outermost edge position of the substrate 110. For example, when viewed from the Z-axis direction, the first upper pattern PTU1, which is positioned at the outermost side, is disposed to overlap the first lower pattern PTD1, which is designated as the target pattern, in the first or second direction. In this case, even when the first lower pattern PTD1 designated as the target pattern is etched to make it difficult to determine the outermost edge position of the substrate 110, the outermost edge position of the substrate 110 may be more accurately monitored by means of the first upper pattern PTU1 disposed at the outermost side. Even when a first upper pattern PTU1 other than the first upper pattern PTU1 disposed at the outermost side is disposed to overlap the first lower pattern PTD1 designated as the target pattern in a first or second direction, the outermost edge position of the substrate 110 may be more accurately monitored by means of the first upper pattern PTU1 as described above. Thus, the display panel 100b may determine a defect for the outermost edge position of the substrate 110 by using the first upper pattern PTU1 which is disposed to overlap the first lower pattern PTD1 designated as the target pattern in the first direction or in the second direction.

Further, the plurality of first upper patterns PTU1 may be used in conjunction with the plurality of second upper patterns PTU2 to measure an slope angle θ with respect to the edge surface 110S of the substrate 110.

For example, the edge surface 110S formed to have a predetermined slope includes a top edge 110UE and a bottom edge 110DE. And, a first directional distance between the first upper pattern PTU1 of the first upper pattern group GU1 corresponding to the top edge 110UE and the second upper pattern PTU2 of the second upper pattern group GU2 corresponding to the bottom edge 110DE may be measured, and an slope angle θ of the edge surface 110S may be measured by using the above-mentioned first directional distance and the thickness T of the substrate 110. Thus, the slope of the edge surface 110S of the substrate 110 may be managed by controlling the etching process based on the measured slope angle θ. Here, the plurality of first upper patterns PTU1 and the plurality of second upper patterns PTU2 may be disposed to be spaced apart from each other along the first direction. In this case, the top edge 110UE of the edge surface 110S may be disposed along a second direction that is different from the first direction, and the first direction and the second direction may be perpendicular to each other.

Further, the plurality of first upper patterns PTU1 may be used in conjunction with the plurality of second upper patterns PTU2 to determine an slope allowable range RAS for the edge surface 110S of the substrate 110. Specifically, when a Safe determination is made for the outermost edge position of the substrate 110 using the first target pattern TPT1 and the second target pattern TPT2, the position of the top edge 110UE provided as the outermost edge position of the substrate 110 may be identified. In this case, if the position of the bottom edge 110DE of the substrate 110 is within the allowable range of the slope angle, it may facilitate the determination for the slope angle θ to be normal without measuring the slope angle θ.

For example, a first lower pattern PTD1 corresponding to the second edge 110E among the plurality of first lower patterns PTD1 may be recognized, and a first upper pattern PTU1 and a second upper pattern PTU2 corresponding to the recognized first lower pattern PTD1 may be easily detected by using the upper guide pattern UGPT. In this case, the detected first upper pattern PTU1 may represent an upper limit within the slope allowable range RAS, and the detected second upper pattern PTU2 may represent a lower limit within the slope allowable range RAS. Here, the interval between the detected first upper pattern PTU1 and the detected second upper pattern PTU2 in the first direction may represent the slope allowable range RAS. Thus, the display panel 100b may receive a Safe determination for the slope angle θ if the bottom edge 110DE is located within the interval between the detected first upper pattern PTU1 and the second upper pattern PTU2 in the first direction. The display panel 100b may then be identified to be a normal panel with respect to the slope angle θ of the edge surface 110S based on the Safe determination.

When viewed from the Z-axis direction, the plurality of upper guide patterns UGPT may be disposed between the first lower pattern group GD1 and the upper pattern groups GU1 and GU2. For example, when viewed from the Z-axis direction, a plurality of first upper guide patterns UGPT1 may be disposed between the first lower pattern group GD1 and the first upper pattern group GU1, and a plurality of second upper guide patterns UGPT2 may be disposed between the first lower pattern group GD1 and the second upper pattern group GU2. Here, the upper guide pattern UGPT is not etched by the etchant because it is disposed on the first planarization layer 117.

An upper guide pattern UGPT may be disposed to correspond to one pattern in the first lower pattern group GD1 and one pattern in each of the upper pattern groups GU1 and GU2. For example, one first upper guide pattern UGPT1 connects one first lower main pattern PTD1a and one first upper main pattern PTU1a, allowing the correspondence between the first lower main pattern PTD1a and the first upper main pattern PTU1a to be identified. Although it has been described as an example that the first upper guide pattern UGPT1 connecting the first lower main pattern PTD1a and the first upper main pattern PTU1a, it is not necessarily limited thereto. When the correspondence between the first lower main pattern PTD1a and the first upper main pattern PTU1a may be identified, the first upper guide pattern UGPT1 may be disposed to be disconnected from the first lower main pattern PTD1a or the first upper main pattern PTU1a. In addition, one second upper guide pattern UGPT2 may connect one first lower main pattern PTD1a and one second upper main pattern PTU2a, allowing the correspondence between the first lower main pattern PTD1a and the second upper main pattern PTU2a to be identified.

Therefore, since the first upper guide pattern UGPT1 extends from the first upper pattern PTU1 toward one side of one of a plurality of first lower patterns PTD1, and the second upper guide pattern UGPT2 extends from the second upper pattern PTU2 toward the other side of one of the first lower patterns PTD1, it is possible to identify the correspondence between the first upper pattern PTU1 and the second upper pattern PTU2.

Although it has been described as an example the display panel 100b includes two or more upper guide patterns UGPT disposed between the first lower pattern group GD1 and one upper pattern group, it is not necessarily limited thereto. In consideration of the recognition rate for the allowable range for the outermost edge position of the substrate 110, two upper guide patterns UGPT may be presented to correspond to the first lower pattern PTD1 designated as the target pattern in the first lower pattern group GD1.

Moreover, the upper guide pattern UGPT may be disposed to correspond to the slope angle θ of the edge surface 110S. Thus, from the disposed orientation of the upper guide pattern UGPT, it is possible to predict whether the slope angle θ of the edge surface 110S is an acute angle or an obtuse angle.

As shown in FIGS. 11, 18 to 20, since a positively tapered opening is formed in the mother glass substrate 10, the slope angle θ of the edge surface 110S may form an acute angle. As the slope angle θ of the edge surface 110S forms an acute angle, the second edge 110E of the substrate 110 is provided as the top edge 110UE and becomes a reference for etching some of the first lower patterns PTD1. And the plurality of first upper patterns PTU1 are disposed to be spaced apart by a predetermined distance from the first edge 100E of the display panel 100b so as to be provided as an element for identifying the slope angle θ of the edge surface 110S. Thus, when viewed from the Z-axis, the first upper guide pattern UGPT1 may be disposed to be inclined from an end of the first upper pattern PTU1 toward the first lower pattern PTD1. In this case, since the first upper pattern group GU1 is disposed at a second distance D2, which is larger than the first distance D1, the first upper guide pattern UGPT1 connecting the first lower pattern PTD1 and the first upper pattern PTU1, which correspond to each other, may be disposed inclined toward outward. Thus, since it is set to form a positively tapered opening on the mother glass substrate 10 in the process, and it can be seen that the first upper guide pattern UGPT1 is disposed to be inclined outwardly from the first upper pattern PTU1, it may be predicted based on the foregoing that the slope angle θ of the edge surface 110S will be formed at an acute angle. It may be also predicted that the slope angle θ of the edge surface 110S will be formed at an acute angle from the fact that it is set to form a positively tapered opening on the mother glass substrate 10 in the process and the second upper guide pattern UGPT2 is disposed to be inclined outwardly from the second upper pattern PTU2. Here, since an acute angle θ is formed based on a positively tapered opening on the mother glass substrate 10 and the first upper guide pattern UGPT1 is disposed to be inclined so that the foregoing can be identified, the first upper guide pattern UGPT1 may be referred to as a forward upper guide pattern.

FIG. 22 is a diagram conceptually illustrating the arrangement relationship between an edge and patterns of a substrate determined to be normal in a display panel of a display device according to another embodiment of the present disclosure.

As shown in FIG. 22, it is illustrated that the top edge 110UE provided as the second edge 110E of the substrate 110 is located between the first target pattern TPT1 and the second target pattern TPT2. Thus, the display panel 100b may receive a Safe determination for the outermost edge position of the substrate 110. Here, the first target pattern TPT1 may represent an upper limit of the outermost edge allowable range REP, and the second target pattern TPT2 may represent a lower limit of the outermost edge allowable range REP.

As the top edge 110UE is located between the first target pattern TPT1 and the second target pattern TPT2, the first lower pattern PTD1 corresponding to the top edge 110UE may be recognized. For example, a first lower pattern PTD1 in the first lower pattern group GD1 that overlaps the top edge 110UE in the Z-axis direction may be recognized. And, a first upper pattern PTU1 corresponding to the recognized first lower pattern PTD1 may be identified by an imaginary first upper matching guide line UMGL1. And, a second upper pattern PTU2 corresponding to the identified first lower pattern PTD1 may be identified by an imaginary second upper matching guide line UMGL2. Here, the first upper matching guide line UMGL1 may be an imaginary line disposed parallel to the first upper guide pattern UGPT1, and the second upper matching guide line UMGL2 may be an imaginary line disposed parallel to the second upper guide pattern UGPT2.

Because the outermost upper pattern PTU in the first upper pattern group GU1 is disposed to be spaced apart by a second distance D2 from the edge 100E of the display panel 100b, and the outermost upper pattern PTU in the second upper pattern group GU2 is disposed to be spaced apart by a third distance D3 from the edge 100E of the display panel 100b, an imaginary first matching line ML1 extending in the second direction (Y-axis direction) from a first upper pattern PTU1 corresponding to the identified first lower pattern PTD1 and an imaginary second matching line ML2 extending in the second direction (Y-axis direction) from a second upper pattern PTU2 corresponding to the recognized first lower pattern PTD1 have a predetermined interval in the first direction (X-axis direction). In this case, the interval between the first matching line ML1 and the second matching line ML2, which are spaced apart from each other in the first direction, may represent a preset slope allowable range RAS. Here, the imaginary first matching line ML1 may be an imaginary line extending in the second direction (Y-axis direction) from the first upper pattern PTU1 corresponding to one first lower pattern PTD1. In addition, the imaginary second matching line ML2 may be an imaginary line extending in the second direction (Y-axis direction) from the second upper pattern PTU2 corresponding to one first lower pattern PTD1. Although it has been described as an example that the display panel 100b discriminates between the first upper matching guide line UMGL1 and the first matching line ML1 for understanding the arrangement relationship between the recognized first lower pattern PTD1 and the first upper pattern PTU1 and the setting for the slope allowable range RAS, it is not necessarily limited thereto. For example, the first matching line ML1 may be an imaginary line that includes the first upper matching guide line UMGL1. In addition, although it has been described as an example that the display panel 100b discriminates between the second upper matching guide line UMGL2 and the second matching line ML2 for understanding the arrangement relationship between the identified first lower pattern PTD1 and the second upper pattern PTU2 and the setting for the slope allowable range RAS, it is not necessarily limited thereto. For example, the second matching line ML2 may be an imaginary line that includes the second upper matching guide line UMGL2.

The first matching line ML1 and the second matching line ML2, which are disposed at a distance from each other in the first direction (X-axis direction), makes it possible to set the slope allowable range RAS. For example, the edge surface 110S having a predetermined slope angle θ is formed by an etching process, and the slope angle θ may be measured using the thickness T of the substrate 110 and the distance on the plane between the top edge 110UE and the bottom edge 110DE as discussed above. As can be seen in FIG. 22, whether or not the edge 110E of the substrate 110 is normal may first be determined by means of the first lower pattern PTD1 corresponding to the top edge 110UE. And, according to the determination of whether the outermost edge position of the substrate 110 is normal or not, the first upper pattern PTU1 corresponding to the first lower pattern PTD1 in the first lower pattern group GD1 overlapping the top edge 110UE in the Z-axis direction may be designated by means of the first upper matching guide line UMGL1. And, the second upper pattern PTU2 corresponding to the first lower pattern PTD1 in the first lower pattern group GD1 overlapping the top edge 110UE in the Z-axis direction may be designated by means of the second upper matching guide line UMGL2. In this case, since the designated first upper pattern PTU1 and the designated second upper pattern PTU2 are designated according to the determination of whether the outermost edge position of the substrate 110 is normal, the designated first upper pattern PTU1 and the designated second upper pattern PTU2 may be used as a reference for determining whether the slope angle θ is normal. Thus, the interval between the first matching line ML1 extending in the second direction (Y-axis direction) from the designated first upper pattern PTU1 and the second matching line ML2 extending in the second direction (Y-axis direction) from the designated second upper pattern PTU2 may indicate the slope allowable range RAS, wherein the slope allowable range RAS may be used to determine whether or not the slope angle θ of the edge surface 110S is normal. In this case, the first matching line ML1 may represent an upper limit within the slope allowable range RAS for the edge surface 110S, and the second matching line ML2 may represent a lower limit within the slope allowable range RAS for the edge surface 110S.

Therefore, when the bottom edge 110DE is located between the first matching line ML1 and the second matching line ML2, the display panel 100b may receive a Safe determination for the slope angle θ of the edge surface 110S. In other words, the determination of whether the slope angle θ of the edge surface 110S is normal or not may be easily made by means of the bottom edge 110DE located between the first matching line ML1 and the second matching line ML2, without separate calculation. Here, the bottom edge 110DE may serve as a factor for measuring the slope angle θ of the edge surface 110S in conjunction with the top edge 110UE.

That is, each of a plurality of first lower patterns PTD1, a plurality of first upper patterns PTU1, and a plurality of second upper patterns PTU2 is disposed to be spaced apart from each other in the first direction, the first edge 100E of the display panel 100b is disposed in the second direction, and the first upper pattern PTU1 and the second upper pattern PTU2, which correspond to the first lower pattern PTD1 overlapping the top edge 110UE in the third direction, form a predetermined interval in the first direction, the slope allowable range RAS. And, when the bottom edge 110DE is located between the slope allowable range RAS, it may be easily determined that the display panel 100b is a normal panel.

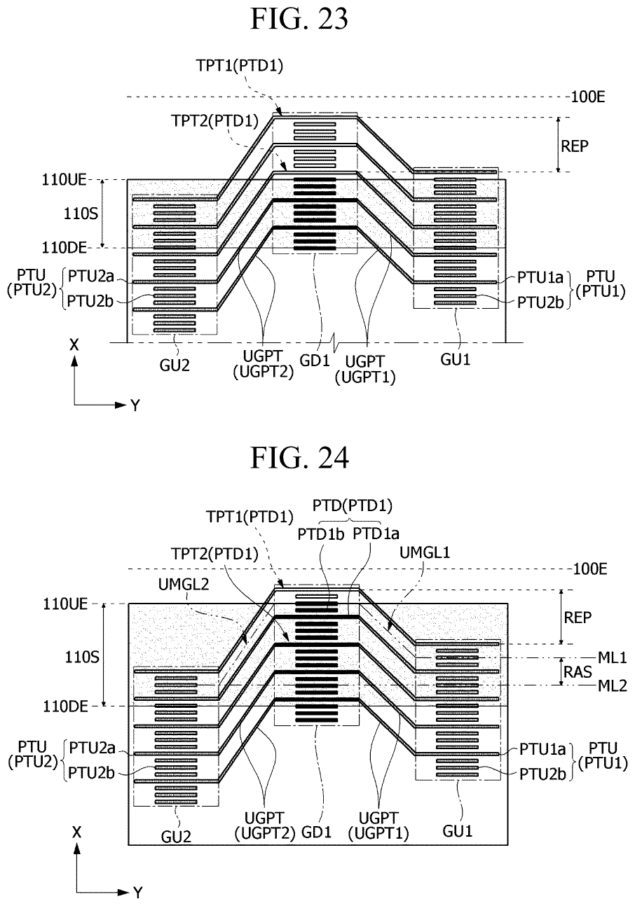

FIG. 23 is a diagram illustrating a defect of an edge position of a substrate determined by a plurality of patterns in a display panel of a display device in accordance with another embodiment of the present disclosure.

As shown in FIG. 23, it is illustrated that the top edge 110UE provided as the second edge 110E of the substrate 110 is located beyond the outermost edge allowable range REP as represented by the interval between the first target pattern TPT1 and the second target pattern TPT2. Thus, the display panel 100b may be classified as an abnormal panel by receiving an Out determination for the outermost edge position of the substrate 110.

FIG. 24 is a diagram illustrating a slope defect of a substrate determined by a plurality of patterns in a display panel of a display device accordance to another embodiment of the present disclosure.

As shown in FIG. 24, it is illustrated that the bottom edge 110DE of the substrate 110 is located beyond the slope allowable range RAS as represented by the interval between the first matching line ML1 and the second matching line ML2. Thus, the display panel 100b may be classified as an abnormal panel by receiving an Out determination with respect to the slope angle θ of the edge surface 110S of the substrate 110.

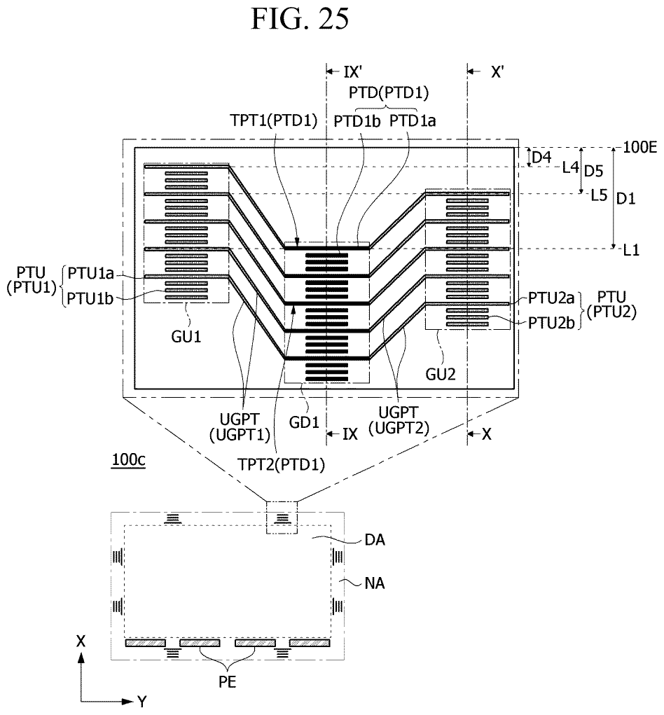

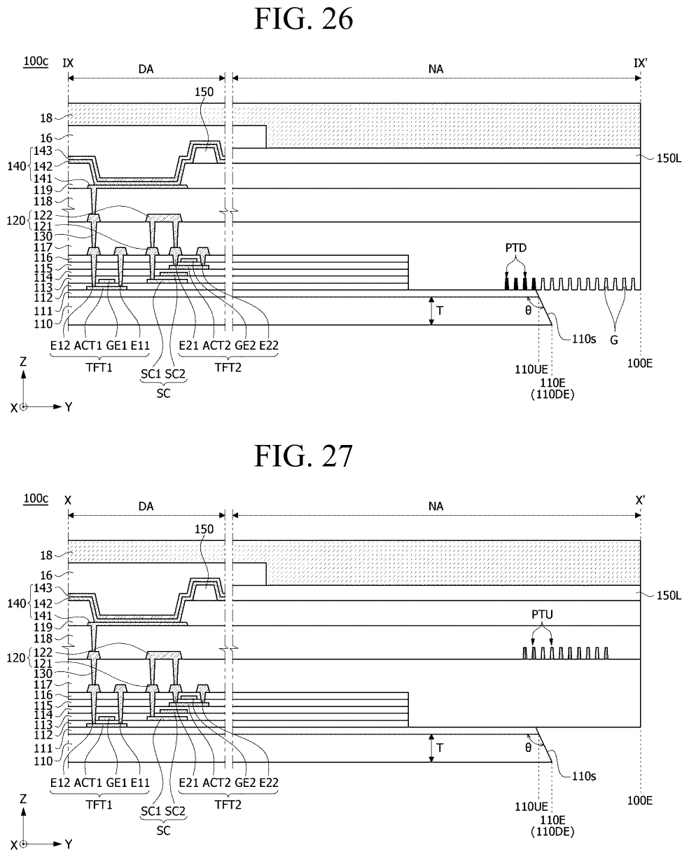

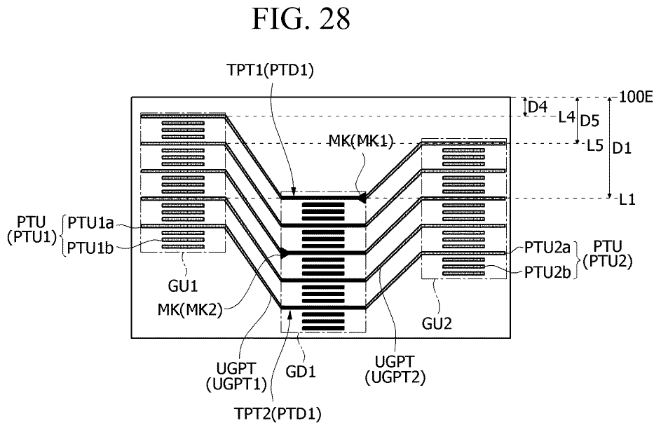

FIG. 25 is a plan view illustrating a display panel according to another embodiment of the present disclosure, FIG. 26 is a cross-sectional view taken along line IX-IX′ in FIG. 25, FIG. 27 is a cross-sectional view taken along line X-X′ in FIG. 25, and FIG. 28 is a plan view illustrating a mark of a display panel according to another embodiment of the present disclosure. An imaginary first line L1, an imaginary fourth line L4, and an imaginary fifth line L5 shown in FIG. 25 are parallel to the first edge 100E of the display panel 100c and/or the second edge 110E of the substrate 110. Here, the display panel 100c shown in FIGS. 25 to 28 may be referred to as a display panel according to a fourth embodiment.

When the display panel 100b of the third embodiment and the display panel 100c of the fourth embodiment are compared with reference to FIGS. 18 to 21 and 25 to 28, the display panel 100c of the fourth embodiment is different from the display panel 100b of the third embodiment in terms of an arrangement position of a first upper pattern group GU1 and a second upper pattern group GU2, an arrangement orientation of an upper guide pattern UGPT, and an edge surface 110S having an obtuse slope angle θ. Thus, the first upper pattern group GU1 of the display panel 100c according to the fourth embodiment may be referred to as a third upper pattern group, and the patterns included in the third upper pattern group may be referred to as third upper patterns, to distinguish it from the display panel 100b of the third embodiment. And, the second upper pattern group GU2 of the display panel 100c according to the fourth embodiment may be referred to as a fourth upper pattern group, and the patterns included in the fourth upper pattern group may be referred to as fourth upper patterns. And, the upper guide pattern UGPT of the display panel 100c according to the fourth embodiment may be referred to as a reverse upper guide pattern. In addition, a display device according to the embodiment of the present disclosure may use the display panel 100c according to the fourth embodiment instead of the display panel 100 according to the first embodiment.

In describing the display panel 100c according to the fourth embodiment with reference to FIGS. 25 to 28, the same components of the display panel 100b according to the third embodiment and the display panel 100c according to the fourth embodiment may be denoted by the same reference symbols, and thus a detailed description thereof will be omitted.

As shown in FIGS. 25 to 28, the display panel 100c according to the fourth embodiment includes a substrate 110, a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, a first transistor TFT1, a second transistor TFT2, a storage capacitor SC, a storage supply line 120, a connection electrode 130, a light-emitting element 140, a spacer 150, a spacer layer 150L, a pad electrode PE, an encapsulation layer 16, a polarizer 18, a side coating layer 190, a lower pattern group, a plurality of upper pattern groups GU1 and GU2, and a groove G. Further, the display panel 100c according to the fourth embodiment may include at least one upper guide patterns UGPT that guides the correspondence between patterns disposed in the lower pattern group and patterns disposed in one of the upper pattern groups GU1 and GU2. The lower pattern group shown in FIG. 25 may have the same configuration as the first lower pattern groups GD1 of the display panel 100a according to the second embodiment. Thus, the lower pattern group of the display panel 100c according to the fourth embodiment may be referred to as a first lower pattern group GD1, and will be described hereinafter as the first lower pattern group GD1.

The substrate 110 may include an edge surface 110S formed by an etching process. The edge surface 110S may be formed on the substrate 110 to have a predetermined slope angle θ by an etching process. As shown in FIGS. 26 and 27, the slope angle θ may represent an angle formed by the top surface of the substrate 110 and the edge surface 110S, and may be formed at an obtuse angle by an etching process that forms a reverse tapered opening in the mother glass substrate 10. Thus, the edge surface 110S of the substrate 110 includes a top edge 110UE and a bottom edge 110DE with respect to the Z-axis direction, wherein the top edge 110UE disposed at the outermost side of the substrate 110 may represent a second edge 110E of the substrate 110.

When viewed from the Z-axis direction, the first lower pattern group GD1, the first upper pattern group GU1, and the second upper pattern group GU2 may be disposed to be spaced apart from each other along the first edge 100E of the display panel 100c. For example, since the first lower pattern group GD1, the first upper pattern group GU1, and the second upper pattern group GU2 may be disposed to correspond to each of the four sides of the substrate 110, the first lower pattern group GD1, the first upper pattern group GU1, and the second upper pattern group GU2 may be disposed to be spaced apart from each other in a first direction or a second direction. Here, the first direction may represent the X-axis direction and the second direction may represent the Y-axis direction.

The first lower pattern group GD1, the first upper pattern group GU1, and the second upper pattern group GU2 may be disposed at different distances relative to the first edge 100E of the display panel 100c. For example, the outermost lower pattern PTD in the first lower pattern group GD1 may be disposed to be spaced apart from the first edge 100E of the display panel 100c by a first distance D1. The outermost upper pattern PTU in the first upper pattern group GU1 may be spaced apart from the first edge 100E of the display panel 100c by a second distance D4. The outermost upper pattern PTU of the second upper pattern group GU2 may be spaced apart from the first edge 100E of the display panel 100c by a fifth distance D5. Here, the fifth distance D5 is larger than the fourth distance D4 and smaller than the first distance D1. Thus, the display panel 100c may monitor the outermost edge position of the substrate 110 by using the first lower pattern group GD1. Moreover, the display panel 100c may facilitate monitoring the slope of the edge surface 110S of the substrate 110 by using the first upper pattern group GU1 and the second upper pattern group GU2.

When viewed from the Z-axis direction, the first lower pattern group GD1 may be disposed between the first upper pattern group GU1 and the second upper pattern group GU2.

The first lower pattern group GD1 may include a plurality of lower patterns PTD. For example, the first lower pattern group GD1 may include a plurality of first lower patterns PTD1.

The plurality of first lower patterns PTD1 may be disposed in an area adjacent to the edge 110E of the substrate 110, and may be disposed between the first buffer layer 111 and the first planarization layer 117.

The reverse tapered opening may be formed in the mother glass substrate 10 by an etching process. Thus, as shown in FIGS. 26 and 27, since the edge surface 110S having an obtuse slope angle θ is formed in the substrate 110 and the first lower pattern PTD1 disposed to overlap the edge surface 110S is etched by the etchant, it is difficult to identify the second edge 110E of the substrate 110 using the reflectivity of the first lower patterns PTD1. For example, in the case of the substrate 110 in which the edge surface 110S having an obtuse slope angle θ is formed, the first lower pattern PTD1 overlapping or adjacent to the bottom edge 110DE located at the outermost side of the substrate 110 is etched by the etching process, and it is therefore difficult to identify the position of the bottom edge 110DE through the first lower pattern PTD1. Therefore, even if the display device according to the present disclosure includes an edge surface 110S having an obtuse slope angle θ, the outermost edge position of the substrate 110 and the slope of the edge surface 110S of the substrate 110 may be easily monitored by identifying the bottom edge 110DE using the upper pattern groups GU1 and GU2 that are not etched by the etchant.

Here, the plurality of first lower patterns PTD1 in the first lower pattern group GD1 may correspond to the plurality of patterns PT of the display panel 100 according to the first embodiment. Therefore, the plurality of first lower patterns PTD1 may serve as a kind of scale for monitoring the amount of etching of the substrate 110 and the top edge 110UE of the substrate 110 formed by the etching process.

The plurality of first lower patterns PTD1 may include main patterns and sub-patterns. For example, the plurality of first lower patterns PTD1 may include first lower main patterns PTD1a and first lower sub-patterns PTD1b. In this case, a plurality of first lower sub-patterns PTD1b may be disposed between the two first lower main patterns PTD1a, wherein the first lower main patterns PTD1a may be formed to have a longer length than the first lower sub-patterns PTD1b.

Moreover, some of the plurality of first lower patterns PTD1 may be designated as target patterns. For example, two first lower main patterns PTD1a, which are spaced apart from each other, among the plurality of first lower patterns PTD1 may be designated as target patterns, and the display panel 100c may be determined to be a normal panel when the top edge 110UE of the substrate 110 is located between the two first lower main patterns PTD1a designated as target patterns.

Moreover, among the plurality of first lower patterns PTD1, a first lower pattern PTD1 disposed on an imaginary first line L1 and a first lower pattern PTD1 spaced inwardly from the first line L1 may be designated as a target pattern. Here, the first lower pattern PTD1 disposed on the first line L1 may be referred to as a first target pattern TPT1, and the first lower pattern PTD1 spaced apart from the first target pattern TPT1 by a predetermined interval may be referred to as a second target pattern TPT2, wherein the interval between the first target pattern TPT1 and the second target pattern TPT2 may represent a top edge allowance range RUEP of the substrate 110. In this case, the first target pattern TPT1 may represent an upper limit of the top edge allowable range of the substrate 110, and the second target pattern TPT2 may represent a lower limit of the top edge allowable range of the substrate 110. Therefore, when the second edge 110E of the substrate 110 is located between the first target pattern TPT1 and the second target pattern TPT2, the display panel 100c may receive a Safe determination for the top edge position of the substrate 110.

As shown in FIG. 28, the display panel 100c may further include a mark MK that makes the target pattern recognizable. The mark MK may include a first mark MK1 and a second mark MK2.

The first mark MK1 may be disposed on the first target pattern TPT1. The second mark MK2 may be disposed to correspond to the second target pattern TPT2. Therefore, when the top edge 110UE of the substrate 110 is located between the first mark MK1 and the second mark MK2, the display panel 100c may receive a Safe determination for the top edge position of the substrate 110.

The first upper pattern group GU1 may include a plurality of upper patterns PTU. For example, the first upper pattern group GU1 may include a plurality of first upper patterns PTU1.

The plurality of first upper patterns PTU1 may be disposed to be spaced apart from the first edge 100E of the display panel 100c by a predetermined distance, and may be disposed on the first planarization layer 117.

The plurality of upper pattern groups GU2 and GU1 may be disposed to be spaced apart from each other by a predetermined interval on the first planarization layer 117. Thus, the upper patterns PTUs in the plurality of upper pattern groups GU1 and GU2 remain even after the etching process is performed on the substrate 110.

Each of the plurality of upper pattern groups GU2 and GU1 may include a plurality of upper patterns PTU disposed to be spaced apart from each other, and the upper patterns PTU may be disposed parallel to the second edge 110E of the substrate 110. Here, the upper patterns PTU disposed in the first upper pattern group GU1 may be referred to as first upper patterns, and the upper patterns PTU disposed in the second upper pattern group GU2 may be referred to as second upper patterns. The plurality of first upper patterns and the plurality of second upper patterns may include main patterns and sub-patterns, as in the plurality of patterns PT disposed on the display panel 100 according to the first embodiment.

The plurality of upper pattern groups GU1 and GU2 may include, but is not necessarily limited to, the first upper pattern group GU1 and the second upper pattern group GU2. For example, the display panel 100c may include the first upper pattern group GU1, or it may include three or more upper pattern groups.

The first upper pattern group GU1 may include a plurality of upper patterns PTU. For example, the first upper pattern group GU1 may include a plurality of first upper patterns PTU1.

The second upper pattern group GU2 may include a plurality of upper patterns PTU. For example, the second upper pattern group GU2 may include a plurality of second upper patterns PTU2.

The plurality of first upper patterns PTU1 and second upper patterns PTU2 may be disposed to be spaced apart from the first edge 100E of the display panel 100c by a predetermined distance, and may be disposed on the first planarization layer 117.

The plurality of first upper patterns PTU1 and second lower patterns PTU2 may include main patterns and sub-patterns. For example, the plurality of first upper patterns PTU1 may include first upper main patterns PTU1a and first upper sub-patterns PTU1b. In this case, a plurality of first upper sub-patterns PTU1b may be disposed between the two first upper main patterns PTU1a, wherein the first upper main patterns PTU1a may be formed to have a longer length than the first upper sub-patterns PTU1b. In addition, the plurality of second upper patterns PTU2 may include second upper main patterns PTU2a and second upper sub-patterns PTU2b. In this case, a plurality of second upper sub-patterns PTU2b may be disposed between the two second upper main patterns PTU2a, wherein the second upper main patterns PTU2a may be formed to have a longer length than the second upper sub-patterns PTU2b.

A first upper pattern PTU1 disposed at the outermost side among the plurality of first upper patterns PTU1 may be disposed on a fourth line L4 provided as an imaginary straight line. In this case, the first upper pattern PTU1 disposed at the outermost side may be disposed on the fourth line L4 in the first direction or the second direction to be spaced apart from the first lower pattern PTD1 designated as the target pattern.

In addition, a second upper pattern PTU2 disposed at the outermost side among the plurality of second upper patterns PTU2 may be disposed on a fifth line L5 provided as an imaginary straight line. In this case, each of the first upper pattern PTU1 and the second upper pattern PTU2 disposed at the outermost side may be disposed to be spaced apart in the first direction or the second direction from the first lower pattern PTD1 disposed at the outermost side. However, some of the plurality of first upper patterns PTU1 that are disposed more inwardly than the outermost first upper patterns PTU1 may overlap some of the plurality of first lower patterns PTD1 in the first direction or the second direction. For example, a first lower pattern PTD1 disposed at the outermost side may overlap one of a plurality of first upper patterns PTU1 in the first direction or the second direction. In addition, some of the plurality of second upper patterns PTU2 that are disposed more inwardly than of the outermost second upper pattern PTU2 may overlap some of the plurality of first lower patterns PTD1 in the first direction or the second direction. For example, a first lower pattern PTD1 disposed at the outermost side may overlap with one of a plurality of second upper patterns PTU2 in the first direction or the second direction.

Thus, when the first lower pattern PTD1 disposed on the first line L1 is designated as the first target pattern TPT1 and the first lower pattern PTD1 spaced apart from the first target pattern TPT1 by a predetermined interval is designated as the second target pattern TPT2, the first lower pattern PTD1 corresponding to the top edge 110UE and also disposed between the first target pattern TPT1 and the second target pattern TPT2 may be etched. In this case, the position of the bottom edge 110DE of the substrate 110 may be identified by the first upper pattern PTU1 or the second upper pattern PTU2, which have not been etched. Moreover, in the case where the first lower pattern PTD1 designated as the second target pattern TPT2 overlap the first upper pattern PTU1 or the second upper pattern PTU2 in the first direction or the second direction, the position of the top edge 110UE of the substrate 110 may also be identified by the first upper pattern PTU1 or the second upper pattern PTU2.

Further, the plurality of first upper patterns PTU1 may be used in conjunction with the plurality of second upper patterns PTU2 to measure an slope angle θ with respect to the edge surface 110S of the substrate 110.

For example, the edge surface 110S formed to have a predetermined slope includes a top edge 110UE and a bottom edge 110DE. And a first directional distance between the first upper pattern PTU1 of the first upper pattern group GU1 corresponding to the top edge 110UE and the second upper pattern PTU2 of the second upper pattern group GU2 corresponding to the bottom edge 110DE may be measured, and an slope angle θ of the edge surface 110S may be measured by using the above-mentioned first directional distance and the thickness T of the substrate 110. Thus, the slope of the edge surface 110S of the substrate 110 may be managed by controlling the etching process based on the measured slope angle θ. Here, the plurality of first upper patterns PTU1 and the plurality of second upper patterns PTU2 may be disposed to be spaced apart from each other along the first direction. In this case, the top edge 110UE of the edge surface 110S may be disposed along a second direction that is different from the first direction, and the first direction and the second direction may be perpendicular to each other.

Further, the plurality of first upper patterns PTU1 may be used in conjunction with the plurality of second upper patterns PTU2 to determine a slope allowable range for the edge surface 110S of the substrate 110. Specifically, when a Safe determination is first made for the top edge position of the substrate 110 using the first target pattern TPT1 and the second target pattern TPT2, the position of the top edge 110UE may be identified. In this case, if the position of the bottom edge 110DE of the substrate 110 is within the allowable range of the slope angle, it may facilitate the determination for the slope angle θ to be normal without measuring the slope angle θ.

For example, a first lower pattern PTD1 corresponding to the top edge 110UE among the plurality of first lower patterns PTD1 may be recognized, and a first upper pattern PTU1 and a second upper pattern PTU2 corresponding to the recognized first lower pattern PTD1 may be easily detected by the lower guide pattern UGPT. In this case, the detected first upper pattern PTU1 may represent an upper limit within the slope allowable range, and the detected second upper pattern PTU2 may represent a lower limit within the slope allowable range. Here, the interval between the detected first upper pattern PTU1 and the detected second upper pattern PTU2 in the first direction may represent the slope allowable range. Thus, the display panel 100c may receive a Safe determination for the slope angle θ if the bottom edge 110DE is located within the interval between the detected first upper pattern PTU1 and the second upper pattern PTU2 in the first direction. The display panel 100c may then be identified to be a normal panel with respect to the slope angle θ of the edge surface 110S based on the Safe determination.

When viewed from the Z-axis direction, the plurality of upper guide patterns UGPT may be disposed between the first lower pattern group GD1 and the upper pattern groups GU1 and GU2. For example, when viewed from the Z-axis direction, a plurality of first upper guide patterns UGPT1 may be disposed between the first lower pattern group GD1 and the first upper pattern group GU1, and a plurality of second upper guide patterns UGPT2 may be disposed between the first lower pattern group GD1 and the second upper pattern group GU2.

An upper guide pattern UGPT may be disposed to correspond to one pattern in the first lower pattern group GD1 and one pattern in each of the upper pattern groups GU1 and GU2. For example, one first upper guide pattern UGPT1 connects one first lower main pattern PTD1a and one first upper main pattern PTU1a, allowing the correspondence between the first lower main pattern PTD1a and the first upper main pattern PTU1a to be identified. Although it has been described as an example that the first upper guide pattern UGPT1 connects the first lower main pattern PTD1a and the first upper main pattern PTU1a, it is not necessarily limited thereto. When the correspondence between the first lower main pattern PTD1a and the first upper main pattern PTU1a may be identified, the first upper guide pattern UGPT1 may be disposed to be disconnected from the first lower main pattern PTD1a or the first upper main pattern PTU1a. In addition, one second upper guide pattern UGPT2 may connect one first lower main pattern PTD1a and one second upper main pattern PTU2a, allowing the correspondence between the first lower main pattern PTD1a and the second upper main pattern PTU2a to be identified.

Although it has been described as an example that the display panel 100c includes two or more upper guide patterns UGPT disposed between the first lower pattern group GD1 and one upper pattern group, it is not necessarily limited thereto. In consideration of the recognition rate for the allowable range for the outermost edge position of the substrate 110, two upper guide patterns UGPT may be presented to correspond to the first lower pattern PTD1 designated as the target pattern in the first lower pattern group GD1.

Moreover, the upper guide pattern UGPT may be disposed to correspond to the slope angle θ of the edge surface 110S. Thus, from the disposed orientation of the upper guide pattern UGPT, it is possible to predict whether the slope angle θ of the edge surface 110S is an acute angle or an obtuse angle.

As shown in FIG. 10 and FIGS. 25 to 27, an reverse tapered opening may be formed in the mother glass substrate 10, and since the reverse tapered opening is formed in the mother glass substrate 10, the slope angle θ of the edge surface 110S may form an obtuse angle. As the slope angle θ of the edge surface 110S forms an obtuse angle, the top edge 110E of the substrate 110 becomes a reference for etching some of the first lower patterns PTD1. Moreover, the plurality of first upper patterns PTU1 are disposed to be spaced apart by a predetermined distance from the first edge 100E of the display panel 100c so as to be provided as an element for identifying the slope angle θ of the edge surface 110S. Thus, when viewed from the Z-axis, the first upper guide pattern UGPT1 may be disposed to be inclined from an end of the first upper pattern PTU1 toward the first lower pattern PTD1. In this case, since the first upper pattern group GU1 is disposed at the fourth distance D4 that is smaller than the first distance D1, the first upper guide pattern UGPT1 connecting the first lower pattern PTD1 and the first upper pattern PTU1, which correspond to each other, may be disposed to be inclined inwardly. Thus, it may be identified that the first lower guide pattern UGPT1 is disposed to be inclined outwardly from the one end, and based on this, it may be predicted that the slope angle θ of the edge surface 110S is obtuse. Further, from the second upper guide pattern UGPT2, which is disposed to be inclined inwardly, it is possible to predict that the slope angle (0) of the edge surface 110S is obtuse.

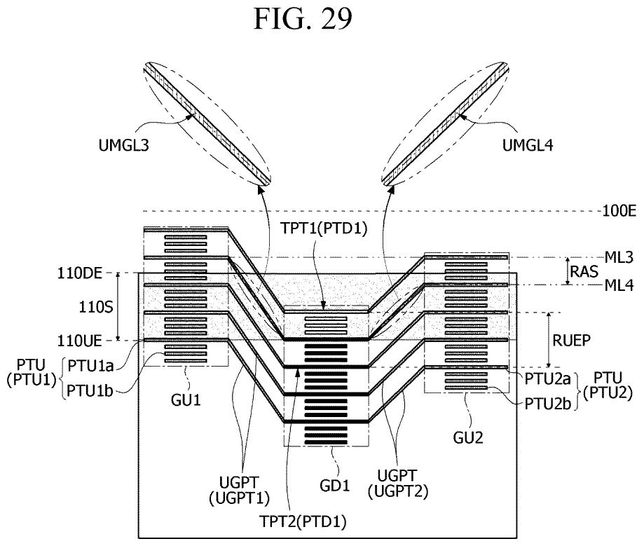

FIG. 29 is a diagram conceptually illustrating the arrangement relationship between an edge and patterns of a substrate determined to be normal in a display panel of a display device according to another embodiment of the present disclosure.

As shown in FIG. 29, it is illustrated that a top edge 110UE is located between a first target pattern TPT1 and a second target pattern TPT2. Thus, the display panel 100c may receive a Safe determination for the top edge position of the substrate 110. Here, the first target pattern TPT1 may represent an upper limit of a top edge allowable range RUEP, and the second target pattern TPT2 may represent a lower limit of the top edge allowable range RUEP.

In some embodiments, the top edge 110UE is located between the first target pattern TPT1 and the second target pattern TPT2 such that the first lower pattern PTD1 corresponding to the top edge 110UE may be recognized. For example, a first lower pattern PTD1 in the first lower pattern group GD1 that overlaps the top edge 110UE in the Z-axis direction may be recognized. Moreover, a first upper pattern PTU1 corresponding to the recognized first lower pattern PTD1 may be identified by an imaginary third upper pattern matching guide line UMGL3 and, a second upper pattern PTU2 corresponding to the identified first lower pattern PTD1 may be identified by an imaginary fourth upper matching guide line UMGL4. In some embodiments, the third upper matching guide line UMGL3 may be an imaginary line disposed parallel to the first upper guide pattern UGPT1, and the fourth upper matching guide line UMGL4 may be an imaginary line disposed parallel to the second upper guide pattern UGPT2.

In some embodiments, the outermost upper pattern PTU in the first upper pattern group GU1 is disposed so as to be spaced apart by a fourth distance D4 from the edge 100E of the display panel 100c and the outermost upper pattern PTU in the second upper pattern group GU2 is disposed so as to be spaced apart by a fifth distance D5 from the edge 100E of the display panel 100c. As such, an imaginary third matching line ML3 extending in the second direction (Y-axis direction) from a first upper pattern PTU1 corresponding to the recognized first lower pattern PTD1 and an imaginary fourth matching line ML4 extending in the second direction (Y-axis direction) from a second upper pattern PTU2 corresponding to the recognized first lower pattern PTD1 may have a predetermined interval in the first direction (X-axis direction). In this case, the interval between the third matching line ML3 and the fourth matching line ML4, which may be spaced apart from each other in the first direction, may represent a preset slope allowable range RAS. The imaginary third matching line ML3 may be an imaginary line extending in the second direction (Y-axis direction) from the first upper pattern PTU1 corresponding to one first lower pattern PTD1. In addition, the imaginary fourth matching line ML4 may be an imaginary line extending in the second direction (Y-axis direction) from the second upper pattern PTU2 corresponding to one first lower pattern PTD1. Although it has been described as an example that the display panel 100c discriminates between the third upper matching guide line UMGL3 and the third matching line ML3 for understanding the arrangement relationship between the recognized first lower pattern PTD1 and the first upper pattern PTU1 and the setting for the slope allowable range RAS, it is not necessarily limited thereto. For example, the third matching line ML3 may be an imaginary line that includes the third upper matching guide line UMGL3. In addition, although it has been described as an example that the display panel 100c discriminates between the fourth upper matching guide line UMGL4 and the fourth matching line ML4 for understanding the arrangement relationship between the identified first lower pattern PTD1 and the second upper pattern PTU2 and the setting for the slope allowable range RAS, it is not necessarily limited thereto. For example, the fourth matching line ML4 may be an imaginary line that includes the fourth upper matching guide line UMGL4.

The slope allowable range RAS may be set by means of the third matching line ML3 and the fourth matching line ML4, which are arranged at a distance from each other in the first direction (X-axis direction). For example, in some embodiments, the edge surface 110S having a predetermined slope angle θ is formed by an etching process, and the slope angle θ may be measured using the thickness T of the substrate 110 and the distance on the plane between the top edge 110UE and the bottom edge 110DE as discussed above. As shown in FIG. 29, whether or not the edge 110UE of the substrate 110 is normal may first be determined by means of the first lower pattern PTD1 corresponding to the top edge 110UE. According to the determination of whether the position of the top edge 110UE of the substrate is normal, the first upper pattern PTU1 corresponding to the first lower pattern PTD1 in the first lower pattern group GD1 overlapping the top edge 110UE in the Z-axis direction may be designated by the third upper matching guide line UMGL3. The second upper pattern PTU2 corresponding to the first lower pattern PTD1 in the first lower pattern group GD1 overlapping the top edge 110UE in the Z-axis direction may be designated by the fourth upper matching guide line UMGL4. In some embodiments, where the designated first upper pattern PTU1 and the designated second upper pattern PTU2 are designated according to the determination of whether or not the position of the top edge 110UE is normal, the designated first upper pattern PTU1 and the designated second upper pattern PTU2 may be used as a reference for determining whether the slope angle θ is normal. Thus, the interval between the third matching line ML3 extending in the second direction (Y-axis direction) from the designated first upper pattern PTU1 and the fourth matching line ML4 extending in the second direction (Y-axis direction) from the designated second upper pattern PTU2 may be indicative of the slope allowable range RAS, wherein the slope allowable range RAS may be used to determine whether or not the slope angle θ of the edge surface 110S is normal. In this case, the third matching line ML3 may represent an upper limit within the slope allowable range RAS for the edge surface 110S, and the fourth matching line ML4 may represent a lower limit within the slope allowable range RAS for the edge surface 110S.

Therefore, when the bottom edge 110DE is located between the third matching line ML3 and the fourth matching line ML4, the display panel 100c may receive a Safe determination for the slope angle θ of the edge surface 110S. In other words, the determination of whether the slope angle θ of the edge surface 110S is normal or not may be easily made by means of the bottom edge 110DE located between the third matching line ML3 and the fourth matching line ML4, without separate calculation. Here, the bottom edge 110DE may serve as a factor for measuring the slope angle θ of the edge surface 110S in conjunction with the top edge 110UE.

That is, each of a plurality of first lower patterns PTD1, a plurality of first upper patterns PTU1, and a plurality of second upper patterns PTU2 is disposed to be spaced apart from each other in the first direction, the first edge 100E of the display panel 100c is disposed in the second direction, and the first upper pattern PTU1 and the second upper pattern PTU2, which correspond to the first lower pattern PTD1 overlapping the top edge 110UE in the third direction, form a predetermined interval in the first direction, the slope allowable range RAS. And, when the bottom edge 110DE is located between the slope allowable ranges RAS, it may be easily determined that the display panel 100c is a normal panel.

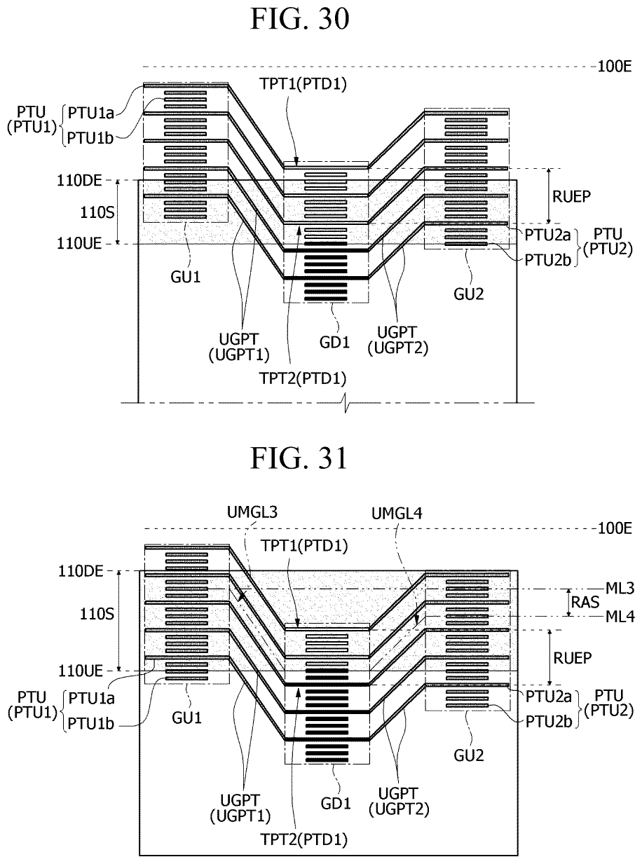

FIG. 30 is a diagram illustrating a defect of an edge position of a substrate determined by a plurality of patterns in a display panel of a display device in accordance with another embodiment of the present disclosure.

As shown in FIG. 30, it is illustrated that the top edge 110UE is located beyond a top edge allowable range RUEP as represented by the interval between a first target pattern TPT1 and a second target pattern TPT2. Thus, the display panel 100c may be classified as an abnormal panel by receiving an Out determination for the top edge position of the substrate 110.

FIG. 31 is a diagram illustrating a slope defect of a substrate determined by a plurality of patterns in a display panel of a display device according to another embodiment of the present disclosure.

As shown in FIG. 31, it is illustrated that the bottom edge 110DE of the substrate 110 is located beyond the slope allowable range RAS as represented by the interval between the third matching line ML3 and the fourth matching line ML4. Thus, the display panel 100c may be classified as an abnormal panel by receiving an Out determination with respect to the slope angle θ of the edge surface 110S of the substrate 110.

Therefore, when the bottom edge 110DE is located between the third matching line ML3 and the fourth matching line ML4, the display panel 100c may receive a Safe determination for the slope angle θ of the edge surface 110S. In other words, the determination of whether the slope angle θ of the edge surface 110S is normal or not may be easily made by means of the bottom edge 110DE located between the third matching line ML3 and the fourth matching line ML4, without separate calculation.

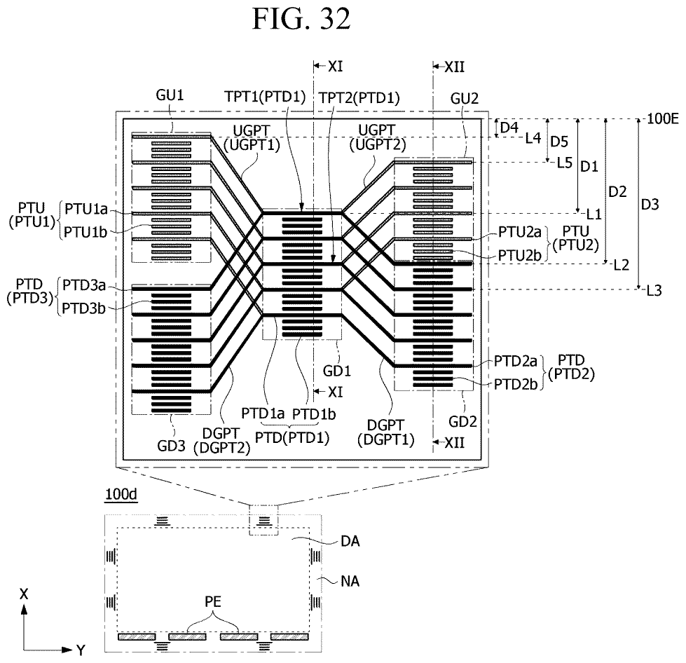

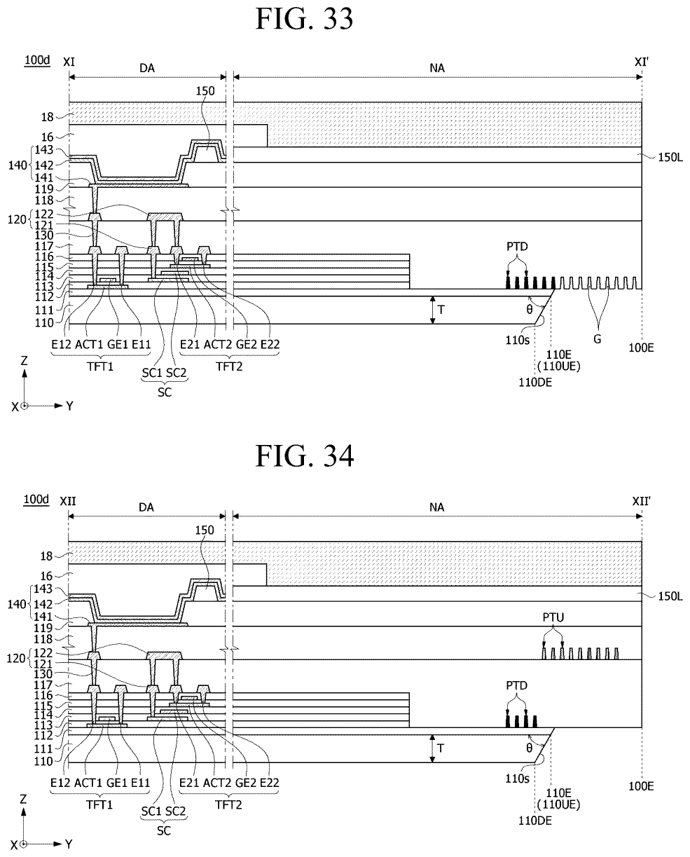

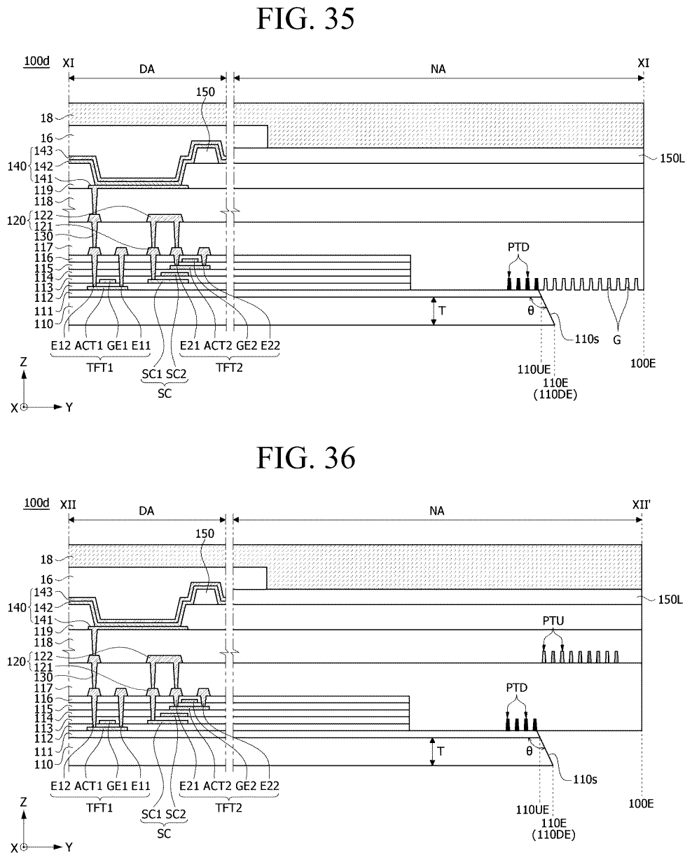

FIG. 32 is a plan view illustrating a display panel according to another embodiment of the present disclosure, FIG. 33 is a cross-sectional taken along lines XI-XI′ in FIG. 32 illustrating the slope of an acute angle, FIG. 34 is a cross-sectional taken along lines XII-XII′ in FIG. 32 illustrating the slope of an acute angle, FIG. 35 is a cross-sectional view taken along lines XI-XI′ in FIG. 32 illustrating the slope of an obtuse angle, and FIG. 36 is a cross-sectional view taken along lines XII-XII′ in FIG. 32 illustrating the slope of an obtuse angle. An imaginary first line L1, an imaginary second line L2, an imaginary third line L3, an imaginary fourth line L4, and an imaginary fifth line L5 shown in FIG. 32 are parallel to a first edge 100E of a display panel 100d and/or a second edge 110E of the substrate 110. Here, the display panel 100d shown in FIGS. 32 to 36 may be referred to as a display panel according to a fifth embodiment.

In the display panel 100d according to the fifth embodiment, even if the slope angle θ of the edge surface 110S is changed based on the lower pattern groups GD1, GD2, and GD3 of the display panel 100a according to the second embodiment and the upper pattern groups GU1 and GU2 of the display panel 100c according to the fourth embodiment, it may be possible to identify whether there is a defect according to the positions of the top edge 110UE and the bottom edge 110DE and whether there is a defect according to the slope allowable range RAS.

In describing the display panel 100d according to the fifth embodiment with reference to FIGS. 32 to 36, the same components of the display panel 100a according to the second embodiment, the display panel 100c according to the fourth embodiment, and the display panel according to the fifth embodiment may be denoted by the same reference symbols, and thus a detailed description thereof will be omitted.

As shown in FIGS. 32 to 36, the display panel 100d according to the fifth embodiment includes a substrate 110, a first buffer layer 111, a first gate insulating layer 112, a first interlayer insulating layer 113, a second buffer layer 114, a second gate insulating layer 115, a second interlayer insulating layer 116, a first planarization layer 117, a second planarization layer 118, a bank 119, a first transistor TFT1, a second transistor TFT2, a storage capacitor SC, a storage supply line 120, a connection electrode 130, a light-emitting element 140, a spacer 150, a spacer layer 150L, a pad electrode PE, an encapsulation layer 16, a polarizer 18, a side coating layer 190, a plurality of lower pattern groups GD1, GD2, and GD3, a plurality of upper pattern groups GU1 and GU2, and a groove G. Further, the display panel 100d according to the fifth embodiment may include a plurality of lower guide patterns DGPT that guide the correspondence between patterns disposed in one lower pattern group and patterns disposed in the other lower pattern group. Further, the display panel 100d according to the fifth embodiment may include a plurality of upper guide patterns UGPT that guide the correspondence between patterns disposed in the lower pattern group GD1 and patterns disposed in one of the upper pattern groups GU1 and GU2.

The substrate 110 may include an edge surface 110S formed by an etching process. The edge surface 110S may be formed on the substrate 110 to have a predetermined slope angle θ by an etching process. The slope angle θ may represent the angle formed by the top surface of the substrate 110 and the edge surface 110S, which may be acute or obtuse according to the etching process.

The edge surface 110S of the substrate 110 includes a top edge 110UE and a bottom edge 110DE with respect to the Z-axis direction, and one of the top edge 110UE and the bottom edge 110DE of the substrate 110 may be disposed at the outermost side due to the etching process to be provided as the second edge 110E of the substrate 110.

When viewed from the Z-axis direction, the first lower pattern group GD1, the second lower pattern group GD2, and the third lower pattern group GD3 may be disposed below the first planarization layer 117 such that they are spaced apart from each other along the first edge 100E of the display panel 100d on a horizontal plane. In this case, the first lower pattern group GD1 may be disposed between the second lower pattern group GD2 and the third lower pattern group GD3.

Further, when viewed from the Z-axis direction, the first lower pattern group GD1 may be disposed between the first upper pattern group GU1 and the second upper pattern group GU2. Here, the first upper pattern group GU1 and the second upper pattern group GU2 are disposed on the first planarization layer 117 and thus may not be affected by an etchant.

Further, the second lower pattern group GD2 may be disposed to overlap the second upper pattern group GU2 in a horizontal direction, and the third lower pattern group GD3 may be disposed to overlap the first upper pattern group GU1 in the horizontal direction. Here, the horizontal direction may refer to a direction perpendicular to the Z-axis direction, and may include a first direction that is the X-axis direction and a second direction that is the Y-axis direction. As shown in FIG. 32, the second lower pattern group GD2 may overlap the second upper pattern group GU2 in the first direction, and the third lower pattern group GD3 may overlap the first upper pattern group GU1 in the first direction, but are not necessarily limited thereto. For example, in the case where the second edge 110E of the substrate 110 is disposed along the first direction, the second lower pattern group GD2 may overlap the second upper pattern group GU2 in the second direction, and the third lower pattern group GD3 may overlap the first upper pattern group GU1 in the second direction.

The first lower pattern group GD1, the second lower pattern group GD2, the third lower pattern group GD3, the first upper pattern group GU1, and the second upper pattern group GU2 may be disposed at different distances relative to the first edge 100E of the display panel 100d. For example, the outermost lower pattern PTD in the first lower pattern group GD1 may be disposed to be spaced apart from the first edge 100E of the display panel 100d by a first distance D1. And the outermost lower pattern PTD in the second lower pattern group GD2 may be disposed to be spaced apart from the first edge 100E of the display panel 100d by a second distance D2. And the outermost lower pattern PTD in the third lower pattern group GD3 may be disposed to be spaced apart from the first edge 100E of the display panel 100d by a third distance D3. And the outermost upper pattern PTU in the first upper pattern group GU1 may be disposed to be spaced apart from the first edge 100E of the display panel 100d by a fourth distance D4. And, the outermost upper pattern PTU of the second upper pattern group GU2 may be spaced apart from the first edge 100E of the display panel 100d by a fifth distance D5. Here, the second distance D2 is larger than the first distance D1 and smaller than the third distance D3. And the fifth distance D5 is larger than the fourth distance D4 and smaller than the first distance D1.

Thus, the display panel 100d may monitor the position of the edge of the substrate 110 by using the first lower pattern group GD1. Moreover, the display panel 100d may easily monitor the slope of the edge surface 110S of the substrate 110 by using the second lower pattern group GD2 and the third lower pattern group GD3 or the first upper pattern group GU1 and the second upper pattern group GU2.

Each of the plurality of lower pattern groups GD1, GD2, and GD3 may include a plurality of lower patterns PTD.

The first lower pattern group GD1 may include a plurality of first low patterns PTD1. The second lower pattern group GD2 may include a plurality of second lower patterns PTD2. And the third lower pattern group GD3 may include a plurality of third lower patterns PTD3. Herein, a first lower pattern PTD1 disposed at the outermost side among the plurality of first lower patterns PTD1 may be disposed on a first line L1 provided as an imaginary straight line. A second lower pattern PTD2 disposed at the outermost side among the plurality of second lower patterns PTD2 may be disposed on the second line L2 provided as an imaginary straight line. And a third lower pattern PTD3 disposed at the outermost side among the plurality of third lower patterns PTD3 may be disposed on a third line L3 provided as an imaginary straight line.

Moreover, some of the plurality of first lower patterns PTD1 may be designated as target patterns. For example, among the plurality of first lower patterns PTD1, the first lower pattern PTD1 disposed on the imaginary first line L1 and the first lower pattern PTD1 disposed on an imaginary second line L2 may be designated as the target patterns, wherein the first lower pattern PTD1 disposed on the first line L1 may be referred to as a first target pattern TPT1, and the first lower pattern PTD1 disposed on the second line L2 may be referred to as a second target pattern TPT2.

Each of the plurality of upper pattern groups GU1 and GU2 may include a plurality of upper patterns PTU.

The first upper pattern group GU1 may include a plurality of first upper patterns PTU1. The second upper pattern group GU2 may include a plurality of first upper patterns PTU2. In addition, a first upper pattern PTU1 disposed at the outermost side among the plurality of first upper patterns PTU1 may be disposed on a fourth line L4 provided as an imaginary straight line. In addition, a second upper pattern PTU2 disposed at the outermost side among the plurality of second upper patterns PTU2 may be disposed on a fifth line L5 provided as an imaginary straight line.

Moreover, the plurality of lower patterns PTD and the plurality of upper patterns PTU may include main patterns and sub-patterns.

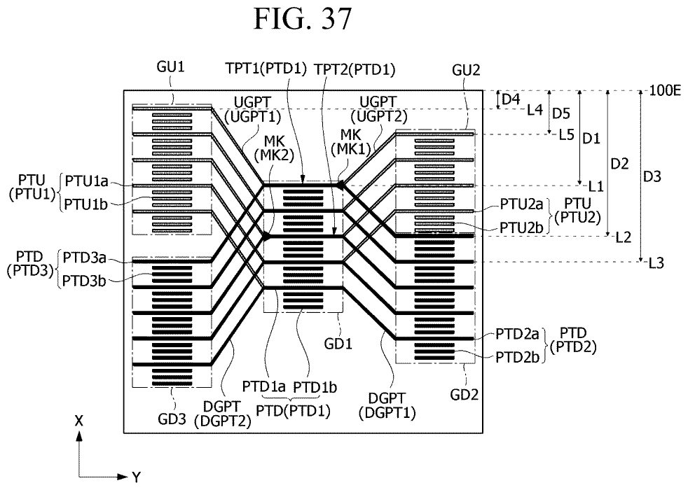

As shown in FIG. 37, the display panel 100d may further include a mark MK that makes the target pattern recognizable. The mark MK may include a first mark MK1 and a second mark MK2.

The first mark MK1 may be disposed on the first target pattern TPT1. The second mark MK2 may be disposed to correspond to the second target pattern TPT2.

The plurality of lower guide patterns DGPT may be disposed between the plurality of lower pattern groups GD1, GD2, and GD3. For example, a plurality of first lower guide patterns DGPT1 may be disposed between the first lower pattern group GD1 and the second lower pattern group GD2, and a plurality of second lower guide patterns DGPT2 may be disposed between the second lower pattern group GD2 and the third lower pattern group GD3. Herein, a lower guide patterns DGPT may be disposed to correspond to one pattern in one lower pattern group and one pattern in another lower pattern group.

When viewed from the Z-axis direction, the plurality of upper guide patterns UGPT may be disposed between the first lower pattern group GD1 and the upper pattern groups GU1 and GU2. For example, when viewed from the Z-axis direction, a plurality of first upper guide patterns UGPT1 may be disposed between the first lower pattern group GD1 and the first upper pattern group GU1, and a plurality of second upper guide patterns UGPT2 may be disposed between the first lower pattern group GD1 and the second upper pattern group GU2.

Meanwhile, after identifying that one of the top edge 110UE and the bottom edge 110DE is located between the first target pattern TPT1 and the second target pattern TPT2, it may be identified whether or not the edge surface 110S overlaps the upper pattern groups GU1 and GU2 in the Z-axis direction, and thus it may be identified whether the slope angle θ of the edge surface 110S is acute or obtuse. For example, if the edge surface 110S overlaps the upper pattern groups GU1 and GU2 in the Z-axis direction when identifying that the top edge 110UE is located between the first target pattern TPT1 and the second target pattern TPT2, it is determined that the slope angle θ of the edge surface 110S is obtuse.

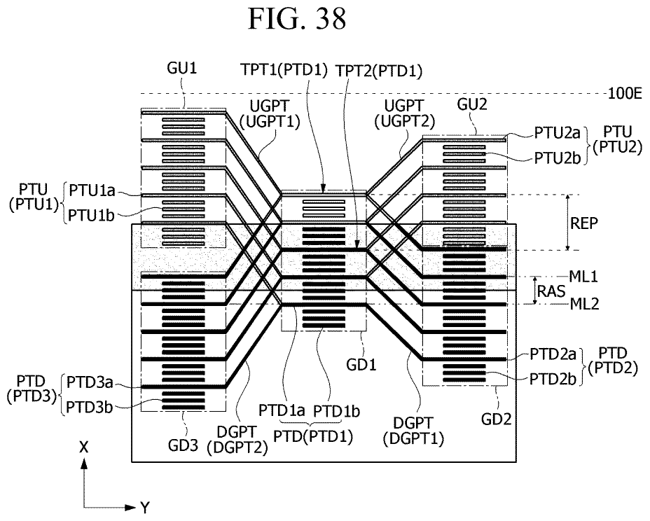

FIG. 38 is a diagram conceptually illustrating an arrangement relationship between an edge and patterns of a substrate determined to be normal in a display panel having the slope of an acute angle of a display device, according to another embodiment of the present disclosure.

As shown in FIG. 38, it is illustrated that the top edge 110UE provided as the second edge 110E of the substrate 110 is located between the first target pattern TPT1 and the second target pattern TPT2. Thus, the display panel 100d may receive a Safe determination for the outermost edge position of the substrate 110. Here, the first target pattern TPT1 may represent an upper limit of the outermost edge allowable range REP, and the second target pattern TPT2 may represent a lower limit of the outermost edge allowable range REP.

As the top edge 110UE is located between the first target pattern TPT1 and the second target pattern TPT2, the first lower pattern PTD1 corresponding to the top edge 110UE may be recognized. And, as in the display panel 100a according to the second embodiment, the second lower pattern PTD2 and the third lower pattern PTD3 corresponding to the first lower pattern PTD1 recognized in the display panel 100d may be identified.

Moreover, the slope allowable range RAS may be set by means of the first matching line ML1 and the second matching line ML2, which are arranged at a distance from each other in the first direction. Here, the interval between the first matching line ML1 and the second matching line ML2, which are spaced apart from each other in the first direction, may represent the slope allowable range RAS. For example, the first matching line ML1 may represent an upper limit within the slope allowable range RAS for the edge surface 110S, and the second matching line ML2 may represent a lower limit within the slope allowable range RAS for the edge surface 110S.

Therefore, when the bottom edge 110DE is located between the first matching line ML1 and the second matching line ML2, the display panel 100d may receive a Safe determination for the slope angle θ of the edge surface 110S. In other words, the determination of whether the slope angle θ of the edge surface 110S is normal or not may be easily made by means of the bottom edge 110DE located between the first matching line ML1 and the second matching line ML2, without separate calculation.

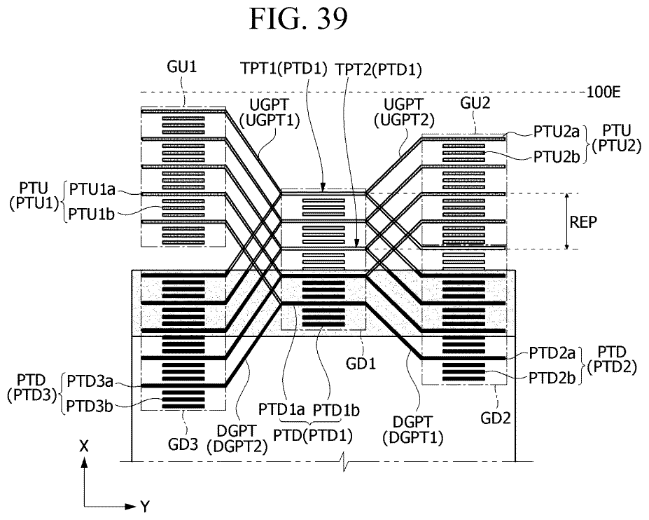

FIG. 39 is a diagram illustrating a defect of an edge position of a substrate determined by a plurality of patterns in a display panel having the slope of an acute angle of a display device, according to another embodiment of the present disclosure.

As shown in FIG. 39, it is illustrated that the top edge 110UE provided as the second edge 110E of the substrate 110 is located beyond the outermost edge allowable range REP as represented by the interval between the first target pattern TPT1 and the second target pattern TPT2. Thus, the display panel 100d may be classified as an abnormal panel by receiving an Out determination for the outermost edge position of the substrate 110.

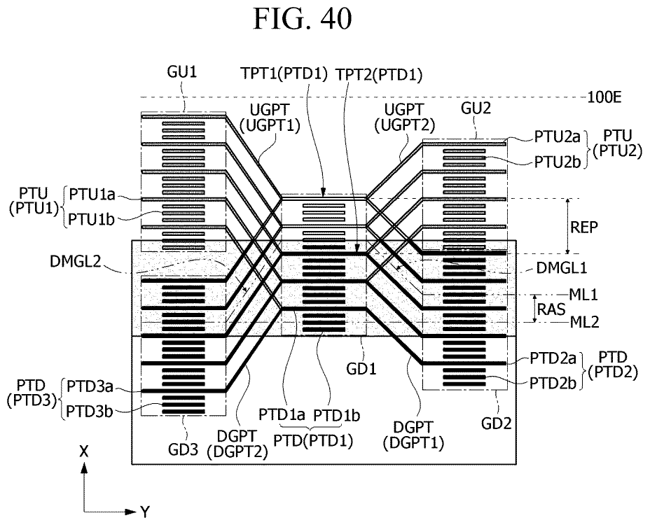

FIG. 40 is a diagram illustrating a slope defect of a substrate determined by a plurality of patterns in a display panel having the slope of an acute angle of a display device, according to another embodiment of the present disclosure.

As shown in FIG. 40, it is illustrated that the bottom edge 110DE of the substrate 110 is located beyond the slope allowable range RAS as represented by the interval between the first matching line ML1 and the second matching line ML2. Thus, the display panel 100d may be classified as an abnormal panel by receiving an Out determination with respect to the slope angle θ of the edge surface 110S of the substrate 110.

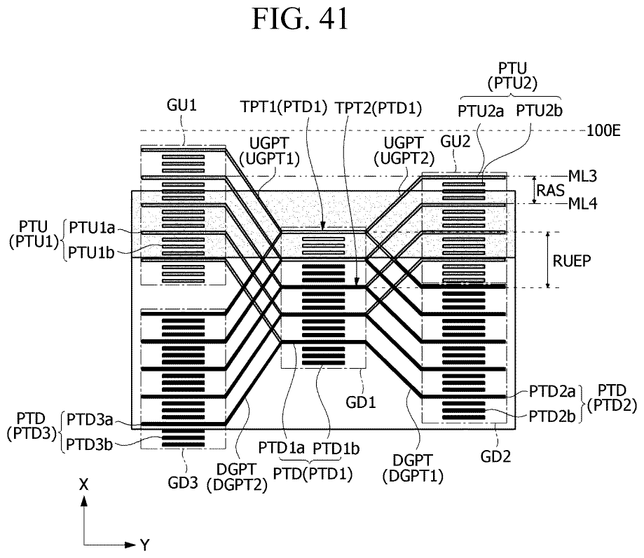

FIG. 41 is a diagram conceptually illustrating an arrangement relationship between an edge and patterns of a substrate determined to be normal in a display panel having the slope of an obtuse angle of a display device, according to another embodiment of the present disclosure.

As shown in FIG. 41, it is illustrated that a top edge 110UE is located between a first target pattern TPT1 and a second target pattern TPT2. Thus, the display panel 100d may receive a Safe determination for the top edge position of the substrate 110. Here, the first target pattern TPT1 may represent an upper limit of the top edge allowable range RUEP, and the second target pattern TPT2 may represent a lower limit of the top edge allowable range RUEP.

As the top edge 110UE is located between the first target pattern TPT1 and the second target pattern TPT2, the first lower pattern PTD1 corresponding to the top edge 110UE may be recognized. And, as in the display panel 100c according to the fourth embodiment, the first upper pattern PTU1 and the second upper pattern PTU2 corresponding to the first lower pattern PTD1 recognized in the display panel 100d may be identified.

And the slope allowable range RAS may be set by means of the third matching line ML3 and the fourth matching line ML4, which are arranged at a distance from each other in the first direction. Here, the interval between the third matching line ML3 and the fourth matching line ML4, which are spaced apart from each other in the first direction, may represent the slope allowable range RAS. For example, the third matching line ML3 may represent an upper limit within the slope allowable range RAS for the edge surface 110S, and the fourth matching line ML4 may represent a lower limit within the slope allowable range RAS for the edge surface 110S.

Therefore, when the bottom edge 110DE is located between the third matching line ML3 and the fourth matching line ML4, the display panel 100d may receive a Safe determination for the slope angle θ of the edge surface 110S. In other words, the determination of whether the slope angle θ of the edge surface 110S is normal or not may be easily made by means of the bottom edge 110DE located between the third matching line ML3 and the fourth matching line ML4, without separate calculation.

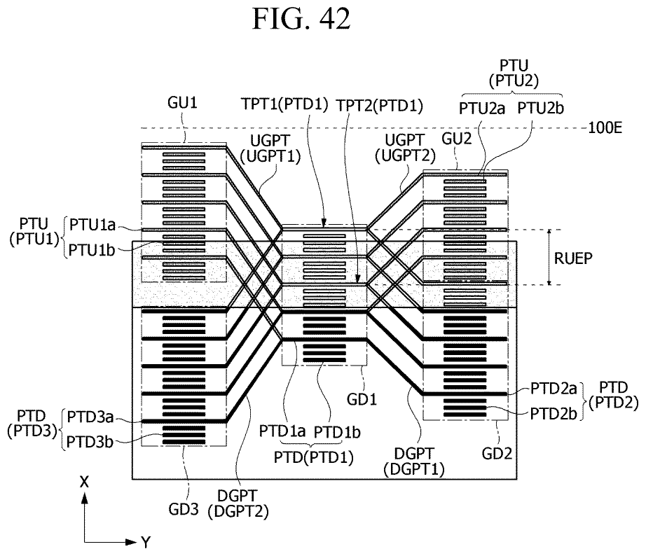

FIG. 42 is a diagram illustrating a defect of an edge position of a substrate determined by a plurality of patterns in a display panel having the slope of an obtuse angle of a display device, according to another embodiment of the present disclosure.

As shown in FIG. 42, it is illustrated that the top edge 110UE is located beyond a top edge allowable range RUEP as represented by the interval between a first target pattern TPT1 and a second target pattern TPT2. Thus, the display panel 100d may be classified as an abnormal panel by receiving an Out determination for the top edge position of the substrate 110.

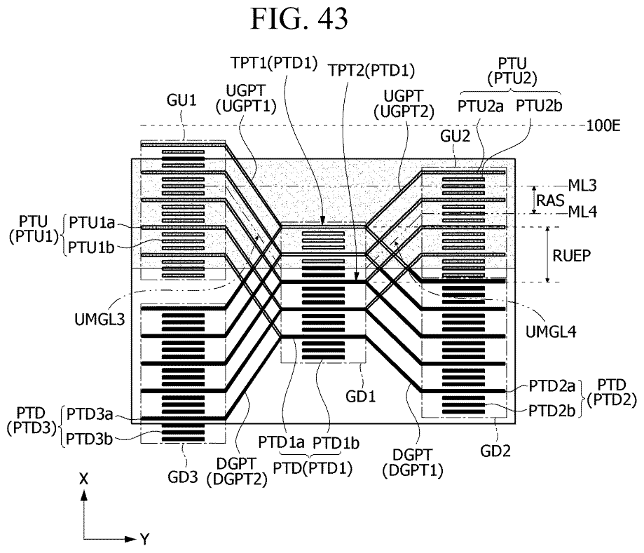

FIG. 43 is a diagram illustrating a slope defect of a substrate determined by a plurality of patterns in a display panel having the slope of an obtuse angle of a display device, according to another embodiment of the present disclosure.

As shown in FIG. 43, it is illustrated that the bottom edge 110DE of the substrate 110 is located beyond the slope allowable range RAS as represented by the interval between the third matching line ML3 and the fourth matching line ML4. Thus, the display panel 100d may be classified as an abnormal panel by receiving an Out determination with respect to the slope angle θ of the edge surface 110S of the substrate 110.

Meanwhile, by identifying whether a portion of the lower guide pattern DGPT that overlaps the edge surface 110S in the Z-axis direction is etched, it is possible to predict whether the slope angle θ of the edge surface 110S is acute or obtuse. For example, when the slope angle θ is acute, it may be confirmed that a portion of the lower guide pattern DGPT that overlaps the edge surface 110S in the Z-axis direction has not been etched (see FIGS. 38 to 40). However, when the slope angle θ is obtuse, it may be confirmed that a portion of the lower guide pattern DGPT that overlaps the edge surface 110S in the Z-axis direction has been etched (see FIGS. 41 to 43).

The display device according to one or more embodiments of the present disclosure may be described as follows.

A display device according to one or more embodiment of the present disclosure may include: a display panel and a flexible printed circuit connected to a pad electrode of the display panel, wherein the display panel may include: a substrate located on a non-display area, a first planarization layer disposed on the substrate, and a plurality of first lower patterns disposed between the substrate and the first planarization layer in the non-displayed area, and wherein the substrate may include a top edge and a bottom edge by which an edge surface having a predetermined slope is formed, the plurality of the first lower patterns may be disposed parallel to the edges of the display panel, and a first lower pattern disposed at the outermost side among the plurality of first lower patterns may be disposed adjacent to the top edge of the substrate.

Two first lower patterns spaced apart by a predetermined interval among the plurality of first lower patterns may each be designated as a first target pattern and a second target pattern, the top edge may be disposed between the first target pattern and the second target pattern, and the first lower pattern disposed at the outermost side may be the first target pattern.

The display panel may further include a mark disposed on each of the first target pattern and the second target pattern.

A groove concavely formed may be disposed to protrude from the outside of the substrate in a lower portion of a partial area of the first planarization layer.

A side coating layer may be further disposed in the groove.

When a slope angle formed by the edge surface and a top surface of the substrate is an acute angle, the display panel may further include: a second lower pattern group and a third lower pattern group spaced apart from a first lower pattern group including the first lower patterns, wherein the second lower pattern group may include a plurality of second lower patterns, the third lower pattern group may include a plurality of third lower patterns, and a second distance from an edge of the display panel to the second lower pattern group may be larger than a first distance from the edge of the display panel to the first lower pattern group and less than a third distance from the edge of the display panel to the third lower pattern group.

The display panel may further include: a first lower guide pattern configured to connect one of the plurality of first lower patterns to one of the plurality of second lower patterns; and a second lower guide pattern configured to connect one of the plurality of first lower patterns to one of the plurality of third lower patterns.

Each of the plurality of the first lower patterns, the plurality of the second lower patterns, and the plurality of the third lower patterns may be disposed to be spaced apart from each other in a first direction, the edge of the display panel may be disposed in a second direction, the second lower pattern and the third lower pattern corresponding to the first lower pattern overlapping the top edge in a third direction may form a predetermined interval in the first direction, and the bottom edge may be located in the predetermined interval.

When a slope angle formed by the edge surface and a top surface of the substrate is an acute angle, the display panel may further include: a first upper pattern group and a second upper pattern group disposed on the first planarization layer, wherein the first upper pattern group may include a plurality of first upper patterns, the second upper pattern group may include a plurality of second upper patterns, and a second distance from an edge of the display panel to the first upper pattern group may be larger than a first distance from the edge of the display panel to the first lower pattern group and less than a third distance from the edge of the display panel to the second upper pattern group.

The display panel may further include a first upper guide pattern and a second upper guide pattern disposed on the first planarization layer, wherein the first upper guide pattern may extend from the first upper pattern toward one side of one of the plurality of first lower patterns, and the second upper guide pattern may extend from the second upper pattern toward the other side of one of the plurality of first lower patterns.

Each of the plurality of the first lower patterns, the plurality of the first upper patterns, and the plurality of the second upper patterns may be spaced apart from each other in a first direction, the edge of the display panel may be disposed in a second direction, the first upper pattern and the second upper pattern corresponding to the first lower pattern overlapping the top edge in a third direction may form a predetermined interval in the first direction, and the bottom edge may be located in the predetermined interval.

When a slope angle formed by a top surface of the substrate and the edge surface is an obtuse angle, the display panel may further include a first upper pattern group and a second upper pattern group disposed on the first planarization layer, wherein the first upper pattern group may include a plurality of first upper patterns, the second upper pattern group may include a plurality of second upper patterns, a fourth distance from an edge of the display panel to the first upper pattern group may be less than a fifth distance from the edge of the display panel to the second upper pattern group, and a first distance from the edge of the display panel to the first lower pattern group may be larger than the fifth distance from the edge of the display panel to the second upper pattern group.

The display panel may further include a first upper guide pattern and a second upper guide pattern disposed on the first planarization layer, wherein the first upper guide pattern may extend from the first upper pattern toward one side of one of the plurality of first lower patterns, and the second upper guide pattern may extend from the second upper pattern toward the other side of one of the plurality of first lower patterns.

Each of the plurality of the first lower patterns, the plurality of the first upper patterns, and the plurality of the second upper patterns may be spaced apart from each other in a first direction, the edge of the display panel may be disposed in a second direction, the first upper pattern and the second upper pattern corresponding to the first lower pattern overlapping the top edge in a third direction may form a predetermined interval in the first direction, and the bottom edge may be located in the predetermined interval.

The substrate may be formed of glass.

A display device according to one or more embodiment of the present disclosure may include a display panel and a flexible printed circuit connected to a pad electrode of the display panel, wherein the display panel may include a substrate located on a non-display area, a first planarization layer disposed on the substrate, a first lower pattern group, a second lower pattern group, and a third lower pattern group disposed between the substrate and the first planarization layer; and a first upper pattern group and a second upper pattern group disposed on the first planarization layer, and wherein a second distance from an edge of the display panel to the second lower pattern group may be larger than a first distance from the edge of the display panel to the first lower pattern group and less than a third distance from the edge of the display panel to the third lower pattern group, a fourth distance from the edge of the display panel to the first upper pattern group may be less than a fifth distance from the edge of the display panel to the second upper pattern group, and a first distance from the edge of the display panel to the first lower pattern group may be larger than the fifth distance from the edge of the display panel to the second upper pattern group.

The second lower pattern group may overlap the second upper pattern group in a first direction, the third lower pattern group may overlap the first upper pattern group in the first direction, and the edge of the display panel may be disposed in a second direction.

The display panel may further include a first lower guide pattern, a second lower guide pattern, a first upper guide pattern, and a second upper guide pattern, wherein the first lower guide pattern may connect one side of a first lower pattern in the first lower pattern group and a second lower pattern in the second lower pattern group, the second lower guide pattern may connect the other side of the first lower pattern and a third lower pattern in the third pattern group, the first upper guide pattern may extend from a first upper pattern in the first upper pattern group toward the other side of the first lower pattern, and the second upper guide pattern may extend from a second upper pattern in the second upper pattern group toward the one side of the first lower pattern.

The above description of the problem to be solved, the means to solve the problem, and the effect described above does not specify the essential features of the claims, and therefore the scope of the claims is not limited by what is described in the disclosure.

Example embodiments of the present disclosure may be described as follows.

In one or more example embodiments, a display device may include a display panel and a flexible printed circuit connected to a pad electrode of the display panel. The display panel may include a substrate having an end portion with an inclined surface and located on a non-display area, a first planarization layer disposed on the substrate, and a plurality of first lower patterns disposed between the substrate and the first planarization layer. The substrate may include a top edge and a bottom edge, and the inclined surface may include a top edge and a bottom edge having an edge surface having a predetermined angle. The plurality of the first lower patterns may be disposed parallel to the edges of the display panel. An outermost first lower pattern of the plurality of first lower patterns may be disposed proximate the top edge of the inclined surface at an outermost side of the plurality of first lower patterns and may be disposed adjacent to the top edge of the substrate.

In some example embodiments, the plurality of the first lower patterns are parallel to the edges of the display panel.

In some example embodiments, the display device further includes a buffer layer disposed on the substrate. The buffer layer may include a buffer layer inclined surface that aligns with the inclined surface of the substrate. The outermost first lower pattern may directly contact an upper surface of the buffer layer proximate the buffer layer inclined surface.

In some example embodiments, the plurality of first lower patterns includes a first target pattern and a second target pattern. The first target pattern and the second target pattern may be spaced apart in a predetermined interval. The top edge may be disposed between the first target pattern and the second target pattern. The first target pattern may be disposed at the outermost side.

In some example embodiments, the display panel further includes a mark disposed on each of the first target pattern and the second target pattern.

In some example embodiments, the display device includes a groove disposed in a lower portion of the first planarization layer and protrudes from an exterior surface of the substrate.

In some example embodiments, the display device includes a side coating layer that is further disposed in the groove.

In some example embodiments, the angle is an acute angle.

In some example embodiments, the display device further includes a second lower pattern group and a third lower pattern group spaced apart from a first lower pattern group that includes the first lower patterns. The second lower pattern group may include a plurality of second lower patterns. The third lower pattern group may include a plurality of third lower patterns. A second distance from an edge of the display panel to the second lower pattern group may be larger than a first distance from the edge of the display panel to the first lower pattern group and less than a third distance from the edge of the display panel to the third lower pattern group.

In some example embodiments, the display device further includes a first lower guide pattern configured to connect one of the plurality of first lower patterns to one of the plurality of second lower patterns. A second lower guide pattern may be configured to connect one of the plurality of first lower patterns to one of the plurality of third lower patterns.

In some example embodiments, each of the plurality of first lower patterns, the plurality of second lower patterns, and the plurality of third lower patterns may be spaced apart from each other in a first direction. An edge of the display panel may extend in a second direction. A predetermined interval may extend in the first direction and may be formed by the second lower pattern and the third lower pattern corresponding to the first lower pattern that overlaps the top edge in a third direction. The bottom edge may be located in the predetermined interval.

In some example embodiments, the display panel further includes a first upper pattern group and a second upper pattern group disposed on the first planarization layer. The first upper pattern group may include a plurality of first upper patterns. The second upper pattern group may include a plurality of second upper patterns. A second distance from an edge of the display panel to the first upper pattern group may be larger than a first distance from the edge of the display panel to the first lower pattern group and less than a third distance from the edge of the display panel to the second upper pattern group.

In some example embodiments, the display panel further includes a first upper guide pattern and a second upper guide pattern disposed on the first planarization layer. The first upper guide pattern may extend from the first upper pattern toward one side of one of the plurality of first lower patterns. The second upper guide pattern may extend from the second upper pattern toward the other side of one of the plurality of first lower patterns.

In some example embodiments, each of the plurality of first lower patterns, the plurality of the first upper patterns, and the plurality of the second upper patterns are spaced apart from each other in a first direction. An edge of the display panel may extend in a second direction. A predetermined interval that extends in the first direction may be formed by the first upper pattern and the second upper pattern corresponding to the first lower pattern that overlaps the top edge in a third direction. The bottom edge may be located in the predetermined interval.

In some example embodiments, the angle is an obtuse angle.

In some example embodiments, the display panel further includes a first upper pattern group and a second upper pattern group disposed on the first planarization layer. The first upper pattern group may include a plurality of first upper patterns. The second upper pattern group may include a plurality of second upper patterns. A fourth distance from an edge of the display panel to the first upper pattern group may be less than a fifth distance from the edge of the display panel to the second upper pattern group. A first distance from the edge of the display panel to the first lower pattern group may be larger than the fifth distance from the edge of the display panel to the second upper pattern group.

In some example embodiments, the display panel further includes a first upper guide pattern and a second upper guide pattern disposed on the first planarization layer. The first upper guide pattern may extend from the first upper pattern toward one side of one of the plurality of first lower patterns. The second upper guide pattern may extend from the second upper pattern toward the other side of one of the plurality of first lower patterns.

In some example embodiments, each of the plurality of first lower patterns, the plurality of the first upper patterns, and the plurality of the second upper patterns are spaced apart from each other in a first direction. An edge of the display panel may extend in a second direction. A predetermined interval may extend in the first direction formed by the first upper pattern and the second upper pattern corresponding to the first lower pattern that overlaps the top edge in a third direction. The bottom edge may be located in the predetermined interval.

In some example embodiments, the substrate is formed of glass.

In other example embodiments, a display device may include a display panel and a flexible printed circuit connected to a pad electrode of the display panel. The display panel may include a substrate comprising an end portion having an inclined surface, a first planarization layer disposed on the substrate, a second planarization layer disposed on the first planarization layer, and a plurality of patterns disposed between the first planarization layer and the second planarization layer. The plurality of patterns may include a plurality of main patterns and a plurality of sub patterns. The main patterns may have a length that is longer than a length of the sub patterns.

In some example embodiments, the inclined surface includes a top edge and a bottom edge and includes a predetermined slope angle. The lower patterns may be disposed in an area that corresponds to an area including the inclined surface of the substrate.

In some example embodiments, the plurality of main patterns includes a first main pattern and a second main pattern. One or more sub patterns of the plurality of sub patterns may be disposed between the first main pattern and the second main pattern.

In some example embodiments, the second lower pattern group overlaps the second upper pattern group in a first direction. The third lower pattern group may overlap the first upper pattern group in the first direction. An edge of the display panel may extend in a second direction.

In some example embodiments, the display panel further includes a first lower guide pattern, a second lower guide pattern, a first upper guide pattern, and a second upper guide pattern. The first lower guide pattern may connect a first side of a first lower pattern in the first lower pattern group and a second lower pattern in the second lower pattern group. The second lower guide pattern may connect a second side of the first lower pattern and a third lower pattern in the third pattern group. The first upper guide pattern may extend from a first upper pattern in the first upper pattern group toward the second side of the first lower pattern. The second upper guide pattern may extend from a second upper pattern in the second upper pattern group toward the first side of the first lower pattern.

As set forth above, specific example embodiments of the present disclosure have been described in more detail with reference to the accompanying drawings. However, the present disclosure is not limited to the foregoing example embodiments, but a variety of modifications are possible without departing from the principle of the present disclosure. Thus, the foregoing example embodiments disclosed herein should be interpreted as being illustrative, while not being limiting, of the principle of the present disclosure, and the scope of the present disclosure is not limited to the foregoing example embodiments. Therefore, the foregoing example embodiments should not be construed as being exhaustive in any aspects.

It will be apparent to those skilled in the art that various modifications and variations can be made in the present disclosure without departing from the spirit or scope of the disclosure. Thus, it is intended that the present disclosure cover such modifications and variations of this disclosure.

What is claimed is:

1. A display device comprising:
a display panel and a flexible printed circuit connected to a pad electrode of the display panel,
wherein the display panel includes:
a substrate comprising an end portion having an inclined surface,
a first planarization layer disposed on the substrate, and
a plurality of first lower patterns disposed between the substrate and the first planarization layer, and
wherein the inclined surface includes a top edge and a bottom edge and comprises a predetermined angle, and
wherein an outermost first lower pattern of the plurality of first lower patterns is disposed proximate the top edge of the inclined surface.

2. The display device of claim 1, wherein the plurality of the first lower patterns are parallel to the edges of the display panel.

3. The display device of claim 1, further comprising a buffer layer disposed on the substrate,
wherein the buffer layer comprises a buffer layer inclined surface that aligns with the inclined surface of the substrate, and
wherein the outermost first lower pattern directly contacts an upper surface of the buffer layer proximate the buffer layer inclined surface.

4. The display device of claim 1, wherein:
the plurality of first lower patterns comprises a first target pattern and a second target pattern,
the first target pattern and the second target pattern are spaced apart in a predetermined interval,
the top edge is disposed between the first target pattern and the second target pattern, and
the first target pattern is disposed at the outermost side.

5. The display device of claim 4, wherein the display panel further includes:
a mark disposed on each of the first target pattern and the second target pattern.

6. The display device of claim 1, wherein a groove is disposed in a lower portion of the first planarization layer and protrudes from an exterior surface of the substrate.

7. The display device of claim 6, wherein a side coating layer is further disposed in the groove.

8. The display device of claim 1,
wherein the angle is an acute angle.

9. The display device of claim 8, further comprising:
a second lower pattern group and a third lower pattern group spaced apart from a first lower pattern group that includes the first lower patterns,
wherein:
the second lower pattern group includes a plurality of second lower patterns,
the third lower pattern group includes a plurality of third lower patterns, and
a second distance from an edge of the display panel to the second lower pattern group is larger than a first distance from the edge of the display panel to the first lower pattern group and less than a third distance from the edge of the display panel to the third lower pattern group.

10. The display device of claim 9, further comprising:
a first lower guide pattern configured to connect one of the plurality of first lower patterns to one of the plurality of second lower patterns; and
a second lower guide pattern configured to connect one of the plurality of first lower patterns to one of the plurality of third lower patterns.

11. The display device of claim 10, wherein:
each of the plurality of first lower patterns, the plurality of second lower patterns, and the plurality of third lower patterns are spaced apart from each other in a first direction,
an edge of the display panel extends in a second direction,
a predetermined interval extends in the first direction and is formed by the second lower pattern and the third lower pattern corresponding to the first lower pattern that overlaps the top edge in a third direction, and
the bottom edge is located in the predetermined interval.

12. The display device of claim 8, wherein the display panel further includes:
a first upper pattern group and a second upper pattern group disposed on the first planarization layer, wherein:
the first upper pattern group includes a plurality of first upper patterns,
the second upper pattern group includes a plurality of second upper patterns, and
a second distance from an edge of the display panel to the first upper pattern group is larger than a first distance from the edge of the display panel to the first lower pattern group and less than a third distance from the edge of the display panel to the second upper pattern group.

13. The display device of claim 12, wherein the display panel further includes:
a first upper guide pattern and a second upper guide pattern disposed on the first planarization layer, wherein:
the first upper guide pattern extends from the first upper pattern toward one side of one of the plurality of first lower patterns, and
the second upper guide pattern extends from the second upper pattern toward the other side of one of the plurality of first lower patterns.

14. The display device of claim 13, wherein:
each of the plurality of first lower patterns, the plurality of the first upper patterns, and the plurality of the second upper patterns are spaced apart from each other in a first direction,
an edge of the display panel extends in a second direction,
a predetermined interval that extends in the first direction is formed by the first upper pattern and the second upper pattern corresponding to the first lower pattern that overlaps the top edge in a third direction, and
the bottom edge is located in the predetermined interval.

15. The display device of claim 1,
wherein the angle is an obtuse angle.

16. The display device of claim 15, the display panel further includes:
a first upper pattern group and a second upper pattern group disposed on the first planarization layer, wherein:
the first upper pattern group includes a plurality of first upper patterns,
the second upper pattern group includes a plurality of second upper patterns,
a fourth distance from an edge of the display panel to the first upper pattern group is less than a fifth distance from the edge of the display panel to the second upper pattern group, and
a first distance from the edge of the display panel to the first lower pattern group is larger than the fifth distance from the edge of the display panel to the second upper pattern group.

17. The display device of claim 16, the display panel further includes:
a first upper guide pattern and a second upper guide pattern disposed on the first planarization layer, wherein:
the first upper guide pattern extends from the first upper pattern toward one side of one of the plurality of first lower patterns, and
the second upper guide pattern extends from the second upper pattern toward the other side of one of the plurality of first lower patterns.

18. The display device of claim 17, wherein:
each of the plurality of first lower patterns, the plurality of the first upper patterns, and the plurality of the second upper patterns are spaced apart from each other in a first direction,
an edge of the display panel extends in a second direction,
a predetermined interval extending in the first direction formed by the first upper pattern and the second upper pattern corresponding to the first lower pattern that overlaps the top edge in a third direction, and
the bottom edge is located in the predetermined interval.

19. The display device of claim 1, wherein the substrate is formed of glass.

20. A display device comprising:
a display panel and a flexible printed circuit connected to a pad electrode of the display panel,
wherein the display panel includes:
a substrate comprising an end portion having an inclined surface,
a first planarization layer disposed on the substrate,
a second planarization layer disposed on the first planarization layer, and
a plurality of patterns disposed between the first planarization layer and the second planarization layer,
wherein the plurality of patterns comprises a plurality of main patterns and a plurality of sub patterns, and
wherein the main patterns have a length that is longer than a length of the sub patterns.

21. The display device of claim 20, wherein the inclined surface includes a top edge and a bottom edge and comprises a predetermined slope angle, and
wherein the lower patterns are disposed in an area that corresponds to an area including the inclined surface of the substrate.

22. The display device of claim 20, wherein the plurality of main patterns includes a first main pattern and a second main pattern, and
wherein one or more sub patterns of the plurality of sub patterns are disposed between the first main pattern and the second main pattern.

23. The display device of claim 20, wherein:
the second lower pattern group overlaps the second upper pattern group in a first direction,
the third lower pattern group overlaps the first upper pattern group in the first direction, and
an edge of the display panel extends in a second direction.

24. The display device of claim 23, wherein the display panel further includes:
a first lower guide pattern, a second lower guide pattern, a first upper guide pattern, and a second upper guide pattern, and wherein:
the first lower guide pattern connects a first side of a first lower pattern in the first lower pattern group and a second lower pattern in the second lower pattern group,
the second lower guide pattern connects a second side of the first lower pattern and a third lower pattern in the third lower pattern group,
the first upper guide pattern extends from a first upper pattern in the first upper pattern group toward the second side of the first lower pattern, and
the second upper guide pattern extends from a second upper pattern in the second upper pattern group toward the first side of the first lower pattern.
